(19) United States
(12) Patent Application Publication
(10) Pub. No.: US 2024/0404804 A1
(43) Pub. Date: Dec. 5, 2024

(54) Reference Box for Direct-Drive Radiofrequency Power Supply

(71) Applicant: Lam Research Corporation, Fremont, CA (US)

(72) Inventors: Alexander Miller Paterson, San Jose, CA (US); Daniel Guzman, San Jose, CA (US); William T. Hart, Castro Valley, CA (US); Cristian Siladie, San Ramon, CA (US); Michael John Martin, Fremont, CA (US); Yuhou Wang, Fremont, CA (US); Michael Drymon, Diablo Grande, CA (US); John Drewery, San Jose, CA (US); Robert Griffith O'Neill, Hayward, CA (US); Luc Albarede, Fremont, CA (US); Neil Simon Ocampo, Newark, CA (US)

(21) Appl. No.: 18/689,017

(22) PCT Filed: Sep. 13, 2022
(86) PCT No.: PCT/US2022/043393

§ 371 Date: Mar. 4, 2024

Related U.S. Application Data
(60) Provisional application No. 63/245,755, filed on Sep. 17, 2021.

(51) Int. Cl. H01J 37/32; H01J 37/34

(52) U.S. Cl. CPC H01J 37/32935; H01J 37/32183; H01J 37/3299; H01J 37/3488

(57) ABSTRACT

A radiofrequency calibration system for a direct-drive radiofrequency power supply includes a reference box that includes a reference circuit for converting a non-reference input impedance to a reference output impedance. The reference box has an input connector electrically connected to a radiofrequency output coupling of the direct-drive radiofrequency power supply. A radiofrequency power meter has a radiofrequency power input electrically connected to an output connector of the reference box. The radiofrequency power meter has an input impedance and an output impedance that substantially match the reference output impedance of the reference box. A cable has a first end electrically connected to a radiofrequency power output of the radiofrequency power meter and a second end connected to a test load that has an impedance that substantially matches the reference output impedance of the reference box. A controller is connected in data communication with a data interface of the radiofrequency power meter.

### BACKGROUND

Plasma processing systems are used to manufacture semiconductor devices, e.g., chips/die, on semiconductor wafers. In the plasma processing system, the semiconductor wafer is exposed to various types of plasma to cause prescribed changes to a condition of the semiconductor wafer, such as through material deposition and/or material removal and/or material implantation and/or material modification, etc. The plasma processing system conventionally includes a radiofrequency (RF) source, an RF transmission cable, an RF impedance matching network, an electrode, and a plasma generation chamber. The RF source is connected to the RF impedance matching network through the RF transmission cable. The RF impedance matching network is connected to the electrode through a electrical conductor. RF power generated by the RF source is transmitted through the RF transmission cable and through the RF impedance matching network to the electrode. RF power transmitted from the electrode causes a process gas to be transformed into a plasma within the plasma generation chamber. It is within this context that embodiments described in the present disclosure arise.

### SUMMARY

In an example embodiment, a reference box for a direct-drive radiofrequency power supply is disclosed. The reference box includes an input connector. The reference box also includes a reference circuit that has an input terminal connected to the input connector. The reference circuit is configured to convert a non-reference input impedance, e.g., non-50 ohm input impedance, to a reference output impedance, e.g., 50 ohm output impedance. The reference box also includes an output connector connected to an output terminal of the reference circuit.

In an example embodiment, a radiofrequency calibration system is disclosed. The system includes a reference box that includes a reference circuit configured to convert a non-reference input impedance, e.g., non-50 ohm input impedance, to a reference output impedance, e.g., 50 ohm output impedance. The reference box has an input connector and an output connector. The input connector is configured to electrically connect with an RF output coupling of a direct-drive radiofrequency power supply. The system also includes a radiofrequency power meter that has a radiofrequency power input electrically connected to the output connector of the reference box. The radiofrequency power meter has a radiofrequency power output and a data interface. The radiofrequency power meter has an input impedance and an output impedance substantially equal to the reference output impedance of the reference box. The system also includes a cable that has an impedance substantially equal to the reference output impedance of the reference box. The cable has a first end electrically connected to the radiofrequency power output of the radiofrequency power meter. The system also includes a test load electrically connected to a second end of the cable. The test load has an impedance substantially equal to the reference output impedance of the reference box. The system also includes a controller connected in data communication with the data interface of the radiofrequency power meter.

In an example embodiment, a method is disclosed for calibrating a direct-drive radiofrequency power supply. The method includes electrically disconnecting a radiofrequency power output of the direct-drive radiofrequency power supply from a downstream radiofrequency power transmission system. The method also includes electrically connecting an input connector of a reference box to the radiofrequency power output of the direct-drive radiofrequency power supply. The reference box includes a reference circuit configured to convert a non-reference input impedance to a reference output impedance. The method also includes electrically connecting an output of the reference box to an input of a radiofrequency power meter. The radiofrequency power meter has an output electrically connected through a cable to a test load. The method also includes operating the direct-drive radiofrequency power supply to drive a setpoint amount of radiofrequency power through the reference box, power meter, and cable to the test load. The method also includes operating the radiofrequency power meter to measure an output amount of radiofrequency power at the output of the reference box. The method also includes adjusting the output amount of radiofrequency power measured by the radiofrequency power meter by a known amount of radiofrequency power dissipated by the reference box to determine an actual output amount of radiofrequency power. The method also includes storing the actual output amount of radiofrequency power in relation to the setpoint amount of radiofrequency power as a radiofrequency power calibration datapoint for the direct-drive radiofrequency power supply. A difference between the actual output amount of radiofrequency power and the setpoint amount of radiofrequency power provides a radiofrequency power calibration adjustment factor to ensure that the radiofrequency power output of the direct-drive radiofrequency power supply substantially matches the setpoint amount of radiofrequency power during operation of the direct-drive radiofrequency power supply.

Other aspects and advantages of the embodiments will become more apparent from the following detailed description and the accompanying drawings.

### BRIEF DESCRIPTION OF THE DRAWINGS

FIG. 1A shows an isometric view of a plasma processing system that includes a direct-drive RF power supply, in accordance with some embodiments.

FIG. 1B shows a front view of the plasma processing system of FIG. 1A, in accordance with some embodiments.

FIG. 1C shows a back view of the plasma processing system of FIG. 1A, in accordance with some embodiments.

FIG. 1D shows a left-side view of the plasma processing system of FIG. 1A, in accordance with some embodiments.

FIG. 1E shows a right-side view of the plasma processing system of FIG. 1A, in accordance with some embodiments.

FIG. 2 shows a top view of the coil assembly, in accordance with some embodiments.

FIG. 3 shows a diagram of a vertical cross-section taken through the plasma processing chamber, in accordance with some embodiments.

FIG. 4 shows an isometric view of the plasma processing system with the platform removed to reveal the region within the first RF connection enclosure, the region within the second RF connection enclosure, and the T-shaped interior region of the metrology enclosure, in accordance with some embodiments.

FIG. 5 shows a perspective view of the plasma processing system looking toward the front of the plasma processing system with the removable doors and removed, in accordance with some embodiments.

FIG. 6 shows the perspective view of the plasma processing system of FIG. 5 with the first RF jumper structure removed from both the first upper coupling structure and the first lower coupling structure, and with the second RF jumper structure removed from both the second upper coupling structure and the second lower coupling structure, in accordance with some embodiments.

FIG. 7A shows a close-up isometric view of the first/second RF jumper structure simultaneously inserted into both the first/second upper coupling structure and the first/second lower coupling structure, in accordance with some embodiments.

FIG. 7B shows a vertical cross-section view through the first/second RF jumper structure installation configuration of FIG. 7A, with the first/second bolt threaded into the first/second dielectric bracket, in accordance with some embodiments.

FIG. 7C shows an isometric view of the first/second bolt removed from the first/second dielectric bracket, with the first/second RF jumper structure removed from both the first/second upper coupling structures and the first/second lower coupling structures, in accordance with some embodiments.

FIG. 8 shows a bottom view of the plasma processing system with the bottom covers of the first junction box and the second junction box removed to show components of the first reactive circuit and the second reactive circuit, in accordance with some embodiments.

FIG. 9A shows a circuit schematic depicting transmission of RF power from the first direct-drive RF signal generator through the first reactive circuit to the outer coil of the coil assembly, in accordance with some embodiments.

FIG. 9B shows an isometric view of a portion of the plasma processing system, from a front-left-upper point of view, with the walls of the first junction box removed to reveal the components of the first reactive circuit and with the walls of the second junction box removed to reveal the components of the second reactive circuit, in accordance with some embodiments.

FIG. 9C shows an isometric view of the plasma processing system as shown in FIG. 9B, from a back-left-upper point of view, in accordance with some embodiments.

FIG. 10A shows a circuit schematic depicting transmission of RF power from the second direct-drive RF signal generator through the second reactive circuit to the inner coil of the coil assembly, in accordance with some embodiments.

FIG. 10B shows an isometric view of a portion of the plasma processing system, from a front-right-upper point of view, with the walls of the first junction box removed to reveal the components of the first reactive circuit and with the walls of the second junction box removed to reveal the components of the second reactive circuit, in accordance with some embodiments.

FIG. 10C shows an isometric view of the plasma processing system as shown in FIG. 10B, from a back-right-lower point of view, in accordance with some embodiments.

FIG. 11 shows a top view of a portion of the plasma processing system, with the walls of the first junction box removed to reveal the components of the first reactive circuit and with the walls of the second junction box removed to reveal the components of the second reactive circuit, in accordance with some embodiments.

FIG. 12 shows a schematic of how each of the first direct-drive RF signal generator and the second direct-drive RF signal generator is connected through the corresponding first reactive circuit or second reactive circuit to the coil assembly, in accordance with some embodiments.

FIG. 13 shows a flowchart of a method for delivering RF power from the direct-drive RF power supply to the plasma processing chamber, in accordance with some embodiments.

FIG. 14 shows a schematic diagram of each of the first and second direct-drive RF signal generators, in accordance with some embodiments.

FIG. 15 shows a circuit schematic of the half-bridge FET circuit that implements voltage limiters across the FETs, in accordance with some embodiments.

FIG. 16A shows a plot of a parameter of an example shaped-amplified square waveform generated at the output of the first/second direct-drive RF signal generator as a function of time, in accordance with some embodiments.

FIG. 16B shows a plot of a parameter of an example shaped-sinusoidal waveform generated at the output of the first/second reactive circuit as a function of time, in accordance with some embodiments.

FIG. 17A shows a plot of a parameter of an example shaped-sinusoidal waveform generated at the output of the first/second reactive circuit as a function of time, in accordance with some embodiments.

FIG. 17B shows a plot of a parameter of an example shaped-sinusoidal waveform generated at the output of the first/second reactive circuit as a function of time, in accordance with some embodiments.

FIG. 17C shows a plot of a parameter of an example shaped-sinusoidal waveform generated at the output of the first/second reactive circuit as a function of time, in accordance with some embodiments.

FIG. 17D shows a plot of a parameter of an example shaped-sinusoidal waveform generated at the output of the first/second reactive circuit as a function of time, in accordance with some embodiments.

FIG. 18 shows a flowchart of a method for calibrating the first/second direct-drive RF signal generator, in accordance with some embodiments.

FIG. 19 shows a schematic of the reference circuit implemented within the reference box, in accordance with some embodiments.

FIG. 20A shows a perspective view of the reference box connected to the first/second upper coupling structure, in accordance with some embodiments.

FIG. 20B shows the perspective view of the reference box of FIG. 20A with the top and sides of the reference box removed to reveal the components of the reference circuit, in accordance with some embodiments.

FIG. 21A shows an isometric view of the plasma processing system with the reference box connected to the first upper coupling structure to receive RF power from the first direct-drive RF signal generator, in accordance with some embodiments.

FIG. 21B shows an isometric view of the plasma processing system with the reference box connected to the second upper coupling structure to receive RF power from the second direct-drive RF signal generator, in accordance with some embodiments.

FIG. 22 shows a flowchart of a method for connecting the reference box to the plasma processing system, in accordance with some embodiments.

FIG. 23 shows a flowchart of a method for calibrating the field unit reference box against the master-standard reference box, in accordance with some embodiments.

FIG. 24 shows a flowchart of a method for using the field unit reference box to calibrate the RF power output of the first/second direct-drive RF signal generator, in accordance with some embodiments.

FIG. 25A shows an isometric view of a hands-free reference box connection system, in accordance with some embodiments.

FIG. 25B shows an isometric view of the hands-free reference box connection system with the first/second RF connection enclosure removed to more clearly reveal components of the hands-free reference box connection system, in accordance with some embodiments.

FIG. 25C shows a side view of the configuration of FIG. 25B, in accordance with some embodiments.

FIG. 25D shows an isometric view of the hands-free reference box connection system, with the guide plate of the field unit reference box inserted between the bottom guide rail and the top guide rail, and with the guide plate and field unit reference box moved toward the RF output coupling up to a point where vertical lifting of the RF output coupling is to start, in accordance with some embodiments.

FIG. 25E shows a side view of the configuration of FIG. 25D, in accordance with some embodiments.

FIG. 25F shows an isometric view of the hands-free reference box connection system, with the guide plate of the field unit reference box inserted between the bottom guide rail and the top guide rail, and with the guide plate and field unit reference box moved further toward the RF output coupling up to a point where vertical lifting of the RF output coupling is at about half way through its vertical stroke length, in accordance with some embodiments.

FIG. 25G shows a side view of the configuration of FIG. 25F, in accordance with some embodiments.

FIG. 25H shows an isometric view of the hands-free reference box connection system, with the guide plate of the field unit reference box inserted between the bottom guide rail and the top guide rail, and with the guide plate and field unit reference box moved to a fully inserted position at which the input connector is physically engaged with and electrically connected to the RF output coupling, in accordance with some embodiments.

FIG. 25I shows another perspective view of the configuration of FIG. 25H from a point of view looking toward the front of the field unit reference box, in accordance with some embodiments.

FIG. 25J shows a side view of the configuration of FIG. 25H, in accordance with some embodiments.

FIG. 25K shows an isometric view of the field unit reference box in the fully inserted position within the first/second RF connection enclosure, with cut-away views of the top guide rail, guide plate, and field unit reference box to show the components of the reference circuit, in accordance with some embodiments.

### DETAILED DESCRIPTION

In the following description, numerous specific details are set forth in order to provide a thorough understanding of the present disclosure. It will be apparent, however, to one skilled in the art that embodiments of the present disclosure may be practiced without some or all of these specific details. In other instances, well known process operations have not been described in detail in order not to unnecessarily obscure the present disclosure.

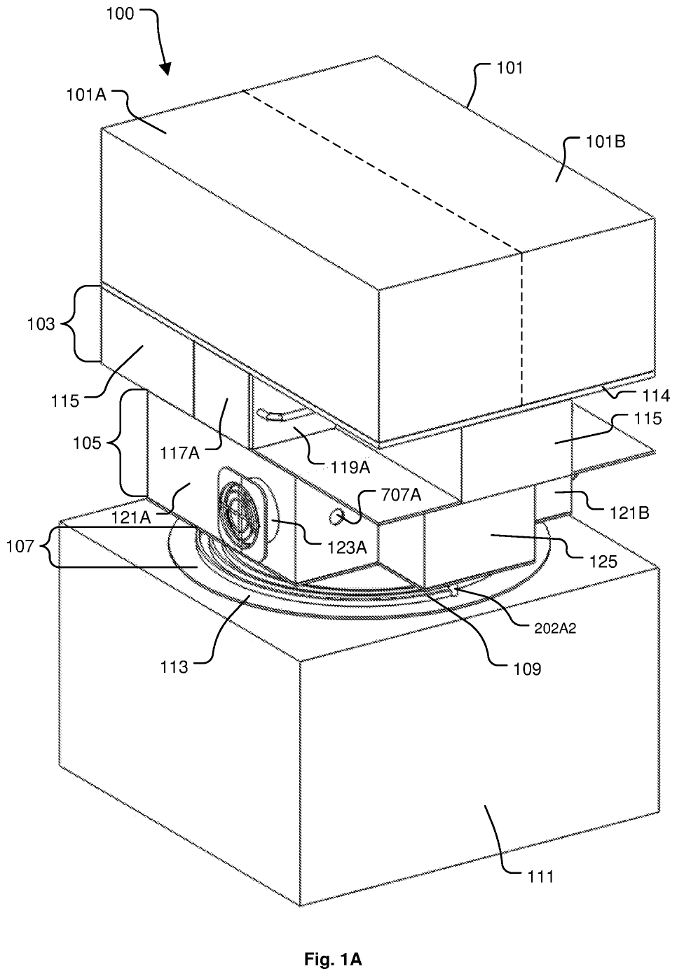

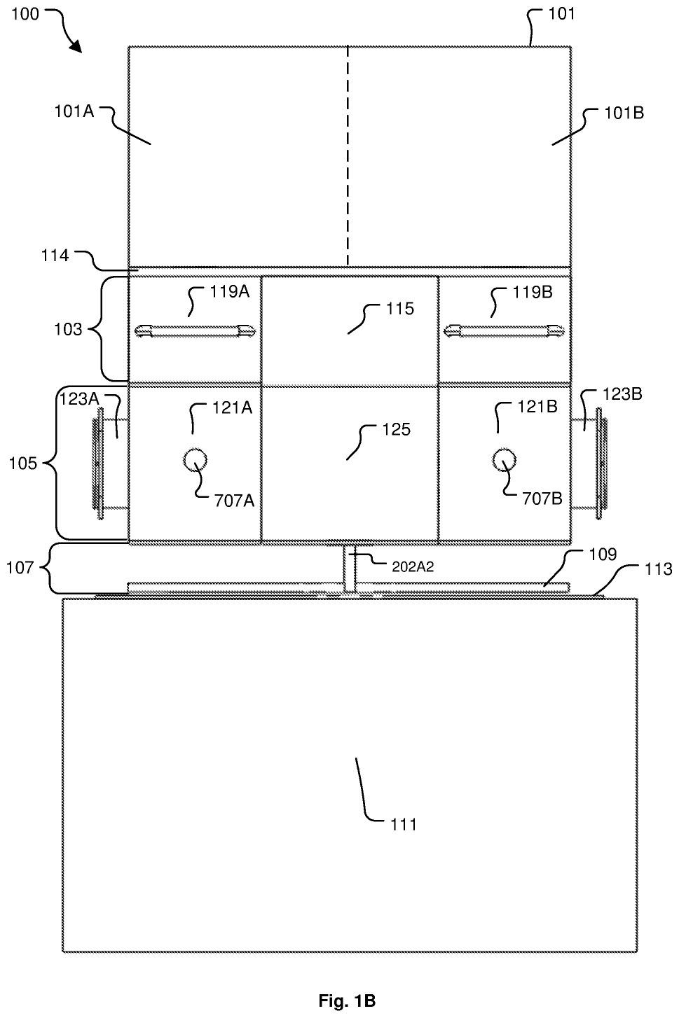

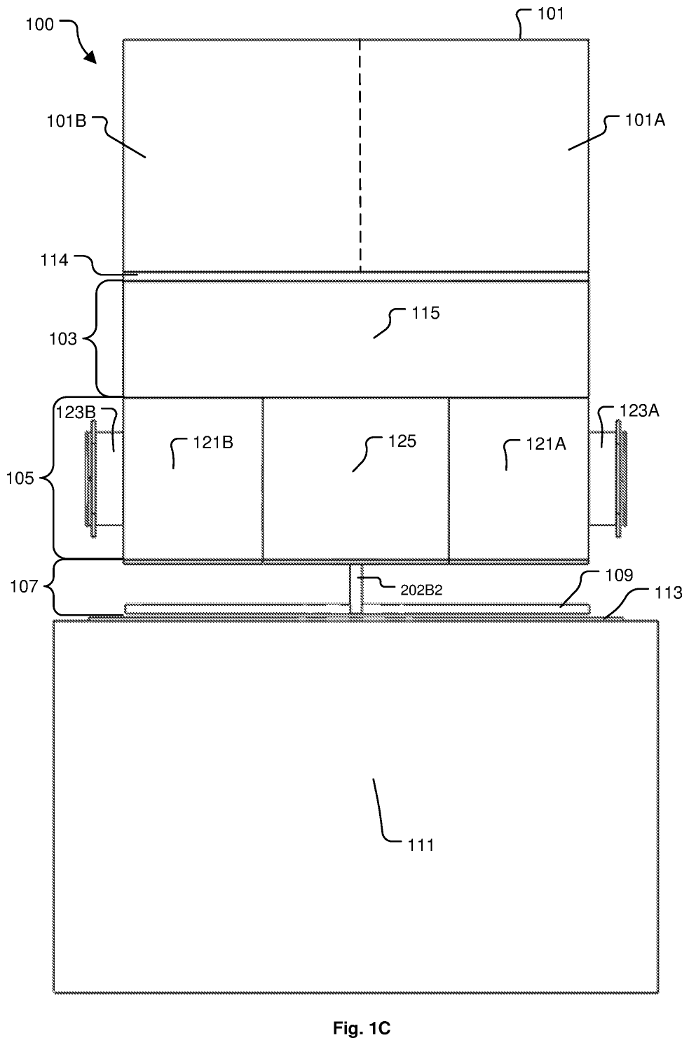

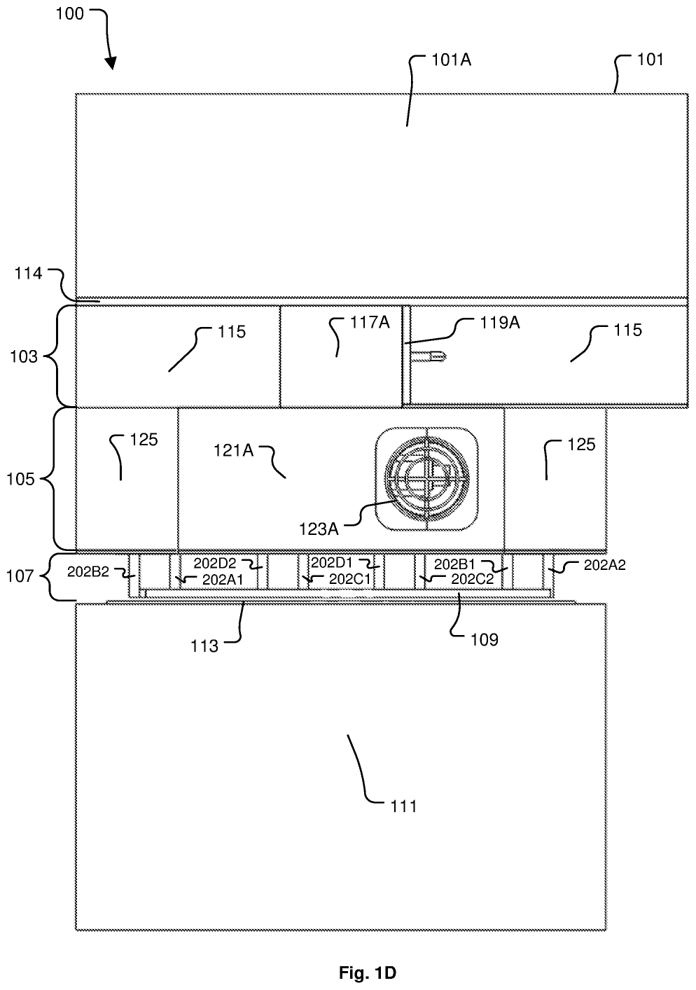

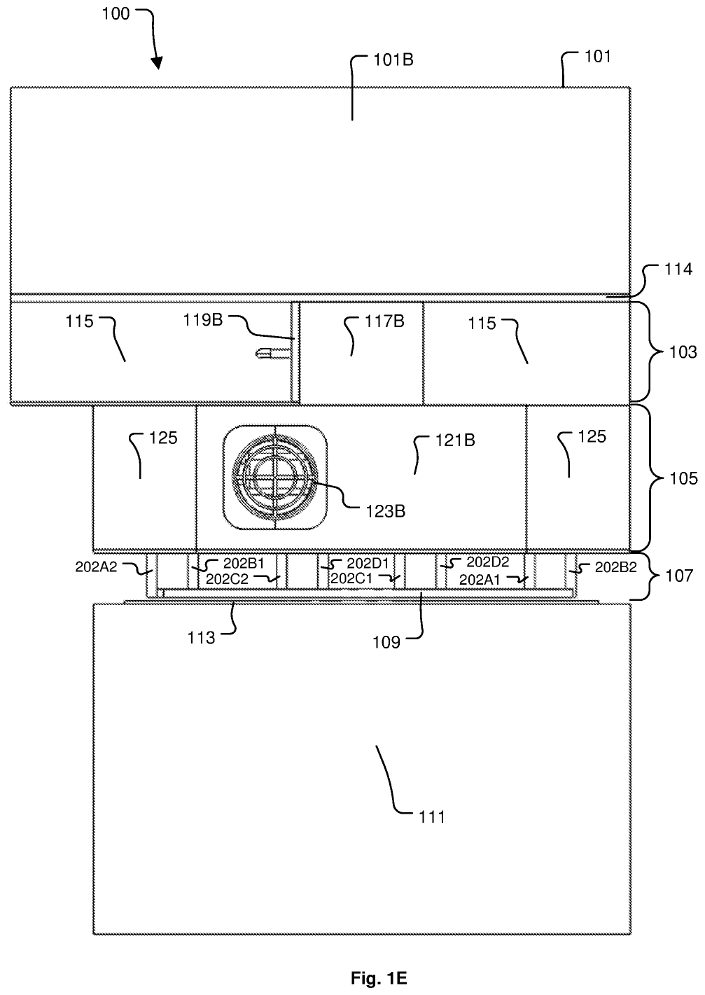

FIG. 1A shows an isometric view of a plasma processing system 100 that includes a direct-drive radiofrequency (RF) power supply 101, in accordance with some embodiments. FIG. 1B shows a front view of the plasma processing system 100, in accordance with some embodiments. FIG. 1C shows a back view of the plasma processing system 100, in accordance with some embodiments. FIG. 1D shows a left-side view of the plasma processing system 100, in accordance with some embodiments. FIG. 1E shows a right-side view of the plasma processing system 100, in accordance with some embodiments.

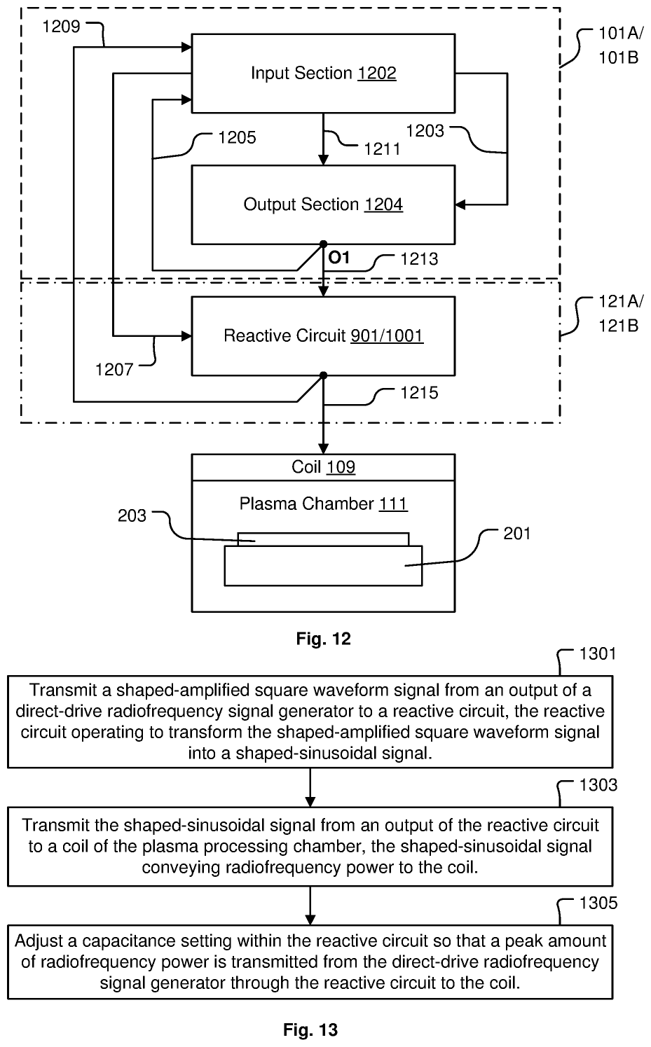

The direct-drive RF power supply 101 is configured to generate and deliver RF power to a plasma processing chamber 111 without having to transmit RF signals through an RF cable and an impedance matching network in route to the plasma processing chamber 111. The direct-drive RF power supply 101 is also referred to as a matchless plasma source (MPS). In the example embodiment of FIGS. 1A-IE, the direct-drive RF power supply 101 is connected to deliver RF power to a coil assembly 109 disposed above a window 113 of the plasma processing chamber 111. In various embodiments, the window 113 is formed of a dielectric material, such as quartz, that allows RF power to be transmitted from the coil assembly 109 through the window 113 and into the plasma processing chamber 111. As the RF power is transmitted into and through the plasma processing chamber 111, the RF power transforms a process gas into a plasma within the plasma processing chamber 111 in exposure to a semiconductor wafer that is supported within the plasma processing chamber 111. In various embodiments, the plasma is used to provide controlled modification of a condition of the semiconductor wafer, such as through material deposition and/or material removal and/or material implantation and/or material modification, etc. Also, in some embodiments, a plasma is generated in the plasma processing chamber 111 to provide for cleaning of the plasma processing chamber 111. The direct-drive RF power supply 101 is described in detail below with regard to FIGS. 12 through 17D. For the present discussion, it should be understood that the direct-drive RF power supply 101 is configured to generate RF signals having a prescribed waveform as a function of time, and deliver the generated RF signals to the coil assembly 109.

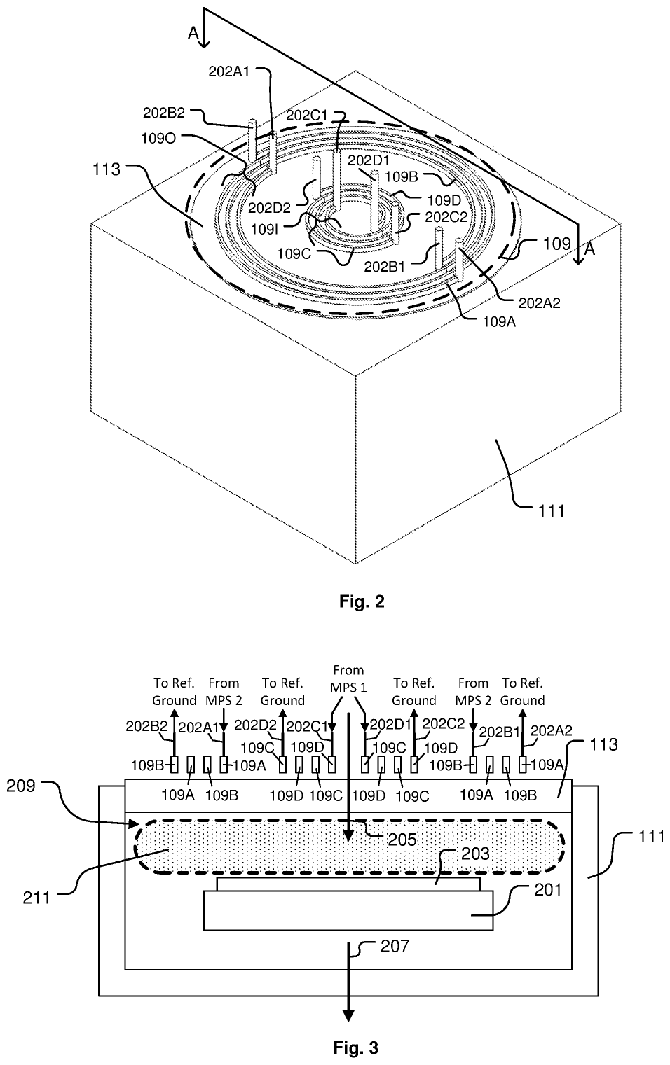

FIG. 2 shows a top view of the coil assembly 109, in accordance with some embodiments. In some embodiments, the coil assembly 109 includes an outer coil 109O that includes a first outer coil winding 109A and a second outer coil winding 109B. In some embodiments, the first outer coil winding 109A and second outer coil winding 109B are interleaved with each other so as to be positioned in an alternating sequence relative to a radial direction extending horizontally outward from the center of the of the coil assembly 109. A first end of the first outer coil winding 109A is connected to receive RF power from the direct-drive RF power supply 101 through a connector 202A1. A second end of the first outer coil winding 109A is connected to a reference ground potential through a connector 202A2. A first end of the second outer coil winding 109B is connected to receive RF power from the direct-drive RF power supply 101 through a connector 202B1. A second end of the second outer coil winding 109B is connected to a reference ground potential through a connector 202B2. In some embodiments, the coil assembly 109 includes an inner coil 109I that includes a first inner coil winding 109C and a second inner coil winding 109D. In some embodiments, the first inner coil winding 109C and second inner coil winding 109D are interleaved with each other so as to be positioned in an alternating sequence relative to a radial direction extending horizontally outward from the center of the of the coil assembly 109. A first end of the first inner coil winding 109C is connected to receive RF power from the direct-drive RF power supply 101 through a connector 202C1. A second end of the first inner coil winding 109C is connected to a reference ground potential through a connector 202C2. A first end of the second inner coil winding 109D is connected to receive RF power from the direct-drive RF power supply 101 through a connector 202D1. A second end of the second inner coil winding 109D is connected to a reference ground potential through a connector 202D2. It should be understood that the coil assembly 109 is shown by way of example. In various embodiments, the coil assembly 109 can include a single coil winding or multiple coil windings. Also, in various embodiments, the multiple windings of the coil assembly 109 can be arranged into multiple, e.g., 2, 3, 4, etc., coil regions, such as the inner coil 109I region and the outer coil 109O region as shown in FIG. 2. In some embodiments, each coil winding in the coil assembly 109 is connected to receive RF power from the direct-drive RF power supply 101, regardless of the coil assembly 109 configuration.

In some embodiments, the direct-drive RF power supply 101 includes a plurality of direct-drive RF signal generators that independently generate and supply RF signals to different portions of the coil assembly 109. For example, in some embodiments, such as shown in FIGS. 1A-IE, the direct-drive RF power supply 101 includes a first direct-drive RF signal generator 101A and a second direct-drive RF signal generator 101B. The first direct-drive RF signal generator 101A is connected to generate and supply RF signals to the first outer coil winding 109A and the second outer coil winding 109B of the coil assembly 109. The second direct-drive RF signal generator 101B is connected to generate and supply RF signals to the first inner coil windings 109C and the second inner coil winding 109D of the coil assembly 109. It should be understood that in various embodiments the direct-drive RF power supply 101 includes more than two direct-drive RF signal generators for generating and supplying RF signals to more than two coils, respectively, within the coil assembly 109, where each coil in the coil assembly 109 includes one or more coil windings. Also, in some embodiments, the direct-drive RF power supply 101 includes a single direct-drive RF signal generator for generating and supplying RF signals to a single coil within the coil assembly 109, where the single coil includes one or more coil windings.

In some embodiments, such as shown in FIGS. 1A-1E, the direct-drive RF power supply 101 is disposed above the plasma processing chamber 111, with the direct-drive RF power supply 101 being separated from the plasma processing chamber 111 by a metrology level 103, an RF power junction level 105, and a coil assembly level 107. In some embodiments, the metrology level 103 is located vertically between the direct-drive RF power supply 101 and the junction box level 105, with the coil assembly level 107 located below the junction box level 105. The metrology level 103 includes a metrology enclosure 115. In some embodiments, the metrology enclosure 115 has a T-shaped interior volume when viewed from above the metrology enclosure 115. In various embodiments, metrology equipment, e.g., optical metrology equipment, thermal metrology equipment, electrical metrology equipment, etc., is disposed within the interior volume of the metrology enclosure 115. It should be understood that this provides for positioning metrology equipment in close proximity to the plasma processing chamber 111 and coil assembly 109, which provides for simplification of metrology equipment deployment and connectivity. In some embodiments, a platform 114 is disposed over the metrology enclosure 115. The platform 114 provides a base structure to support the direct-drive RF power supply 101.

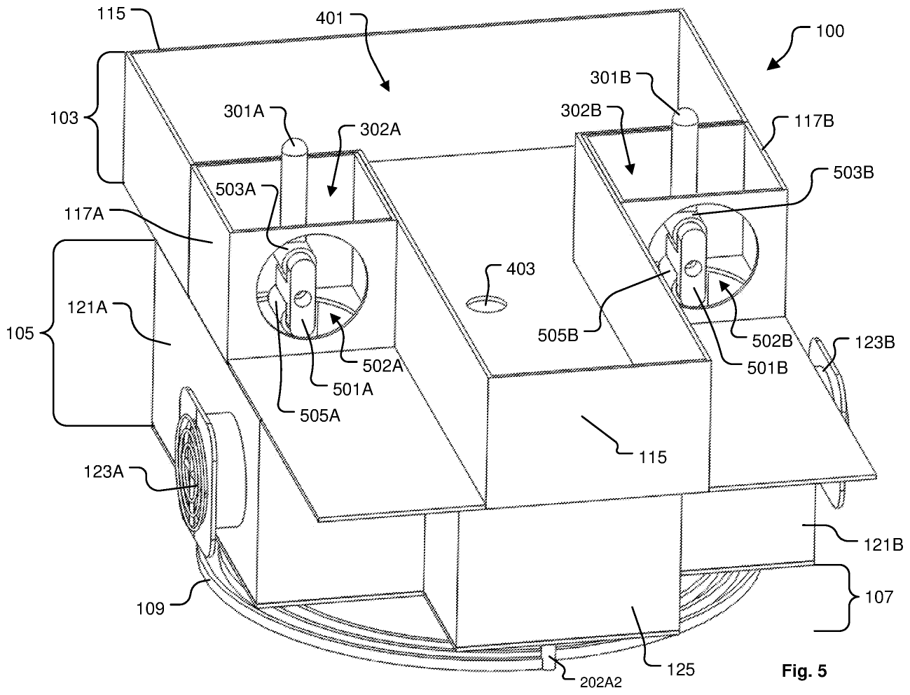

In some embodiments, the metrology level 103 also includes a first RF connection enclosure 117A and a second RF connection enclosure 117B. The first RF connection enclosure 117A is formed to provide a protected region within and through which RF connection structures are disposed to provide for transmission of RF power from the first direct-drive RF signal generator 101A to the outer coil 109O of the coil assembly 109. A removable door 119A is provided to cover an access opening 502A (see FIG. 5) into the region within the first RF connection enclosure 117A. The second RF connection enclosure 117B is formed to provide a protected region within and through which RF connection structures are disposed to provide for transmission of RF power from the second direct-drive RF signal generator 101B to the inner coil 109I of the coil assembly 109. A removable door 119B is provided to cover an access opening 502B (see FIG. 5) into the region within the second RF connection enclosure 117B.

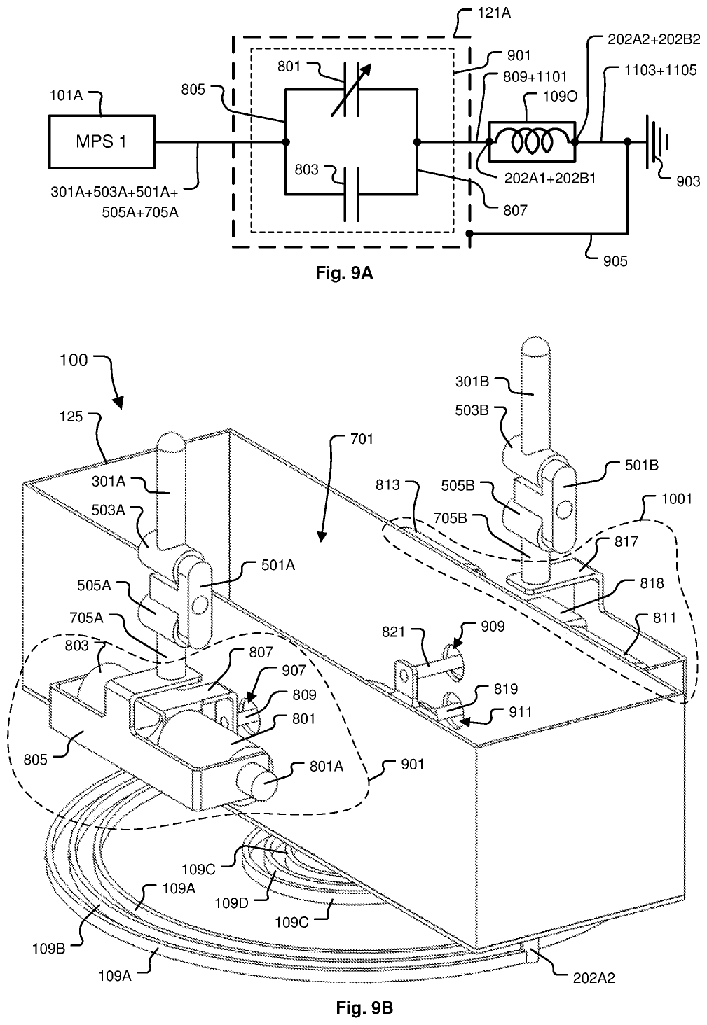

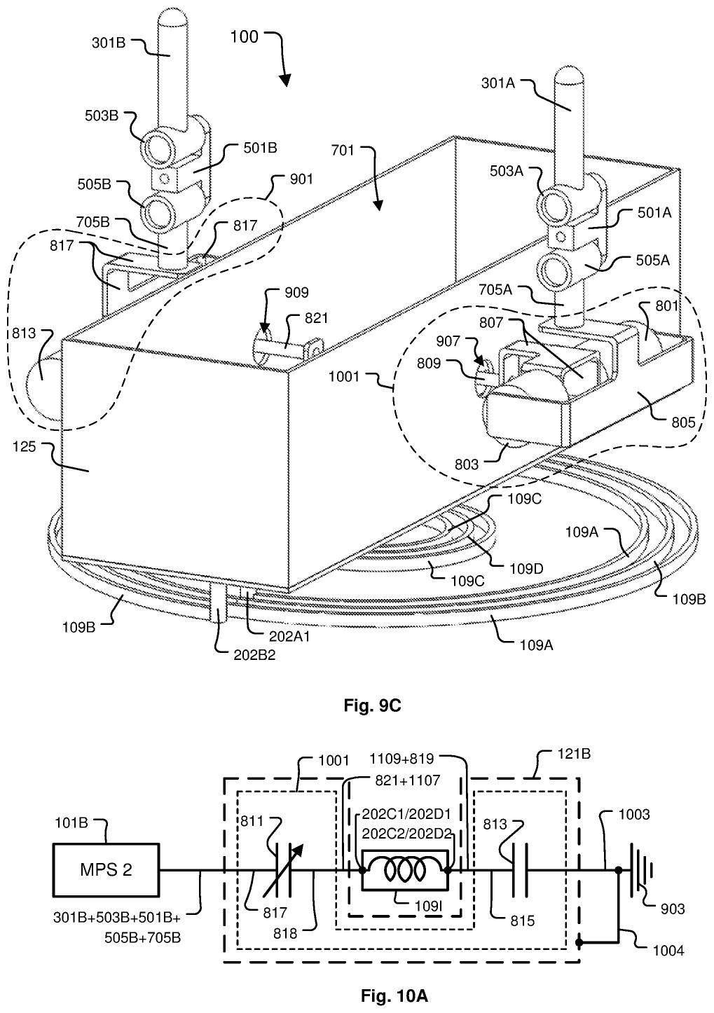

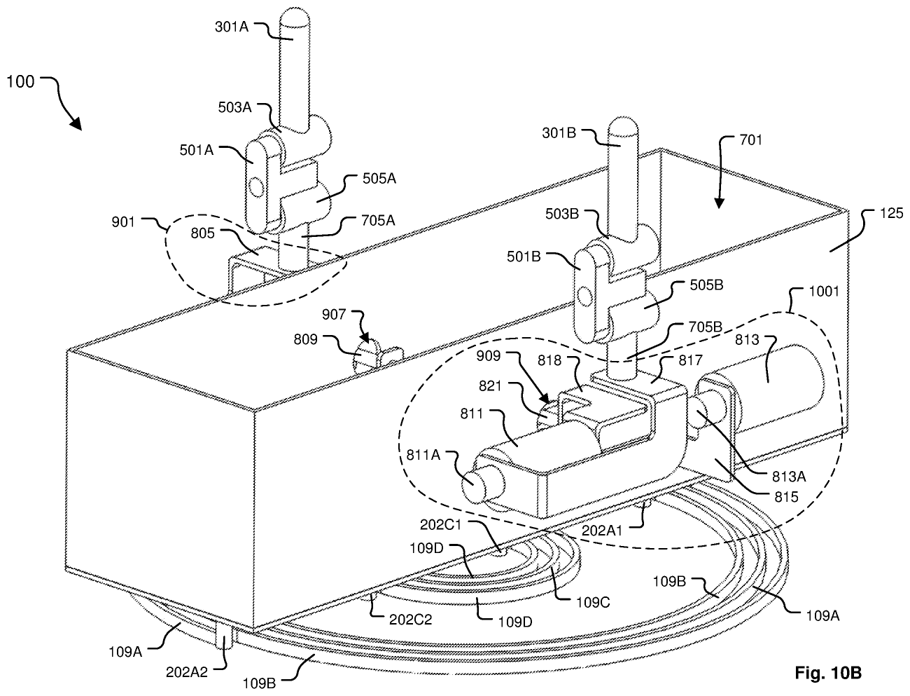

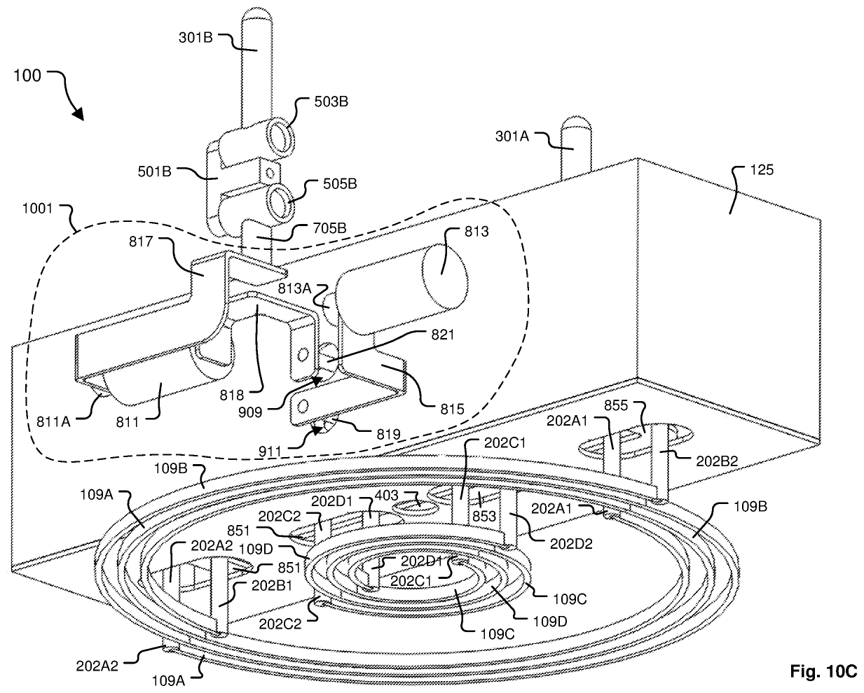

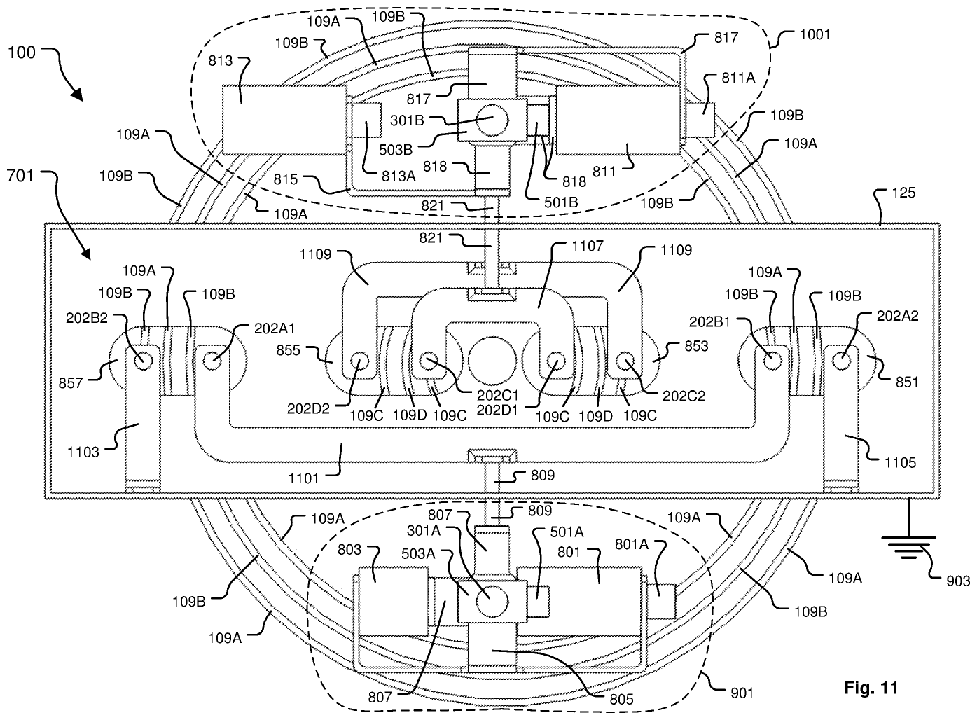

The junction box level 105 includes a first junction box 121A, a second junction box 121B, and a coil connection enclosure 125. In some embodiments, the coil connection enclosure 125 is substantially centered on the plasma processing chamber 111 and is correspondingly substantially centered on the coil assembly 109 disposed above the window 113 of the plasma processing chamber 111. The first junction box 121A includes an interior region in which a first reactive circuit 901 (see FIG. 9) is disposed, with the first reactive circuit 901 being connected between the first direct-drive RF signal generator 101A and the outer coil 109O of the coil assembly 109. The second junction box 121B includes an interior region in which a second reactive circuit 1001 (see FIG. 10) is disposed, with the second reactive circuit 1001 being connected between the second direct-drive RF signal generator 101B and the inner coil 109I of the coil assembly 109. The coil connection enclosure 125 includes an interior region in which a first conductive structure 1101 (see FIG. 11) is disposed to electrically connect the first reactive circuit 901 to the outer coil 109O of the coil assembly 109, and in which a second conductive structure 1107 (see FIG. 11) is disposed to electrically connect the second reactive circuit 1001 to the inner coil 109I of the coil assembly 109. The coil connection enclosure 125 also houses a third conductive structure 1103 (see FIG. 11) and a fourth conductive structure 1105 (see FIG. 11) to provide for electrical connection of the outer coil 109O of the coil assembly 109 to a reference ground potential, such as to the reference ground potential that exists on the walls of the coil connection enclosure 125. The coil connection enclosure 125 also houses a fifth conductive structure 1109 (see FIG. 11) to provide a ground return electrical connection from the inner coil 109I of the coil assembly 109 to second reactive circuit 1001.

In some embodiments, the first junction box 121A is equipped with a fan 123A to circulate air through the interior region of the first junction box 121A to maintain cooling of components within the first reactive circuit 901. Similarly, in some embodiments, the second junction box 121B is equipped with a fan 123B to circulate air through the interior region of the second junction box 121B to maintain cooling of components within the second reactive circuit 1001. Also, in some embodiments, the first junction box 121A includes an access port 707A through which a device or tool can be disposed to provide for adjustment of one or more of component(s) within the first reactive circuit 901, such as to provide for adjustment of a setting of a variable capacitor within the first reactive circuit 901. Similarly, in some embodiments, the second junction box 121B includes an access port 707B through which a device or tool can be disposed to provide for adjustment of one or more of component(s) within the second reactive circuit 1001, such as to provide for adjustment of a setting of a variable capacitor within the second reactive circuit 1001.

FIG. 3 shows a diagram of a vertical cross-section taken through the plasma processing chamber 111, in accordance with some embodiments. The vertical cross-section diagram of FIG. 3 corresponds to the View A-A as referenced in FIG. 2. It should be understood that the vertical cross-section diagram of FIG. 3 depicts a simplified representation of the plasma processing chamber 111. In various embodiments, the plasma processing chamber 111 includes other components and features that are not shown in FIG. 3, in order to avoid unnecessarily obscuring the relevant description of the plasma processing chamber 111. Also, in various embodiments, the components that are depicted in FIG. 3 can be shaped, positioned, and oriented in ways that differ from their particular representation in FIG. 3, without departing from their intended purpose as discussed herein. The plasma processing chamber 111 includes a substrate support 201, e.g., an electrostatic chuck, on which a substrate 203, e.g., a semiconductor wafer, is supported during plasma processing of the substrate 203. During operation of the plasma processing chamber 111, a process gas is flowed into a processing region 209 within the plasma processing chamber 111, as indicated by arrow 205. Also, during operation of the plasma processing chamber 111, RF power is supplied from the first direct-drive RF signal generator 101A to the outer coil 109O and/or from the second direct-drive RF signal generator 101B to the inner coil 109I. The RF power is transmitted from the inner coil 109I and/or outer coil 109O through the window 113 and through the processing region 209 within the plasma processing chamber 111.

Within the processing region 209, the RF power causes the process gas to transform into a plasma 211 in exposure to the substrate 203 supported on the substrate support 201. Also, during operation of the plasma processing chamber 111, exhaust gases and by-product materials from processing of the substrate 203 are exhausted from the plasma processing chamber 111, as indicated by arrow 207. It should be understood that in various embodiments operation of the plasma processing chamber 111 can include many other additional operations, such as generating a bias voltage at the substrate 203 level to attract or repel electrically charged constituents of the plasma 211 toward or away from the substrate 203, and/or controlling a temperature of the substrate 203, and/or applying additional RF power to one or more electrode(s) disposed within the substrate support 201 to generate additional plasma 211, among other additional operations. Also, in various embodiments, the plasma processing chamber 111 is operated in accordance with a prescribed recipe that specifies a temporal schedule for controlling one or more of: supply of process gas(es) to the processing region 209, pressure and temperature within the processing region 209, supply of RF power to the inner coil 109I and/or outer coil 109O, supply of bias voltage at the substrate 203 level, supply of RF power to electrode(s) within the substrate holder 201, among essentially any other process parameter associated with plasma processing of the substrate 203.

A first upper RF connection structure 301A extends from the region within the first RF connection enclosure 117A through the platform 114 to connect with an RF supply output of the first direct-drive RF signal generator 101A. The first upper RF connection structure 301A is formed of electrically conductive material over which RF power is readily transmitted. In some embodiments, an RF insulator structure 303A is disposed between the first upper RF connection structure 301A and the platform 114 to prevent RF power from coupling to the platform 114. In some embodiments, instead of the RF insulator structure 303A, an open space is maintained between the first upper RF connection structure 301A and the platform 114 to prevent RF power from coupling to the platform 114. In some embodiments, a combination of open space and a variation of the RF insulator structure 303A is provided between the first upper RF connection structure 301A and the platform 114 to prevent RF power from coupling to the platform 114. A second upper RF connection structure 301B extends from the region within the second RF connection enclosure 117B through the platform 114 to connect with an RF supply output of the second direct-drive RF signal generator 101B. The second upper RF connection structure 301B is formed of electrically conductive material over which RF power is readily transmitted. In some embodiments, an RF insulator structure 303B is disposed between the second upper RF connection structure 301B and the platform 114 to prevent RF power from coupling to the platform 114. In some embodiments, instead of the RF insulator structure 303B, an open space is maintained between the second upper RF connection structure 301B and the platform 114 to prevent RF power from coupling to the platform 114. In some embodiments, a combination of open space and a variation of the RF insulator structure 303B is provided between the second upper RF connection structure 301B and the platform 114 to prevent RF power from coupling to the platform 114.

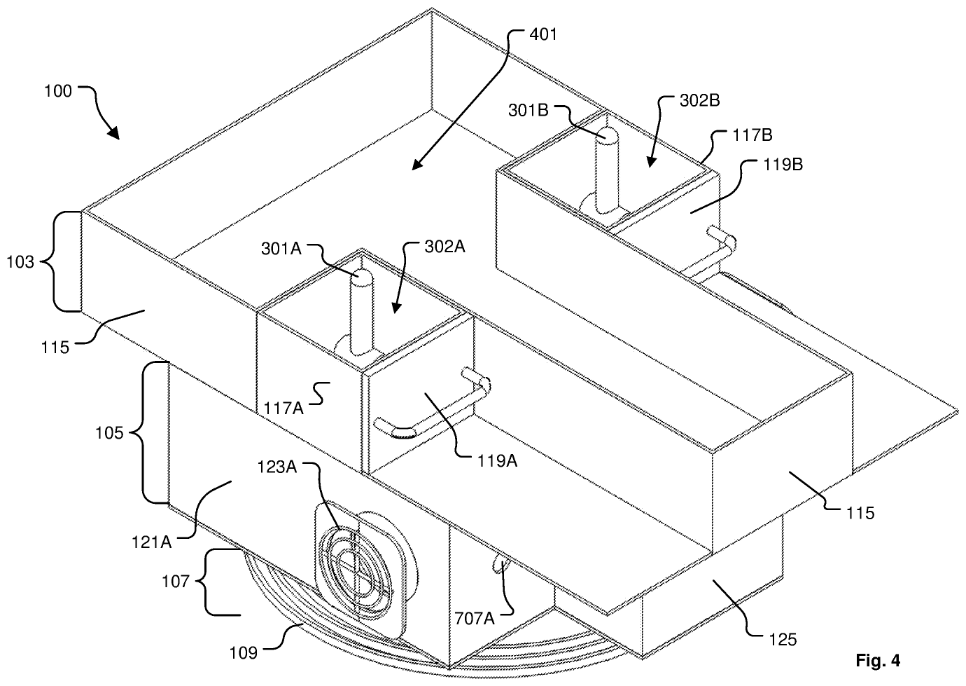

FIG. 4 shows an isometric view of the plasma processing system 100 with the platform 114 removed to reveal the region 302A within the first RF connection enclosure 117A, the region 302B within the second RF connection enclosure 117B, and the T-shaped interior region 401 of the metrology enclosure 115, in accordance with some embodiments. As previously mentioned, in various embodiments, metrology equipment such as optical metrology equipment, and/or thermal metrology equipment, and/or electrical metrology equipment, among other types of metrology equipment is/are disposed within the T-shaped interior region 401 of the metrology enclosure 115. In some embodiments, a viewport 403 is formed through the bottom of the metrology enclosure 115 to provide an unobscured line-of-sight view through the window 113 into the processing region 209 within the plasma processing chamber 111. In some embodiments, the viewport 403 is used by an optical metrology device disposed within the interior region 401 of the metrology enclosure 115 to obtain a direct line-of-sight of the plasma 211 generated in the processing region 209 within the plasma processing chamber 111.

FIG. 5 shows a perspective view of the plasma processing system 100 looking toward the front of the plasma processing system 100 with the removable doors 119A and 119B removed, in accordance with some embodiments. Specifically, the removable door 119A is removed to reveal the access opening 502A into the region 302A within the first RF connection enclosure 117A. Similarly, the removable door 119B is removed to reveal the access opening 502B into the region 302B within the second RF connection enclosure 117B. In some embodiments, the first upper RF connection structure 301A extends downward to connect with a first upper coupling structure 503A. The first upper coupling structure 503A is formed of electrically conductive material over which RF power is readily transmitted. A first lower coupling structure 505A is positioned below a spaced apart from the first upper coupling structure 503A within the interior region 302A of the first RF connection enclosure 117A. The first lower coupling structure 505A is formed of electrically conductive material over which RF power is readily transmitted. In some embodiments, each of the first upper coupling structure 503A and the first lower coupling structure 505A is formed to have as substantially annular cylindrical shape with a corresponding cylindrical axis positioned in a substantially horizontal orientation pointed toward the access opening 502A of the first RF connection enclosure 117A.

A first RF jumper structure 501A is configured to insert into both the first upper coupling structure 503A and the first lower coupling structure 505A to establish an electrical connection between the first upper coupling structure 503A and the first lower coupling structure 505A. The first RF jumper structure 501A is formed of electrically conductive material over which RF power is readily transmitted. In some embodiments, the first RF jumper structure 501A is configured to physically contact both the first upper coupling structure 503A and the first lower coupling structure 505A when the first RF jumper structure 501A is inserted into the openings of both the first upper coupling structure 503A and the first lower coupling structure 505A. In this manner, with the first RF jumper structure 501A simultaneously inserted into the openings of both the first upper coupling structure 503A and the first lower coupling structure 505A, RF power supplied to the first upper RF connection structure 301A from the first direct-drive RF signal generator 101A is transmitted over the first upper coupling structure 503A to first RF jumper structure 501A, and over the first RF jumper structure 501A to the first lower coupling structure 505A.

A second RF jumper structure 501B is configured to insert into both a second upper coupling structure 503B and a second lower coupling structure 505B to establish an electrical connection between the second upper coupling structure 503B and the second lower coupling structure 505B. The second RF jumper structure 501B is formed of electrically conductive material over which RF power is readily transmitted. In some embodiments, the second RF jumper structure 501B is configured to physically contact both the second upper coupling structure 503B and the second lower coupling structure 505B when the second RF jumper structure 501B is inserted into the openings of both the second upper coupling structure 503B and the second lower coupling structure 505B. In this manner, with the second RF jumper structure 501B simultaneously inserted into the openings of both the second upper coupling structure 503B and the second lower coupling structure 505B, RF power supplied to the second upper RF connection structure 301B from the second direct-drive RF signal generator 101B is transmitted over the second upper coupling structure 503B to second RF jumper structure 501B, and over the second RF jumper structure 501B to the second lower coupling structure 505B.

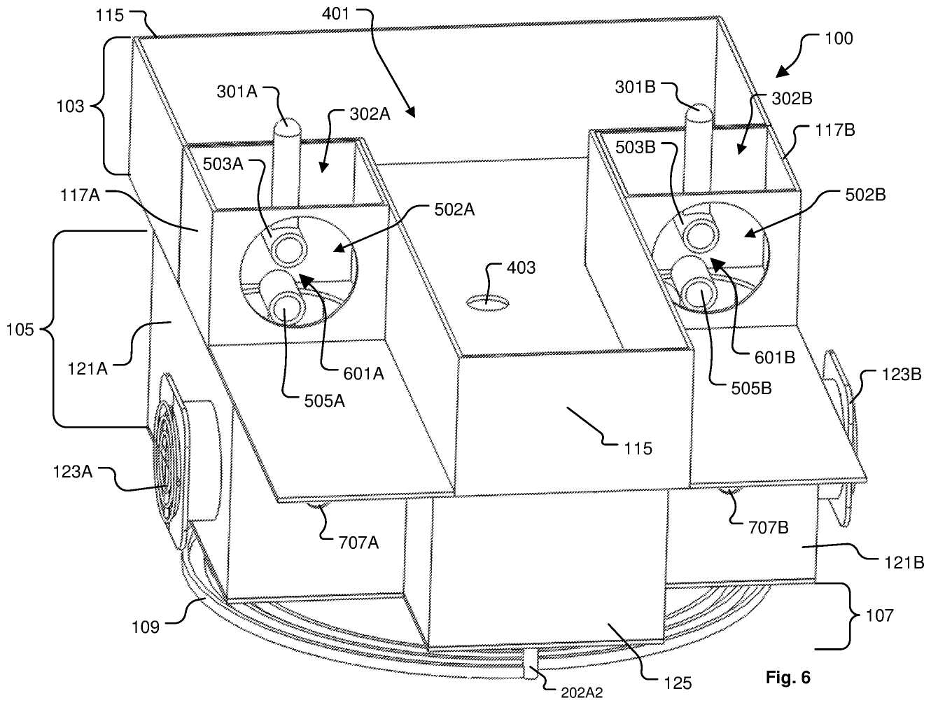

FIG. 6 shows the perspective view of the plasma processing system 100 of FIG. 5 with the first RF jumper structure 501A removed from both the first upper coupling structure 503A and the first lower coupling structure 505A, and with the second RF jumper structure 501B removed from both the second upper coupling structure 503B and the second lower coupling structure 505B, in accordance with some embodiments. In some embodiments, the first RF jumper structure 501A is accessible through the opening 502A of the first RF connection enclosure 117A for slidable removal from and insertion into both the first upper coupling structure 503A and the first lower coupling structure 505A. Similarly, in some embodiments, the second RF jumper structure 501B is accessible through the opening 502B of the first RF connection enclosure 117B for slidable removal from and insertion into both the second upper coupling structure 503B and the second lower coupling structure 505B. Removal of the first RF jumper structure 501A, as indicated by arrow 601A, serves to disconnect the first upper coupling structure 503A from the first lower coupling structure 505A so that RF power does not travel from the first upper coupling structure 503A to the first lower coupling structure 505A. Similarly, removal of the second RF jumper structure 501B, as indicated by arrow 601B, serves to disconnect the second upper coupling structure 503B from the second lower coupling structure 505B so that RF power does not travel from the second upper coupling structure 503B to the second lower coupling structure 505B.

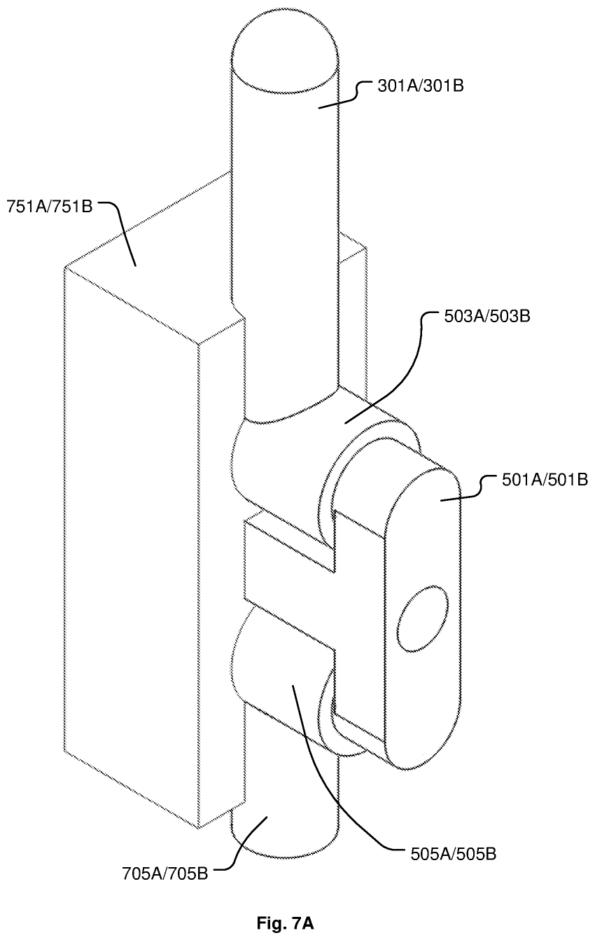

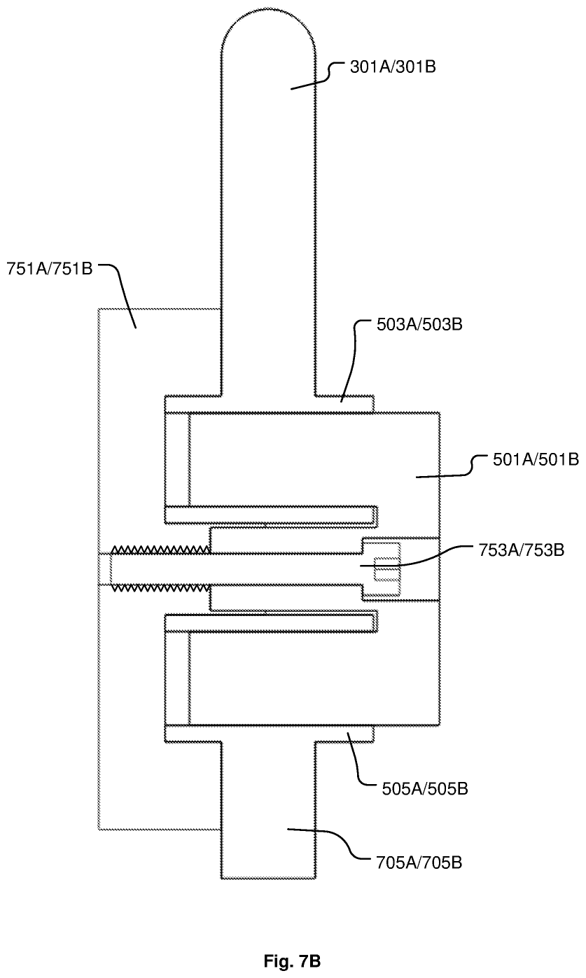

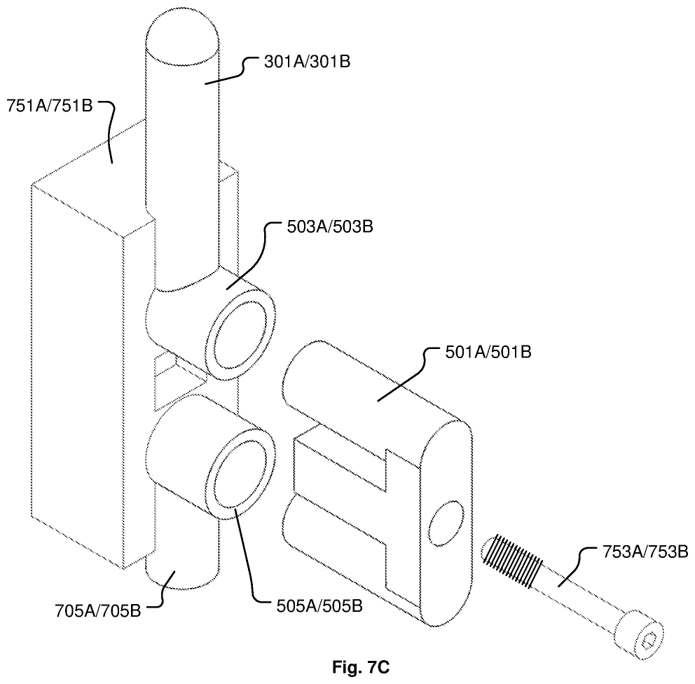

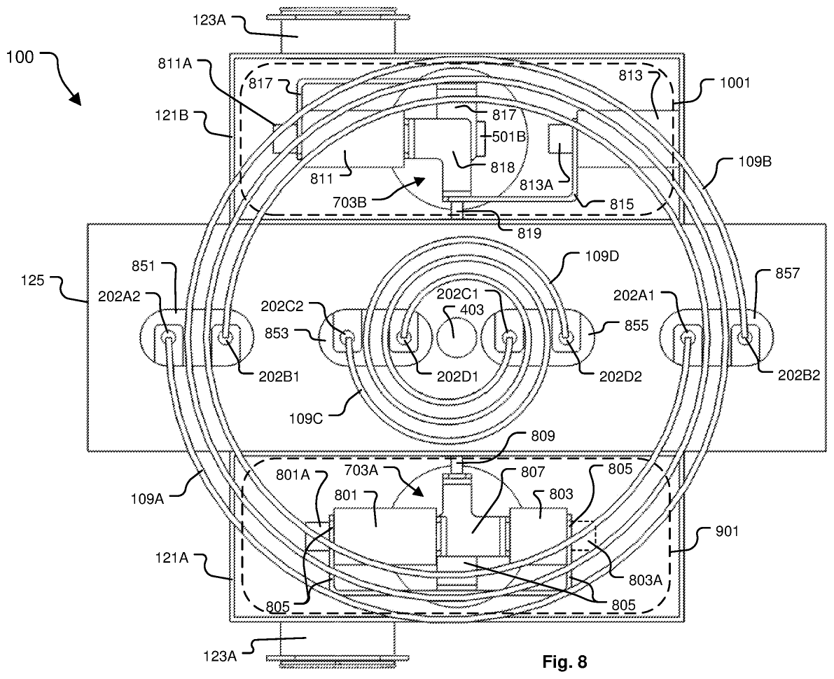

FIG. 7A shows a close-up isometric view of the first/second RF jumper structure 501A/501B simultaneously inserted into both the first/second upper coupling structure 503A/503B and the first/second lower coupling structure 505A/505B, in accordance with some embodiments. The first lower coupling structure 505A is connected to a first lower RF connection structure 705A that extends from the region 302A inside the first RF connection enclosure 117A to a region 703A (see FIG. 8) inside the first junction box 121A. The first lower RF connection structure 705A is formed of electrically conductive material over which RF power is readily transmitted. In some embodiments, the first lower RF connection structure 705A extends through an opening in the top of the first junction box 121A that is sized large enough to ensure that RF power is not coupled from the first lower RF connection structure 705A to the first junction box 121A walls. The second lower coupling structure 505B is connected to a second lower RF connection structure 705B that extends from the region 302B inside the second RF connection enclosure 117B to a region 703B (see FIG. 8) inside the second junction box 121B. The second lower RF connection structure 705B is formed of electrically conductive material over which RF power is readily transmitted. In some embodiments, the second lower RF connection structure 705B extends through an opening in the top of the second junction box 121B that is sized large enough to ensure that RF power is not coupled from the second lower RF connection structure 705B to the second junction box 121B walls.

In the example embodiment of FIG. 7A, the first RF jumper structure 501A is secured within the first upper coupling structure 503A and the first lower coupling structure 505A by a first bolt 753A that threads into a first dielectric bracket 751A. In the same manner, the second RF jumper structure 501A is secured within the second upper coupling structure 503B and the second lower coupling structure 505B by a second bolt 753B that threads into a second dielectric bracket 751B. For example, FIG. 7B shows a vertical cross-section view through the first/second RF jumper structure 501A/501B installation configuration of FIG. 7A, with the first/second bolt 753A/753B threaded into the first/second dielectric bracket 751A/751B, in accordance with some embodiments. The first/second dielectric bracket 751A/751B is formed by an electrical insulator material over which RF power does not easily travel. In some embodiments, the first dielectric bracket 751A is secured to both the first upper RF connection structure 301A and the first lower RF connection structure 705A. Similarly, in some embodiments, the second dielectric bracket 751B is secured to both the second upper RF connection structure 301B and the second lower RF connection structure 705B.

FIG. 7C shows an isometric view of the first/second bolt 753A/753B removed from the first/second dielectric bracket 751A/751B, with the first/second RF jumper structure 501A/501B removed from both the first/second upper coupling structures 503A/503B and the first/second lower coupling structures 505A/505B, in accordance with some embodiments. In some embodiments, the first dielectric bracket 751A is configured to maintain a spatial relationship between the first upper coupling structure 503A and the first lower coupling structure 505A when the first RF jumper structure 501A is removed from the first upper/lower coupling structures 503A/505A. Similarly, in some embodiments, the second dielectric bracket 751B is configured to maintain a spatial relationship between the second upper coupling structure 503B and the second lower coupling structure 505B when the second RF jumper structure 501B is removed from the second upper/lower coupling structures 503B/505B.

FIG. 8 shows a bottom view of the plasma processing system 100 with the bottom covers of the first junction box 121A and the second junction box 121B removed to show components of the first reactive circuit 901 and the second reactive circuit 1001, in accordance with some embodiments. The first junction box 121A includes the first reactive circuit 901, which is described below with regard to FIGS. 9A-9C. The first reactive circuit 901 includes a first capacitor 801 and a second capacitor 803. In some embodiments, the first capacitor 801 is a variable capacitor and the second capacitor 803 is a fixed capacitor. In some embodiments, the first capacitor 801 is a variable capacitor that includes a capacitance setting control 801A that is physically accessible through the access port 707A on the front wall of the first junction box 121A. In some embodiments, the capacitance setting control 801A is adjustable by using a tool, e.g., screwdriver, inserted through the access port 707A on the front wall of the first junction box 121A. In some embodiments, the capacitance setting control 801A includes a stepper motor that is connected to control the capacitance setting of the first capacitor 801, where the stepper motor is controlled by signals that are conveyed either electrically or wirelessly to the stepper motor, thereby enabling automated and/or remote adjustment of the capacitance setting control 801A.

An input terminal of the first capacitor 801 is electrically connected through a connection structure 805 to the first lower RF connection structure 705A. An input terminal of the second capacitor 803 is also electrically connected through the connection structure 805 to the first lower RF connection structure 705A. The connection structure 805 is formed of electrically conductive material over which RF power is readily transmitted. In some embodiments, the connection structure 805 is formed as an electrically conductive articulated strap structure. An output terminal of the first capacitor 801 is electrically connected through a connection structure 807 to a connector 809 that extends through an opening 907 (see FIG. 9B) from the region 703A inside the first junction box 121A to the region 701 inside the coil connection enclosure 125. The connector 809 is formed of electrically conductive material over which RF power is readily transmitted. An output terminal of the second capacitor 803 is also electrically connected through the connection structure 807 to the connector 809. The connection structure 807 is formed of electrically conductive material over which RF power is readily transmitted. In some embodiments, the connection structure 807 is formed as an electrically conductive articulated strap structure. The connector 809 is electrically connected to the first conductive structure 1101 disposed within the region 701 inside the coil connection enclosure 125 (see FIG. 11), such that the first reactive circuit 901 is electrically connected to the outer coil 109O of the coil assembly 109 through the connector 809 and the first conductive structure 1101. In this manner, RF power is transmitted from the first reactive circuit 901 to the outer coil 109O by way of the connection structure 807, the connector 809, and the first conductive structure 1101.

The second junction box 121B includes the second reactive circuit 1001, which is described below with regard to FIGS. 10A-10C. The second reactive circuit 1001 includes a first capacitor 811 and a second capacitor 813. In some embodiments, the first capacitor 811 is a variable capacitor and the second capacitor 813 is a fixed capacitor. In some embodiments, the first capacitor 811 is a variable capacitor and the second capacitor 813 is also a variable capacitor. In some embodiments, the first capacitor 811 is a variable capacitor that includes a capacitance setting control 811A that is physically accessible through the access port 707B on the front wall of the second junction box 121B. In some embodiments, the capacitance setting control 811A is adjustable by using a tool, e.g., screwdriver, inserted through the access port 707B on the front wall of the second junction box 121B. In some embodiments, the capacitance setting control 811A includes a stepper motor that is connected to control the capacitance setting of the first capacitor 811, where the stepper motor is controlled by signals that are conveyed either electrically or wirelessly to the stepper motor, thereby enabling automated and/or remote adjustment of the capacitance setting control 811A. In some embodiments, the second capacitor 813 is a variable capacitor that includes a capacitance setting control 813A that is physically accessible through the access port 707B on the front wall of the second junction box 121B. In some embodiments, the capacitance setting control 813A is adjustable by using a tool, e.g., screwdriver, inserted through the access port 707B on the front wall of the second junction box 121B or through another access port formed through some wall of the second junction box 121B. In some embodiments, the capacitance setting control 813A includes a stepper motor that is connected to control the capacitance setting of the second capacitor 813, where the stepper motor is controlled by signals that are conveyed either electrically or wirelessly to the stepper motor, thereby enabling automated and/or remote adjustment of the capacitance setting control 813A.

An input terminal of the first capacitor 811 is electrically connected through a connection structure 817 to the second lower RF connection structure 705B (see FIG. 9B). The connection structure 817 is formed of electrically conductive material over which RF power is readily transmitted. In some embodiments, the connection structure 817 is formed as an electrically conductive articulated strap structure. An output terminal of the first capacitor 811 is electrically connected through a connection structure 818 to a connector 821 (see FIG. 9B) that extends through an opening 909 (see FIG. 9B) from the region 703B inside the second junction box 121B to the region 701 inside the coil connection enclosure 125. The connector 821 is formed of electrically conductive material over which RF power is readily transmitted. The connector 821 is electrically connected to the second conductive structure 1107 disposed within the region 701 inside the coil connection enclosure 125 (see FIG. 11), such that the second reactive circuit 1001 is electrically connected to the inner coil 109I of the coil assembly 109 through the connector 821 and the second conductive structure 1107. In this manner, RF power is transmitted from the second reactive circuit 1001 to the inner coil 109I by way of the connection structure 817, the connector 821, and the second conductive structure 1107.

An input terminal of the second capacitor 813 is electrically connected to a connection structure 815. The connection structure 815 is electrically connected to a connector 819. The connector 819 extends through an opening 911 from the region 703B inside the second junction box 121B to the region 701 inside the coil connection enclosure 125. The connector 819 is electrically connected to the fifth conductive structure 1109 disposed within the region 701 inside the coil connection enclosure 125 (see FIG. 11), such that a ground return electrical connection extends from the inner coil 109I of the coil assembly 109 through second reactive circuit 1001. Each of the connection structure 815 and the connector 819 is formed of electrically conductive material over which RF power is readily transmitted. In some embodiments, the connection structure 815 is formed as an electrically conductive articulated strap structure. An output terminal of the second capacitor 813 is also electrically connected to a reference ground potential 903. In some embodiments, the output terminal of the second capacitor 813 is electrically connected to the wall of the second junction box 121B, where the wall of the second junction box 121B is electrically connected to the reference ground potential 903. In some embodiments, the output terminal of the second capacitor 813 is physically attached to the wall of the second junction box 121B.

FIG. 9A shows a circuit schematic depicting transmission of RF power from the first direct-drive RF signal generator 101A through the first reactive circuit 901 to the outer coil 109O of the coil assembly 109, in accordance with some embodiments. The circuit schematic of FIG. 9A shows the input terminals of the first capacitor 801 and a second capacitor 803 electrically connected to the output of the first direct-drive RF signal generator 101A through a combination of the first upper RF connection structure 301A, the first upper coupling structure 503A, the first RF jumper structure 501A, the first lower coupling structure 505A, the first lower RF connection structure 705A, and the connection structure 805. The circuit schematic of FIG. 9A also shows the output terminals of the first capacitor 801 and a second capacitor 803 electrically connected to the RF supply ends of the outer coil 109O through a combination of the connection structure 807, the connector 809, the first conductive structure 1101, and the connectors 202A1 and 202B1. The circuit schematic of FIG. 9A also shows the ground return ends of the outer coil 109O electrically connected to the reference ground potential 903 through a combination of the connector 202A2, the third conductive structure 1103 (see FIG. 11), the connector 202B2, and the fourth conductive structure 1105 (see FIG. 11). The circuit schematic of FIG. 9A also shows the walls of the first junction box 121A electrically connected to the reference ground potential 903 through an electrical connection 905. The combination of the first capacitor 801 and a second capacitor 803 effectively cancels the series inductance of the outer coil 109O to provide a series resonance in order to make the load seen by the first direct-drive RF signal generator 101A real.

FIG. 9B shows an isometric view of a portion of the plasma processing system 100, from a front-left-upper point of view, with the walls of the first junction box 121A removed to reveal the components of the first reactive circuit 901 and with the walls of the second junction box 121B removed to reveal the components of the second reactive circuit 1001, in accordance with some embodiments. An open region 701 exists inside the coil connection enclosure 125. FIG. 9C shows an isometric view of the plasma processing system 100 as shown in FIG. 9B, from a back-left-upper point of view, in accordance with some embodiments.

FIG. 10A shows a circuit schematic depicting transmission of RF power from the second direct-drive RF signal generator 101B through the second reactive circuit 1001 to the inner coil 109I of the coil assembly 109, in accordance with some embodiments. The circuit schematic of FIG. 10A shows the input terminal of the first capacitor 811 electrically connected to the output of the second direct-drive RF signal generator 101B through a combination of the second upper RF connection structure 301B, the second upper coupling structure 503B, the second RF jumper structure 501B, the second lower coupling structure 505B, the first lower RF connection structure 705B, and the connection structure 817. The circuit schematic of FIG. 10A also shows the output terminal of the first capacitor 811 electrically connected to the RF supply ends of the inner coil 109I through a combination of the connection structure 818, the connector 821, the second conductive structure 1107, and the connectors 202C1 and 202C1. The circuit schematic of FIG. 10A also shows the ground return ends of the inner coil 109I electrically connected to the input terminal of the second capacitor 813 through a combination of the connectors 202C2 and 202D2, the fifth conductive structure 1109 (see FIG. 11), the connector 819, and the connection structure 815. The circuit schematic of FIG. 10A also shows the output terminal of the second capacitor 813 electrically connected to the reference ground potential 903 through an electrical connection 1003. The circuit schematic of FIG. 10A also shows the walls of the second junction box 121B electrically connected to the reference ground potential 903 through an electrical connection 1004.

The capacitor 811 effectively cancels the series inductance of the inner coil 109I to provide a series resonance in order to make the load seen by the second direct-drive RF signal generator 101B real. Also, the capacitor 813 provides for balancing of the inner coil 109I so that the voltages at the two ends of first inner coil winding 109C are out of phase with respect to the reference ground potential 903 (meaning that these end voltages are at about one-half of the voltage with respect to the reference ground potential) and so that the voltages at the two ends of second inner coil winding 109D are also out of phase with respect to the reference ground potential 903 (meaning that these end voltages are at about one-half of the voltage with respect to the reference ground potential). This balancing of the inner coil 109I by the capacitor 813 helps prevent damage to the window 113 caused by plasma 211 sputtering because the voltage difference between the terminals of the inner coil 109I and the plasma 211 is reduced.

FIG. 10B shows an isometric view of a portion of the plasma processing system 100, from a front-right-upper point of view, with the walls of the first junction box 121A removed to reveal the components of the first reactive circuit 901 and with the walls of the second junction box 121B removed to reveal the components of the second reactive circuit 1001, in accordance with some embodiments. FIG. 10C shows an isometric view of the plasma processing system 100 as shown in FIG. 10B, from a back-right-lower point of view, in accordance with some embodiments.

FIG. 11 shows a top view of a portion of the plasma processing system 100, with the walls of the first junction box 121A removed to reveal the components of the first reactive circuit 901 and with the walls of the second junction box 121B removed to reveal the components of the second reactive circuit 1001, in accordance with some embodiments. The first conductive structure 1101 disposed within the region 701 inside the coil connection enclosure 125 is configured to electrically connect the connector 809 to each of the connectors 202A1 and 202B1. In this manner RF power is supplied from the first reactive circuit 901 over the first conductive structure 1101 to the RF supply ends of the first outer coil winding 109A and second outer coil winding 109B of the outer coil 109O. The second conductive structure 1107 disposed within the region 701 inside the coil connection enclosure 125 is configured to electrically connect the connector 821 to each of the connectors 202C1 and 202D1. In this manner RF power is supplied from the second reactive circuit 1001 over the second conductive structure 1107 to the RF supply ends of the first inner coil winding 109C and second inner coil winding 109D of the inner coil 109I. The third conductive structure 1103 disposed within the region 701 inside the coil connection enclosure 125 is configured to electrically connect the ground return end of the first outer coil winding 109A to the reference ground potential 903 by way of the coil connection enclosure 125. Similarly, the fourth conductive structure 1105 disposed within the region 701 inside the coil connection enclosure 125 is configured to electrically connect the ground return end of the second outer coil winding 109B to the reference ground potential 903 by way of the coil connection enclosure 125. The fifth conductive structure 1109 disposed within the region 701 inside the coil connection enclosure 125 is configured to electrically connect the connector 819 to each of the connectors 202C2 and 202D2. In this manner, an RF ground return path is provided from the ground return ends of the first inner coil winding 109C and the second inner coil winding 109D over the fifth conductive structure 1109 to the input terminal of the second capacitor 813 within the second reactive circuit 1001.

FIG. 11 also shows an opening 851 formed in the bottom the coil connection enclosure 125 through which the connectors 202A2 and 202B1 extend to connected with the outer coil 109O. An opening 853 is also formed in the bottom the coil connection enclosure 125 through which the connectors 202C2 and 202D1 extend to connected with the inner coil 109I. An opening 855 is also formed in the bottom the coil connection enclosure 125 through which the connectors 202C1 and 202D2 extend to connected with the inner coil 109I. An opening 857 is also formed in the bottom the coil connection enclosure 125 through which the connectors 202A1 and 202B2 extend to connected with the outer coil 109O.

FIG. 12 shows a schematic of how each of the first direct-drive RF signal generator 101A and the second direct-drive RF signal generator 101B is connected through the corresponding first reactive circuit 901 or second reactive circuit 1001 to the coil assembly 109, in accordance with some embodiments. Each of the first direct-drive RF signal generator 101A and the second direct-drive RF signal generator 101B includes an input section 1202 and an output section 1204. The input section 1202 is electrically connected to the output section 1204, as indicated by the arrow 1211. For the first direct-drive RF signal generator 101A, the output section 1204 is electrically connected to the first reactive circuit 901, as indicated by the arrow 1213. For the first direct-drive RF signal generator 101A, the arrow 1213 represents the combination of the first upper RF connection structure 301A, the first upper coupling structure 503A, the first RF jumper structure 501A, the first lower coupling structure 505A, and the first lower RF connection structure 705A. For the second direct-drive RF signal generator 101B, the output section 1204 is electrically connected to the second reactive circuit 1001, as indicated by the arrow 1213. For the second direct-drive RF signal generator 101B, the arrow 1213 represents the combination of the second upper RF connection structure 301B, the second upper coupling structure 503B, the second RF jumper structure 501B, the second lower coupling structure 505B, and the second lower RF connection structure 705B. The first reactive circuit 901 is electrically connected to the outer coil 109O, as indicated by the arrow 1215. For the first reactive circuit 901, the arrow 1215 represents the combination of the connector 809, the first conductive structure 1101, and the connectors 202A1 and 202B1. The second reactive circuit 1001 is electrically connected to the inner coil 109I, as indicated by the arrow 1215. For the second reactive circuit 1001, the arrow 1215 represents the combination of the connector 821, the second conductive structure 1107, and the connectors 202C1 and 202C1.

The input section 1202 includes an electrical signal generator and a portion of a gate driver. The output section 1204 includes a remaining portion of the gate driver and a half-bridge transistor circuit. In some embodiments, the input section 1202 includes a controller board on which the electrical signal generator and the entirety of the gate driver are implemented, with the output section 1204 including the half-bridge transistor circuit. The input section 1202 generates multiple square wave signals and provides the square wave signals to the output section 1204. The output section 1204 generates an amplified square waveform from the multiple square wave signals received from the input section 1202. The output section 1204 also shapes an envelope, such as a peak-to-peak magnitude, of the amplified square waveform. For example, a shaping control signal 1203 is supplied from the input section 1202 to the output section 1204 to generate the envelope. The shaping control signal 1203 has multiple voltage values for shaping the amplified square waveform to generate a shaped-amplified square waveform. For the first direct-drive RF signal generator 101A, the shaped-amplified square waveform is transmitted from the output section 1204 to the first reactive circuit 901. For the second direct-drive RF signal generator 101B, the shaped-amplified square waveform is transmitted from the output section 1204 to the second reactive circuit 1001.

Each of the first reactive circuit 901 and the second reactive circuit 1001 removes, such as filters out, higher-order harmonics of the shaped-amplified square waveform to generate a shaped-sinusoidal waveform having a fundamental frequency. The shaped-sinusoidal waveform has the same envelope as the shaped-amplified square waveform. For the first direct-drive RF signal generator 101A, RF power is transmitted from the first reactive circuit 901 to the outer coil 109O in the form of the shaped-sinusoidal waveform having the fundamental frequency. For the second direct-drive RF signal generator 101B, RF power is transmitted from the second reactive circuit 1001 to the inner coil 109I in the form of the shaped-sinusoidal waveform having the fundamental frequency. RF power transmitted to the inner coil 109I and/or outer coil 109O is transmitted into the plasma chamber 111 to transform one or more process gas(es) within the processing chamber 111 into the plasma 211 for processing of the substrate 203, as previously discussed with regard to FIG. 3.

In some embodiments, for the first direct-drive RF signal generator 101A, a reactance of the first reactive circuit 901 is modified by transmitting a quality factor control signal 1207 from the input section 1202 to the first reactive circuit 901, where the quality factor control signal 1207 directs implementation of a specific change in the reactance of the first reactive circuit 901, such as by directing implementation of a change in the capacitance setting of the variable capacitor 801. In some embodiments, for the second direct-drive RF signal generator 101B, a reactance of the second reactive circuit 1001 is modified by transmitting the quality factor control signal 1207 from the input section 1202 to the second reactive circuit 1001, where the quality factor control signal 1207 directs implementation of a specific change in the reactance of the second reactive circuit 1001, such as by directing implementation of a change in the capacitance setting of the variable capacitor 811.

In some embodiments, a feedback signal 1205 is sent from an output O1 of the output section 1204 to the input section 1202. In some embodiments, a phase difference between the time-varying voltage and the time-varying current of the shaped-amplified square waveform output from the output section 1204 is determined from the feedback signal 1205 to enable control of the output section 1204 to reduce or eliminate the phase difference. In some embodiments, for the first direct-drive RF signal generator 101A, in addition to or instead of the feedback signal 1205, an optional feedback signal 1209 is transmitted from the output of the first reactive circuit 901 to the input section 1202. In some embodiments, a phase difference between the time-varying voltage and the time-varying current of the shaped-sinusoidal waveform output from the first reactive circuit 901 is determined from the feedback signal 1209 to enable control of the output section 1204 and/or first reactive circuit 901 to reduce or eliminate the phase difference. In some embodiments, for the second direct-drive RF signal generator 101B, in addition to or instead of the feedback signal 1205, the optional feedback signal 1209 is transmitted from the output of the second reactive circuit 1001 to the input section 1202. In some embodiments, a phase difference between the time-varying voltage and the time-varying current of the shaped-sinusoidal waveform output from the second reactive circuit 1001 is determined from the feedback signal 1209 to enable control of the output section 1204 and/or second reactive circuit 1001 to reduce or eliminate the phase difference.

FIG. 13 shows a flowchart of a method for delivering RF power from the first/second direct-drive RF power supply 101A/101B to the plasma processing chamber 111, in accordance with some embodiments. The method includes an operation 1301 for transmitting a shaped-amplified square waveform signal from an output of the first/second direct-drive RF signal generator 101A/101B to the reactive circuit 901/1001, where the reactive circuit 901/1001 operates to transform the shaped-amplified square waveform signal into the shaped-sinusoidal signal. In some embodiments, the direct-drive RF signal generator 101A/101B has a non-reference output impedance, e.g., non-50 ohm output impedance. In some embodiments, a reference output impedance referred to herein is an impedance value of about 50 ohms. However, in some embodiments, the reference output impedance referred to herein is an impedance value other than 50 ohms. The method also includes an operation 1303 for transmitting the shaped-sinusoidal signal from an output of the reactive circuit 901/1001 to the coil 109O/109I of the plasma processing chamber 111. The shaped-sinusoidal signal conveys RF power to the coil 109O/109I. The method also includes an operation 1305 for adjusting a capacitance setting within the reactive circuit 901/1001 so that a peak amount of RF power is transmitted from the direct-drive radiofrequency signal generator 101A/101B through the reactive circuit 901/1001 to the coil 109O/109I.

In some embodiments, adjusting the capacitance setting in operation 1305 essentially cancels an inductive part of a load to which the direct-drive RF signal generator 101A/101B is connected by way of the coil 109O/109T so that the load is primarily a resistive load. In some embodiments, adjusting the capacitance setting in operation 1305 removes non-fundamental harmonic components of the shaped-amplified square waveform signal that is transmitted from the output of the direct-drive RF signal generator 101A/101B to the reactive circuit 901/1001. In some embodiments, the shaped-amplified square waveform signal output by the first direct-drive RF signal generator 101A has a frequency of about 2 megaHertz (MHz) and the capacitance setting of the variable capacitor 801 in the first reactive circuit 901 is adjusted in the operation 1305 within a range extending from about 2500 picofarads (pF) to about 4500 pF. In some embodiments, the shaped-amplified square waveform signal output by the second direct-drive RF signal generator 101B has a frequency of about 13.56 megaHertz (MHz) and the capacitance setting of the variable capacitor 811 in the second reactive circuit 1001 is adjusted in the operation 1305 within a range extending from about 5 pF to about 1000 pF.

In various embodiments disclosed herein, the junction box 121A/121B is provided for an RF power transmission system for the plasma processing chamber 111. The junction box 121A/121B includes a first terminal (such as the connection structure 805/817) configured to connect to an RF supply signal pin (such as the first/second lower RF connection structure 705A/705B), where the RF supply signal pin is electrically connected to the output of the first/second direct-drive RF signal generator 101A/101B. The junction box 121A/121B also includes a second terminal (such as the connection structure 807/818) configured to connect to the outer/inner coil 109O/109I. In some embodiments, the second terminal is connected to multiple separate windings of the outer/inner coil 109O/109I. The junction box 121A/121B also includes the first/second reactive circuit 901/1001 connected between the first terminal and the second terminal. The first/second reactive circuit 901/1001 is configured to transform a shaped-amplified square waveform signal into a shaped-sinusoidal signal in route from the first terminal to the second terminal.

In some embodiments, the first reactive circuit 901 is configured to provide a capacitance between the first terminal and the second terminal within a range extending from about 2500 picofarads (pF) to about 4500 pF. In some embodiments, the first reactive circuit 901 includes the variable capacitor 801 and the fixed capacitor 803 connected in parallel with each other. In some embodiments, a capacitance setting of the variable capacitor 801 is adjustable within a range extending from about 100 pF to about 2000 pF, and a capacitance of the fixed capacitor 803 is within a range extending from about 2000 pF to about 3500 pF. In some embodiments, the first direct-drive RF signal generator 101A is configured to supply the shaped-amplified square waveform signal having a frequency of about 2 MHz. In some embodiments, the second reactive circuit 1001 is configured to provide a capacitance between the first terminal and the second terminal (by way of the variable capacitor 811) within a range extending from about 5 pF to about 1000 pF. In some embodiments, the second direct-drive RF signal generator 101B is configured to supply the shaped-amplified square waveform signal having a frequency of about 13.56 MHz. Also, in some embodiments, the second junction box 121B includes the capacitor 813 connected a ground return end of the inner coil 109I and the reference ground potential 903. In some embodiments, the capacitor 813 has a capacitance within a range extending from about 200 pF to about 500 pF.

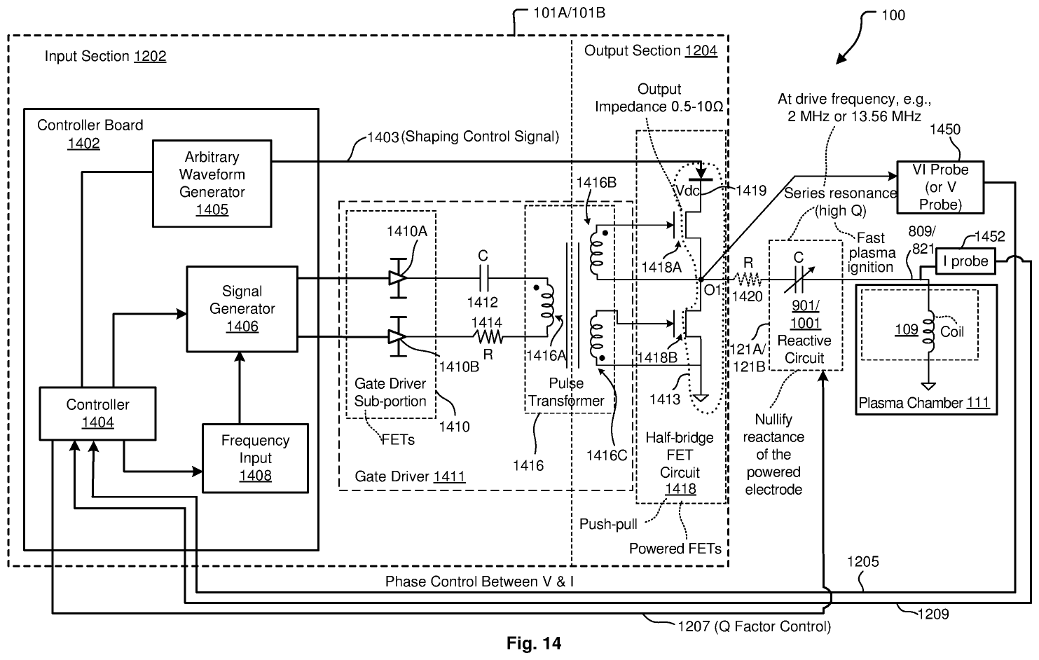

FIG. 14 shows a schematic diagram of each of the first and second direct-drive RF signal generators 101A/101B, in accordance with some embodiments. The input section 1202 includes a controller board 1402 and a portion of a gate driver 1411. The gate driver 1411 is coupled to the controller board 1402. The output section 1204 includes the remaining portion of the gate driver 1411 and a half-bridge field effect transistor (FET) circuit 1418. The half-bridge FET circuit 1418 or a tree, described below, is sometimes referred to herein as an amplification circuit and is coupled to the gate driver 1411.

The controller board 1402 includes a controller 1404, a signal generator 1406, and a frequency input 1408. In some embodiments, the controller 1404 includes a processor and a memory device. In some embodiments, the controller 1404 includes one or more of a microprocessor, an application specific integrated circuit (ASIC), a central processing unit, a processor, a programmable logic device (PLD), and a Field Programmable Gate Array (FPGA). The signal generator 1406 is a square wave oscillator that generates a square wave signal, such as a digital waveform or a pulse train. The square wave pulses between a first logic level, such as high (or one), and a second logic level, such as low (or zero). The signal generator 1406 generates the square wave signal at a prescribed operating frequency, such as 400 kiloHertz (kHz), or 2 MHz, or 13.56 MHz, or 27 MHz, or 60 MHz, among other operating frequencies.

The gate driver 1411 includes a first portion, which has a gate driver sub-portion 1410, a capacitor 1412, a resistor 1414, and a primary winding 1416A of a transformer 1416. The gate driver 1411 also includes a second portion (the remaining portion), which includes secondary windings 1416B and 1416C of the transformer 1416. The gate driver sub-portion 1410 includes multiple gate drivers 1410A and 1410B. Each of the gate drivers 1410A and 1410B is coupled to a positive voltage source at one end and to a negative voltage source at its opposite end. The half-bridge FET circuit 1418 includes a FET 1418A and a FET 1418B that are coupled to each other in a push-pull configuration. In some embodiments, such as shown in FIG. 14, the FETs 1418A and 1418B are n-type FETs that turn on when at least a threshold voltage is applied their gate conductor. However, in other embodiments, the FETs 1418A and 1418B are p-type FETs that turn off when at least a threshold voltage is applied their gate conductor. In some embodiments, each of the FET 1418A and the FET 1418B is implemented as a metal oxide semiconductor field effect transistor (MOSFET). In some embodiments, another type of transistor is used in place of the FETs 1418A and 1418A, such as an insulated gate bipolar transistor (IGBT), or a metal semiconductor field effect transistor (MESFET), or a junction field effect transistor (JFET), among others. In some embodiments, each of the FET 1418A and the FET 1418B is made from silicon carbide, or silicon, or gallium nitride. Each of the FET 1418A and the FET 1418B has an output impedance that lies within a pre-determined range, such as within a range extending from about 0.01 Ohm to about 10 Ohms. In some embodiments, the half-bridge FET circuit 1418 includes a direct current (DC) rail 1413 (illustrated within a dotted section), which includes a voltage source Vdc electrically connected to a first terminal of the FET 1418A through a conductor 1419. A second terminal of the FET 1418A is electrically connected to a first terminal of the FET 1418B. A second terminal of the FET 1418B is electrically connected to a reference ground potential.

In some embodiments, a voltage and current (VI) probe 1450 is coupled to the output O1 of the half-bridge FET circuit 1418. The VI probe 1450 is a sensor that measures a complex current at the output O1, a complex voltage at the output O1, and a phase difference between the complex voltage and the complex current. The complex current has a magnitude and a phase. Similarly, the complex voltage has a magnitude and a phase. The output O1 is between the source terminal of the FET 1418A and the drain terminal of the FET 1418B. The VI probe 1450 is coupled to the controller 1404 to transmit the feedback signal 1209. In some embodiments, a voltage (V) probe 1450 is used in place of the VI probe 1450. In these embodiments, a current (I) probe 1452 is coupled to the output of the first/second reactive circuit 901/1001. The V probe 1450 is a sensor that measures a time-varying complex voltage magnitude and phase at the output O1. The I probe 1452 is a sensor that measures a time-varying complex current magnitude and phase at the output of the first/second reactive circuit 901/1001.

The controller 1404 is coupled to the signal generator 1406 to provide the frequency input 1408, such as the operating frequency, to the signal generator 1406. The controller 1404 is further coupled through a conductor to the voltage source Vdc of the DC rail 1413. The signal generator 1406 is also coupled at its output to the gate drivers 1410A and 1410B. An output of the gate driver 1410A is coupled to the capacitor 1412. An output of the gate driver 1410B is coupled to the resistor 1414. The capacitor 1412 and the resistor 1414 are coupled to opposite ends of the primary winding 1416A of the transformer 1416. The capacitor 312 functions to cancel or negate an inductance of the primary winding 1416A. The cancellation or negation of the inductance of the primary winding 1416A facilitates generation of a square shape of the gate drive signals that are output by the gate drivers 1410A and 1410B. Also, the resistor 1414 reduces an oscillation of the square wave signal that is generated by the signal generator 1406.

A first end of the secondary winding 1416B of the transformer 1416 is electrically connected to a gate terminal of the FET 1418A. A second end of the secondary winding 1416B is electrically connected to both the second terminal of the FET 1418A and the first terminal of the FET 1418B, which are both electrically connected to the output O1 of the half-bridge FET circuit 1418.

A first end of the secondary winding 1416C of the transformer 1416 is electrically connected to a gate terminal of the FET 1418B. A second end of the secondary winding 1416C is electrically connected to the reference ground potential. The output O1 of the half-bridge FET circuit 1418 is electrically connected to the input of the first/second reactive circuit 901/1001. A resistance 1420 is seen by the output O1 of the half-bridge FET circuit 1418. The resistance 1420 represents a combination of the resistance in the portion of the coil assembly 109 to which the first/second direct-drive RF signal generator 101A/101B is connected, the resistance presented by the plasma 211 when present within the plasma processing chamber 111, and the resistance of the RF power transmission path from the output O1 to the coil assembly 109.

The controller 1404 generates a setting, such as the frequency input 1408, and provides the frequency input 1408 to the signal generator 1406. The frequency input 1408 is the value, such as 2 MHz or 13.56 MHz, of the target operating frequency. The signal generator 1406 generates an input RF signal having the target operating frequency upon receiving the setting from the controller 1404. The input RF signal is the square wave signal. The gate drivers 1410A and 1410B amplify the input RF signal to generate an amplified RF signal and provide the amplified RF signal to the primary winding 1416A of the transformer 1416.

Based on a directionality of electrical current flow of the amplified RF signal at a given time, either the secondary winding 1416B or the secondary winding 1416C generates a gate drive signal having a threshold voltage at the given time. For example, when the electrical current of the amplified RF signal flows from a positively charged terminal (indicated by a dot) of the primary winding 1416A to a negatively charged terminal (indicated by the absence of a dot) of the primary winding 1416A, the secondary winding 1416B generates a gate drive signal having at least the threshold voltage to turn on the FET 1418A, and the secondary winding 1416C does not generate the threshold voltage such that the FET 1418B is off. Conversely, when the current of the amplified RF signal flows from the negatively charged terminal (indicated by the absence of the dot) of the primary winding 1416A to the positively charged terminal (indicated by the dot) of the primary winding 1416A, the secondary winding 1416C generates a gate drive signal having at least the threshold voltage to turn on the FET 1418B, and the secondary winding 1416B does not generate the threshold voltage such that the FET 1418A is off.

Each gate drive signal that is transmitted to the gate of the FET 1418A and the gate of the FET 1418B is a square wave signal, e.g., a digital signal or a pulsed signal, having the target operating frequency. For example, each gate drive signal that is transmitted to the gate of the FET 1418A and the gate of the FET 1418B transitions between a low level and a high level. The gate drive signals that are transmitted to the gate of the FET 1418A and the gate of the FET 1418B have the target operating frequency and are in reverse synchronization with respect to each other. More specifically, during a time interval or a time at which the gate drive signal that is transmitted to the gate of the FET 1418A transitions from the low level to the high level, the gate drive signal that is transmitted to the gate of the FET 1418B simultaneously transitions from the high level to the low level. Similarly, during a time interval or a time in which the gate drive signal that is transmitted to the gate of the FET 1418A transitions from the high level to the low level, the gate drive signal that is transmitted to the gate of the FET 1418B simultaneously transitions from the low level to the high level. This reverse synchronization of the gate drive signals allows the FETs 1418A and 1418B to be turned on consecutively and to be turned off consecutively in a repeating manner in accordance with the target operating frequency of the time-varying square wave signal. The FETs 1418A and 1418B are consecutively operated. For example, when the FET 1418A is turned on, the FET 1418B is turned off. And, when the FET 1418B is turned on, the FET 1418A is turned off. The FETs 1418A and 1418B are not on at the same time or during the same time period. At frequencies other than the target operating frequency, the first/second reactive circuit 901/1001 functions to present a high load so that not much current will come out of the first/second direct-drive RF signal generator 101A/101B at the other non-target frequencies.

When the FET 1418A is on and the FET 1418B is off, electrical current flows between the voltage source Vdc and the output O1 to generate a voltage at the output O1. The voltage at the output O1 is generated according to the voltage values received from the controller 1404 or an arbitrary waveform generator 1405, which is further described below. When the FET 1418B is off, there is no electrical current flowing from the output O1 to the ground potential that is coupled to the FET 1418B. Electrical current flows from the voltage source Vdc through the output O1 to the input of the first/second reactive circuit 901/1001 when the FET 1418A is on. Also, when the FET 1418B is on and the FET 1418A is off, electrical current flows from the output O1 to the reference ground potential coupled to the FET 1418B. When the FET 1418A is off, there is no electrical current flowing from the voltage source Vdc to the output O1.

In some embodiments, the controller 1404 directs the arbitrary waveform generator 1405 to generate the shaping control signal 1403 that indicates voltage values. The shaping control signal 1403 is transmitted through an electrical conductor to the voltage source Vdc. The DC rail 1413 is agile in that there is fast control of the voltage source Vdc by the controller 1404 (and, optionally, by the arbitrary waveform generator 1405). Both the controller 1404 and the voltage source Vdc are electronic circuits, which allow the controller 1404 to substantially instantaneously control the voltage source Vdc. For example, at a time the controller 1404 sends (either directly or by way of the arbitrary waveform generator 1405) the voltage values in the shaping control signal 1403 to the voltage source Vdc, the voltage source Vdc substantially instantaneously changes its output voltage level accordingly. In some embodiments, the voltage values indicated by the shaping control signal 1403 are within a range extending from about zero volt to about 80 volts, such that the DC rail 1413 operates within this voltage range. The voltage values indicated by the shaping control signal 1403 are magnitudes of the voltage signal that is generated by the voltage source Vdc to define the shaped envelope of the shaped-amplified square waveform at the output O1 of the output section 1204. For example, when the first/second direct-drive RF signal generator 101A/101B is operated to generate a continuous waveform, the voltage values indicated by the shaping control signal 1403 control, as a function of time, a peak-to-peak magnitude of a parameter of the continuous waveform generated at the output O1 of the output section 1204, where the parameter is one or more of power, voltage, and current, by way of example. The peak-to-peak magnitude of the continuous waveform defines the shaped envelope of the continuous waveform as a function of time.

In another example, when the first/second direct-drive RF signal generator 101A/101B is operated to generate the shaped-amplified square waveform at the output O1 to have a shaped envelope that is pulsed shape, the voltage values indicated by the shaping control signal 1403 are changed substantially instantaneously (in a step-function-like manner) at a given time or during a given pre-determined time period, such that the peak-to-peak magnitude of the shaped-amplified square waveform changes from a first parameter level (e.g., high level) to a second parameter level (e.g., low level) or changes from the second parameter level to the first parameter level, where the parameter is one or more of power, voltage, and current, by way of example. In another example, when the first/second direct-drive RF signal generator 101A/101B is operated to generate the shaped-amplified square waveform at the output O1 to have a shaped envelope that is of arbitrary shape, the voltage values indicated by the shaping control signal 1403 are changed in a prescribed and controlled arbitrary manner as directed by the controller 1404 by way of the arbitrary waveform generator 1405, such that the peak-to-peak magnitude of the shaped-amplified square waveform changes is the prescribed and controlled arbitrary manner. In another example, when the first/second direct-drive RF signal generator 101A/101B is operated to generate the shaped-amplified square waveform at the output O1 to have a multi-state pulsed shape, the voltage values indicated by the shaping control signal 1403 are changed substantially instantaneously (in a step-function-like manner) at a given time or during a given pre-determined time period, such that the peak-to-peak magnitude of the shaped-amplified square waveform changes between different states, where each of the different states has a different peak-to-peak magnitude of particular parameter level, e.g., power level, voltage level, and/or current level, among others. In various embodiments, the number of different states is two or more, as specified by the controller 1404.

The shaped-amplified square waveform generated at the output O1 of the output section 1204 is based on operation (as a function of time) of the FETs 1418A and 1418B in accordance with the gate drive signals as output by the gate drivers 1410A and 1410B, and supply (as a function of time) of voltage by the voltage source Vdc in accordance with the shaping control signal 1403. An amount of amplification of the shaped-amplified square waveform is based on the output impedances of the FETs 1418A and 1418B of the half-bridge FET circuit 1418, the voltage values that are supplied by the controller 1404 (and, optionally, by the arbitrary waveform generator 1405) to the voltage source Vdc, and a maximum achievable voltage value of the voltage source Vdc. The first/second reactive circuit 901/1001 receives the shaped-amplified square waveform and functions to reduce or eliminate the higher-order harmonics of the shaped-amplified square waveform to generate the shaped-sinusoidal waveform having a fundamental frequency. It should be understood that the shaped-sinusoidal waveform that is output by the first/second reactive circuit 901/1001 has the same shaped envelope as the shaped-amplified square waveform that is input to the first/second reactive circuit 901/1001. The shaped-sinusoidal waveform that is output by the first/second reactive circuit 901/1001 is provided to the coil assembly 109 as an RF signal for generation of the plasma 211 within the plasma processing chamber 111.

The VI probe 1450 measures the complex voltage and complex current of the shaped-amplified square waveform at the output O1 and provides the feedback signal 1205 to the controller 1404, where the feedback signal 1205 indicates the complex voltage and complex current. The controller 1404 identifies the phase difference between the complex voltage of the shaped-amplified square waveform and the complex current of the shaped-amplified square waveform from the feedback signal 1205, and determines whether the phase difference is within a predetermined acceptable range. For example, the controller 1404 determines whether or not the phase difference is zero or within a predetermined acceptable range (percentage) away from zero. Upon determining that the phase difference is not within the predetermined acceptable range, the controller 1404 changes frequency values of the operating frequency to change the frequency input 1408. The changed frequency values are provided from the frequency input 1408 to the signal generator 1406 to change the operating frequency of the signal generator 1406. In some embodiments, the operating frequency is changed in less than or equal to about 10 microseconds. The operating frequency of the signal generator 1406 is changed until the controller 1404 determines that the phase difference between the complex voltage and the complex current that is measured by the VI probe 1450 is within the predetermined acceptable range. Upon determining that the phase difference between the complex voltage and the complex current is within the predetermined acceptable range, the controller 1404 does not further change the frequency input 1408. When the phase difference is within the predetermined acceptable range, a predetermined amount of power is provided from the output O1 of the first/second direct-drive RF signal generator 101A/101B through the first/second reactive circuit 901/1001 to the coil assembly 109.

In some embodiments, in addition to or instead of changing the frequency input 1408, the controller 1404 changes the voltage values in the shaping control signal 1403 that is being supplied to the voltage source Vdc in order to change the voltage signal generated by the voltage source Vdc. The voltage source Vdc changes its voltage level in accordance with the voltage values indicated in the shaping control signal 1403. The controller 1404 continues to change the voltage values in the shaping control signal 1403 until the shaped-amplified square waveform achieves a predetermined power setpoint. In some embodiments, the predetermined power setpoint is stored in a memory device of the controller 1404. In various embodiments, instead of changing a voltage of the shaped-amplified square waveform at the output O1, a current of the shaped-amplified square waveform is changed. For example, by directing changes in the voltage values in the shaping control signal 1403, the controller 1404 changes the current of the shaped-amplified square waveform at the output O1 until the shaped-amplified square waveform achieves a predetermined current setpoint. In some embodiments, the predetermined current setpoint is stored in the memory device of the controller 1404. In some embodiments, instead of changing a voltage or a current of the shaped-amplified square waveform at the output O1, a power of the shaped-amplified square waveform is changed. For example, by directing changes in the voltage values in the shaping control signal 1403, the controller 1404 changes the power of the shaped-amplified square waveform at the output O1 until the shaped-amplified square waveform achieves a predetermined power setpoint. In some embodiments, the predetermined power setpoint is stored in the memory device of the controller 1404. It should be noted that any change in the voltage, current, or power of the shaped-amplified square waveform generated at the output O1 produces the same change in the voltage, current, or power, respectively, of the shaped-sinusoidal waveform that is output by the first/second reactive circuit 901/1001.

In some embodiments, the controller 1404 is coupled through a motor driver and a motor (e.g., stepper motor) to the first/second reactive circuit 901/1001. In some embodiments, the motor driver is implemented as an integrated circuit device that includes one or more transistors. The controller 1404 sends a signal, such as the quality factor control signal 1207, to the motor driver to generate an electrical signal that is transmitted from the motor driver to the motor. The motor operates in accordance with the electrical signal received from the motor driver to change a reactance of the first/second reactive circuit 901/1001. For example, in some embodiments, the motor operates to change an area (or spacing) between electrically conducive plates within the capacitor 801/811 to change the reactance of the first/second reactive circuit 901/1001. In some embodiments, the reactance of the first/second reactive circuit 901/1001 is changed to maintain a prescribed quality factor of the first/second reactive circuit 901/1001.

The first/second reactive circuit 901/1001 in combination with an inductance of the outer/inner coil 109O/109I has a high quality factor (Q). For example, an amount of power of the shaped-amplified square waveform generated at the output O1 that is lost in the first/second reactive circuit 901/1001 is low compared to an amount of power of the shaped-sinusoidal waveform that is transmitted from the output of the first/second reactive circuit 901/1001 to the outer/inner coil 109O/109I. The high quality factor of the first/second reactive circuit 901/1001 facilitates fast ignition of the plasma 211 within the plasma processing chamber 111. Also, the first/second reactive circuit 901/1001 is configured and set to resonate out an inductive reactance of the outer/inner coil 109O/109I and the plasma 211, such that the output O1 of the first/second direct-drive RF signal generator 101A/101B sees the resistance 1420 but does not see essentially any reactance. For example, the first reactive circuit 901 is controlled to have a reactance that reduces, such as nullifies or cancels, a reactance of one or more of the outer coil 109O, the plasma 211, and the RF power transmission connections between the first reactive circuit 901 and the outer coil 109O. In some embodiments, the reactance of the first reactive circuit 901 is controlled by controlling the capacitance setting of the variable capacitor 801. Similarly, the second reactive circuit 1001 is controlled to have a reactance that reduces, such as nullifies or cancels, a reactance of one or more of the inner coil 109I, the plasma 211, and the RF power transmission connections between the second reactive circuit 1001 and the inner coil 109I. In some embodiments, the reactance of the second reactive circuit 1001 is controlled by controlling the capacitance setting of the variable capacitor 811.

In some embodiments, the FETs 1418A and 1418B are fabricated from silicon carbide to have a low internal resistance and fast switching time, and to facilitate cooling of the FETs 1418A and 1418B. The low internal resistance of the FETs 1418A and 1418B provides for higher efficiency, which enables the FETs 1418A and 1418B to turn on nearly instantaneously and to turn off fast, such as in less than 10 microseconds. In some embodiments, each of the FETs 1418A and 1418B is configured to turn on and off in less than a pre-determined time period, such as less than 10 microseconds. In some embodiments, each of the FETs 1418A and 1418B is configured to turn on and off in a time period extending from about 0.5 microsecond to about 10 microseconds. In some embodiments, each of the FETs 1418A and 1418B is configured to turn on and off in a time period extending from about 1 microsecond to about 5 microseconds. In some embodiments, each of the FETs 1418A and 1418B is configured to turn on and off in a time period extending from about 3 microseconds to about 7 microseconds. It should be understood that there is essentially no delay in transition between the on and off states for each of the FETs 1418A and 1418B. In this manner, when the FET 1418A turns on, the FET 1418B essentially simultaneously turns off. And, when the FET 1418A turns off, the FET 1418B essentially simultaneously turns on. The FETs 1418A and 1418B are configured to switch on and off fast enough to ensure that the FETs 1418A and 1418B will not be on at the same time in order to avoid electrical current flow directly from the voltage source Vdc to the reference ground potential through the FETs 1418A and 1418B.

The low internal resistance of the silicon carbide FETs 1418A and 1418B reduces an amount of heat generated by the silicon carbide FETs 1418A and 1418B, which makes it easier to cool the silicon carbide FETs 1418A and 1418B using a cooling plate or a heat sink.

It should be understood that the components, such as transistors, of the first/second direct-drive RF signal generator 101A/101B are electronic. Also, it should be understood that there is no RF impedance matching network and RF cable in the RF power transmission path from the first/second direct-drive RF signal generator 101A/101B to the coil assembly 109. The electronic components within the first/second direct-drive RF signal generator 101A/101B in combination with the absence of the RF impedance matching network and RF cable in the RF power transmission path from the first/second direct-drive RF signal generator 101A/101B to the coil assembly 109 provides for repeatability and consistency in regard to fast plasma 211 ignition and plasma 211 sustainability across different plasma processing chambers 111.

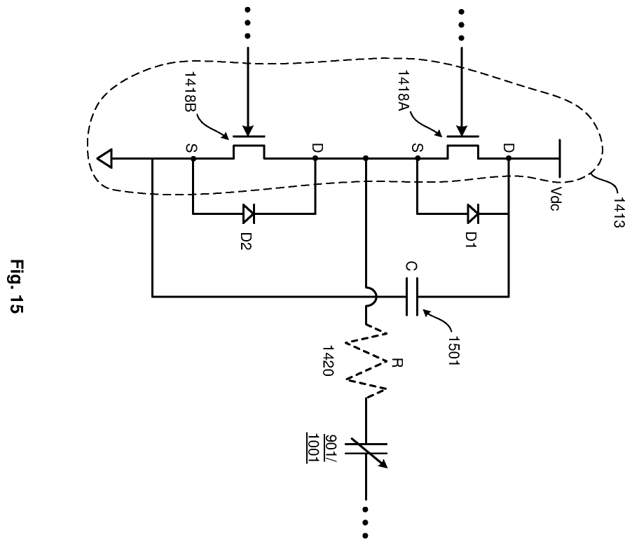

FIG. 15 shows a circuit schematic of the half-bridge FET circuit 1418 that implements voltage limiters across the FETs 1418A and 1418B, in accordance with some embodiments. A diode D1 is connected between the drain terminal (D) and the source terminal (S) of the FET 1418A to limit voltage across the FET 1418A. When the FET 1418A is turned on and the FET 1418B is turned off, voltage across the FET 1418A increases until the voltage is limited by the diode D1. The diode D1 functions to prevent electrical current from adversely shooting through the FET 1418A directly from the voltage source Vdc to the reference ground potential. Similarly, a diode D2 is connected between the drain terminal (D) and the source terminal (S) of the FET 1418B to limit voltage across the FET 1418B. When the FET 1418B is turned on and the FET 1418A is turned off, voltage across the FET 1418B increases until the voltage is limited by the diode D2. The diode D2 functions to prevent electrical current from adversely shooting through the FET 1418B directly from the voltage source Vdc to the reference ground potential. A capacitor 1501 is connected between the drain terminal (D) of the FET 1418A and the source terminal (S) of the FET 1418B. In the event of a delay in turning off and on of the FET 1418A and/or 1418B, electrical current will flow from the voltage source Vdc through the capacitor 1501 to the reference ground potential to reduce the probability of having an adverse and potentially damaging amount of electrical current flow through the output O1 of the first/second direct-drive RF signal generator 101A/101B to the coil assembly 109.

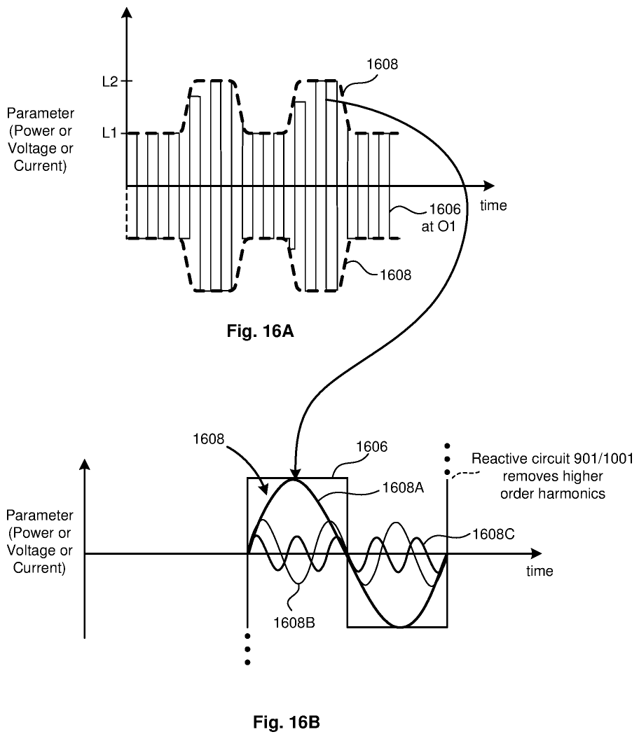

FIG. 16A shows a plot of a parameter of an example shaped-amplified square waveform 1606 generated at the output O1 of the first/second direct-drive RF signal generator 101A/101B as a function of time, in accordance with some embodiments. The parameter of the shaped-amplified square waveform 1606 is either power, voltage, or current. The shaped-amplified square waveform 1606 has a shaped envelope 1608 generated in accordance with the voltage values indicated by the shaping control signal 1403 as directed by the controller 1404 and/or arbitrary waveform generator 1405. The shaped envelope 1608 is controlled so that an absolute magnitude of the parameter of the shaped-amplified square waveform 1606 transitions between a first level L1 (lower level) and a second level L2 (higher level). The parameter has a lower peak-to-peak magnitude at the first level L1 than at the second level L2. It should be understood that the shaped envelope 1608 can have a different shape than what is shown in FIG. 16A, depending on the voltage values indicated by the shaping control signal 1403. For example, the shaping control signal 1403 can be generated to direct the shaped envelope 1608 to have a continuous wave shape, a triangular shape, a multi-level pulse shape, or essentially any other prescribed controlled arbitrary shape.

FIG. 16B shows a plot of a parameter of an example shaped-sinusoidal waveform 1608 generated at the output of the first/second reactive circuit 901/1001 as a function of time, in accordance with some embodiments. The parameter of the shaped-sinusoidal waveform 1608 is either power, voltage, or current. The shaped-sinusoidal waveform 1608 is based on the shaped-amplified square waveform 1606 that is input to the first/second reactive circuit 901/1001 as a function of time. The shaped-amplified square waveform 1606 is a combination of a fundamental frequency sinusoidal waveform 1608A and multiple higher-order harmonic frequency sinusoidal waveforms 1608B, 1608C, etc. For example, the sinusoidal waveform 1608B represents a second order harmonic frequency of the fundamental frequency sinusoidal waveform 1608A. And, the sinusoidal waveform 1608C represents a third order harmonic frequency of the fundamental frequency sinusoidal waveform 1608A. The first/second reactive circuit 901/1001 functions to remove the higher-order harmonic frequency sinusoidal waveforms 1608B, 1608C from the shaped-amplified square waveform 1606, so that just the fundamental frequency sinusoidal waveform 1608A is provided at the output of the first/second reactive circuit 901/1001 as a function of time. The high quality factor of the first/second reactive circuit 901/1001 facilitates removal of the higher-order harmonic frequency sinusoidal waveforms 1608B, 1608C, etc. from the shaped-amplified square waveform 1606 that is output by the first/second direct-drive RF signal generator 101A/101B. The fundamental frequency sinusoidal waveform 1608A is transmitted as the shaped-sinusoidal waveform 1608 to the coil assembly 109, thereby transmitting RF power to the coil assembly 109.

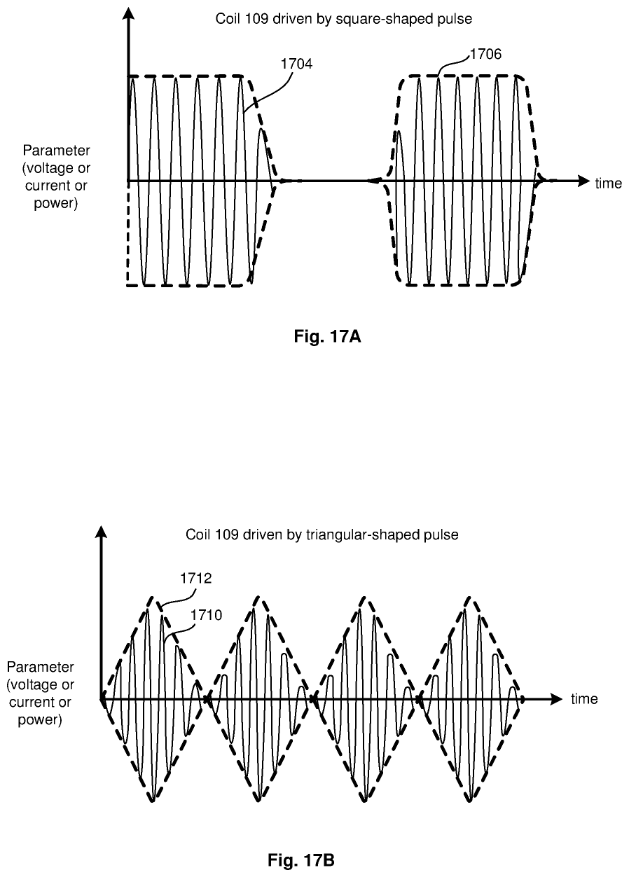

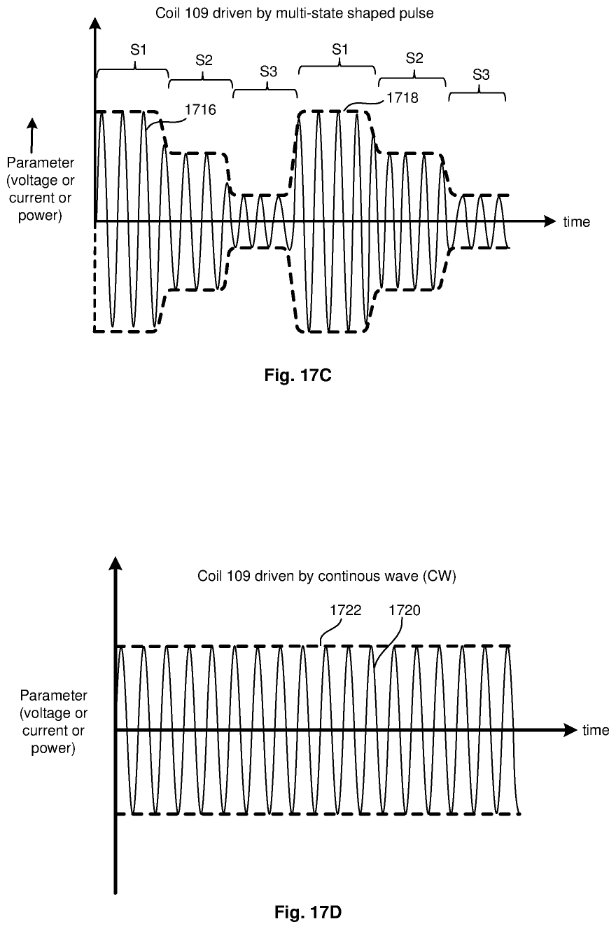

FIG. 17A shows a plot of a parameter of an example shaped-sinusoidal waveform 1704 generated at the output of the first/second reactive circuit 901/1001 as a function of time, in accordance with some embodiments. The parameter of the shaped-sinusoidal waveform 1704 is either power, voltage, or current. The shaped-sinusoidal waveform 1704 has a shaped envelope 1706 generated in accordance with the voltage values indicated by the shaping control signal 1403 as directed by the controller 1404 and/or arbitrary waveform generator 1405. The shaped envelope 1706 defines a peak-to-peak change in the parameter of the shaped-sinusoidal waveform 1704 as a function of time. The example shaped envelope 1706 represents a square-shaped envelope, such as a pulse shaped envelope.

FIG. 17B shows a plot of a parameter of an example shaped-sinusoidal waveform 1710 generated at the output of the first/second reactive circuit 901/1001 as a function of time, in accordance with some embodiments. The parameter of the shaped-sinusoidal waveform 1710 is either power, voltage, or current. The shaped-sinusoidal waveform 1710 has a shaped envelope 1712 generated in accordance with the voltage values indicated by the shaping control signal 1403 as directed by the controller 1404 and/or arbitrary waveform generator 1405. The shaped envelope 1712 defines a peak-to-peak change in the parameter of the shaped-sinusoidal waveform 1710 as a function of time. The example shaped envelope 1710 represents a triangular-shaped envelope.

FIG. 17C shows a plot of a parameter of an example shaped-sinusoidal waveform 1716 generated at the output of the first/second reactive circuit 901/1001 as a function of time, in accordance with some embodiments. The parameter of the shaped-sinusoidal waveform 1716 is either power, voltage, or current. The shaped-sinusoidal waveform 1716 has a shaped envelope 1718 generated in accordance with the voltage values indicated by the shaping control signal 1403 as directed by the controller 1404 and/or arbitrary waveform generator 1405. The shaped envelope 1718 defines a peak-to-peak change in the parameter of the shaped-sinusoidal waveform 1716 as a function of time. The example shaped envelope 1718 represents a multi-state shaped envelope that includes three different states S1, S2, and S3. The shaped envelope 1718 is defined so that the peak-to-peak change in the parameter of the shaped-sinusoidal waveform 1716 during the first state S1 is greater than the peak-to-peak change in the parameter of the shaped-sinusoidal waveform 1716 during the first state S2. The shaped envelope 1718 is also defined so that the peak-to-peak change in the parameter of the shaped-sinusoidal waveform 1716 during the second state S2 is greater than the peak-to-peak change in the parameter of the shaped-sinusoidal waveform 1716 during the third state S3. The shaped envelope 1718 revert back to the first state S1 after the third state S3. The states S1, S2, and S3 repeat at a frequency that is less than the frequency of the shaped-amplified square waveform that is output by the first/second direct-drive RF signal generator 101A/101B. Therefore, the states S1, S2, and S3 repeat at a frequency that is less than the frequency of the shaped-sinusoidal waveform 1716. In various embodiments, the multi-state shaped envelope includes more than three different states, with each different state corresponding to a different peak-to-peak change in the parameter of the shaped-sinusoidal waveform 1716 as a function of time. Also, in various embodiments, the multi-state shaped envelope can be controlled so that any of the three or more different states of the shaped envelope has either a lower or higher peak-to-peak magnitude of the parameter of the shaped-sinusoidal waveform 1716 relative to a next state of the shaped envelope.

FIG. 17D shows a plot of a parameter of an example shaped-sinusoidal waveform 1720 generated at the output of the first/second reactive circuit 901/1001 as a function of time, in accordance with some embodiments. The parameter of the shaped-sinusoidal waveform 1720 is either power, voltage, or current. The shaped-sinusoidal waveform 1720 has a shaped envelope 1722 generated in accordance with the voltage values indicated by the shaping control signal 1403 as directed by the controller 1404 and/or arbitrary waveform generator 1405. The shaped envelope 1722 defines a peak-to-peak change in the parameter of the shaped-sinusoidal waveform 1720 as a function of time. The example shaped envelope 1722 is flat, such that shaped-sinusoidal waveform 1720 represents a continuous wave signal.

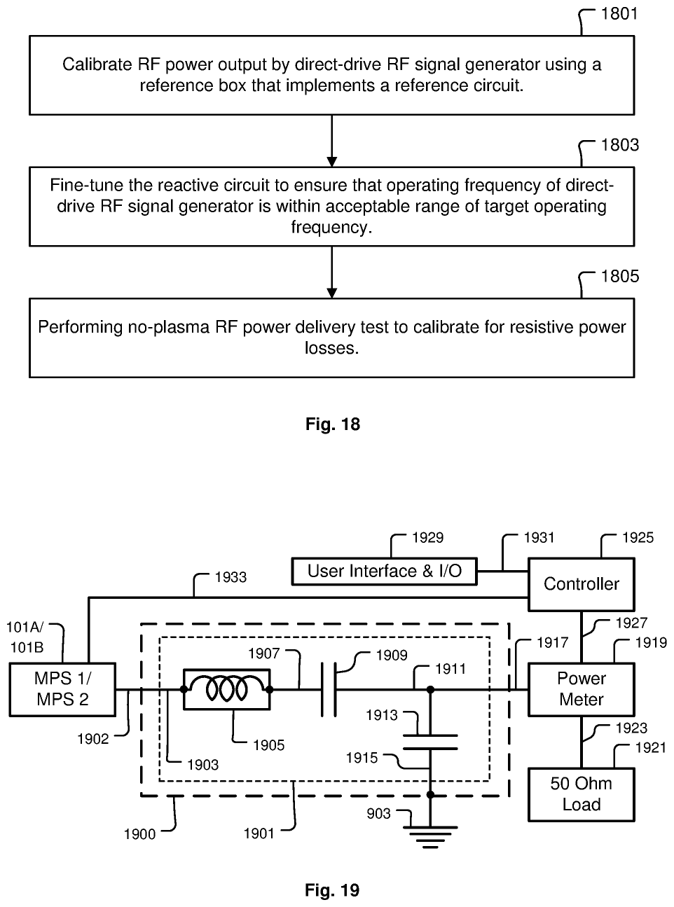

FIG. 18 shows a flowchart of a method for calibrating the first/second direct-drive RF signal generator 101A/101B, in accordance with some embodiments. It should be understood that the method of FIG. 18 is performed separately for each of the first direct-drive RF signal generator 101A and the second direct-drive RF signal generator 101B. For ease of description, first/second direct-drive RF signal generator 101A/101B is used to refer to either the first direct-drive RF signal generator 101A or the second direct-drive RF signal generator 101B. In some embodiments, the method of FIG. 18 is performed at the time of initial installation and setup of the plasma processing system 100 in the semiconductor fabrication facility, and at times of periodic maintenance, such as annual maintenance.

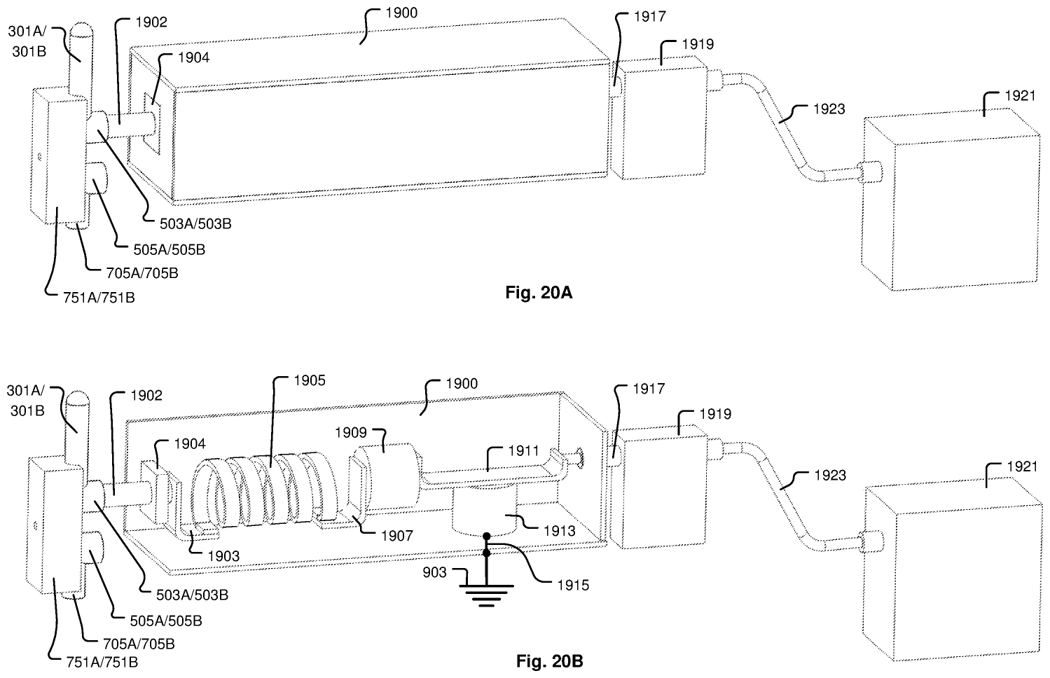

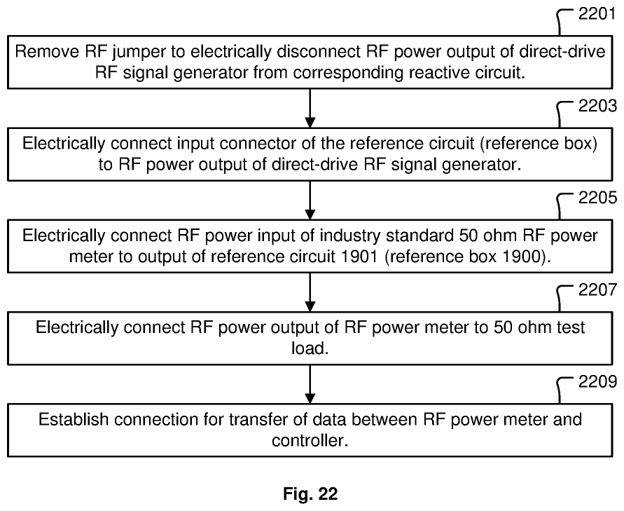

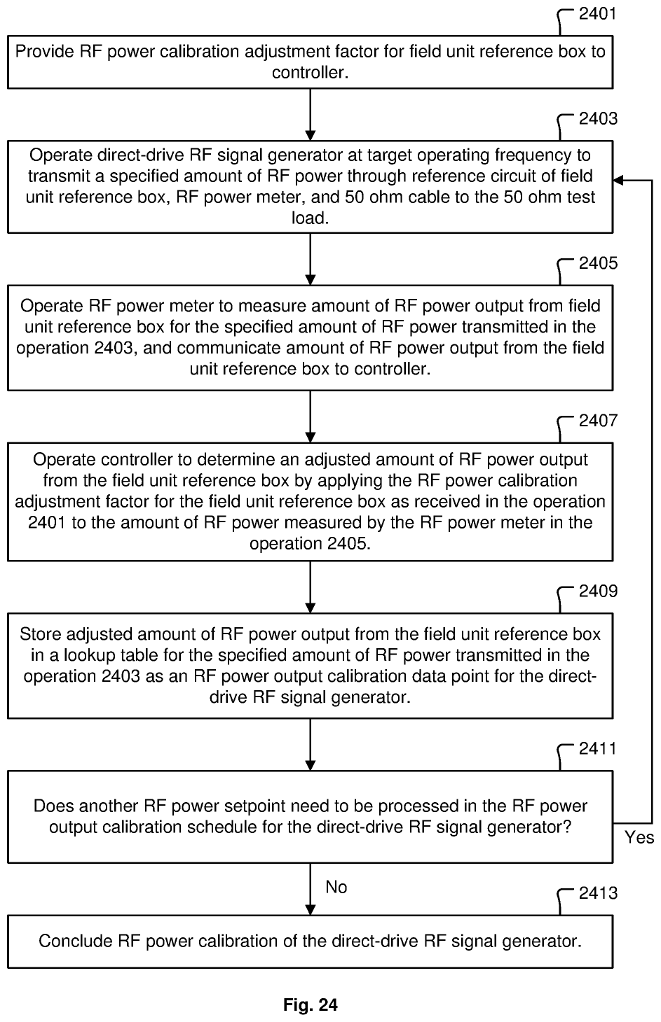

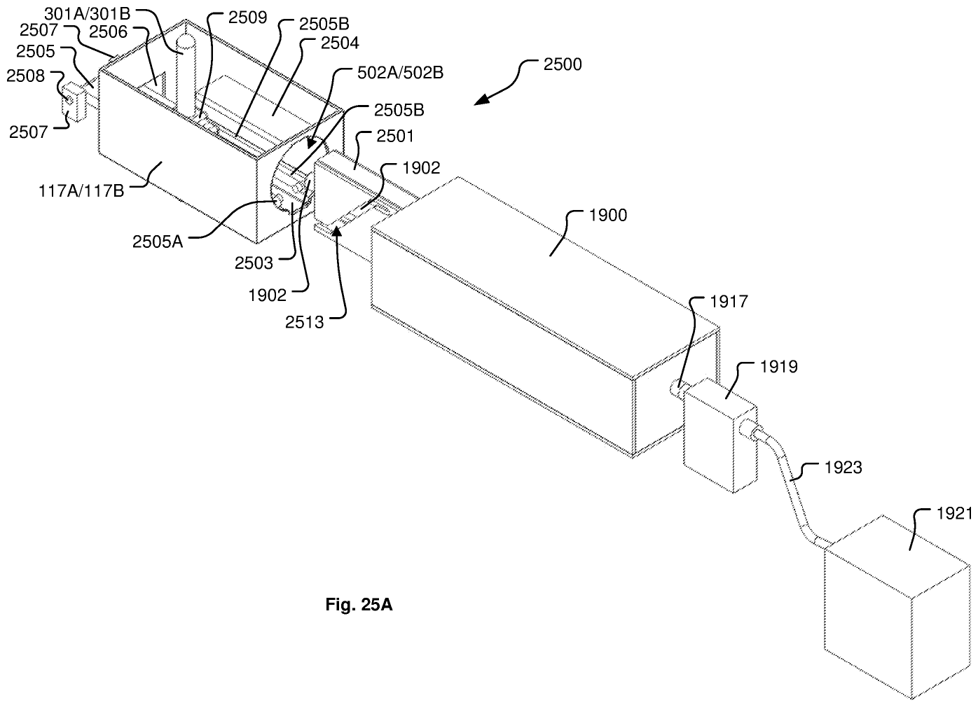

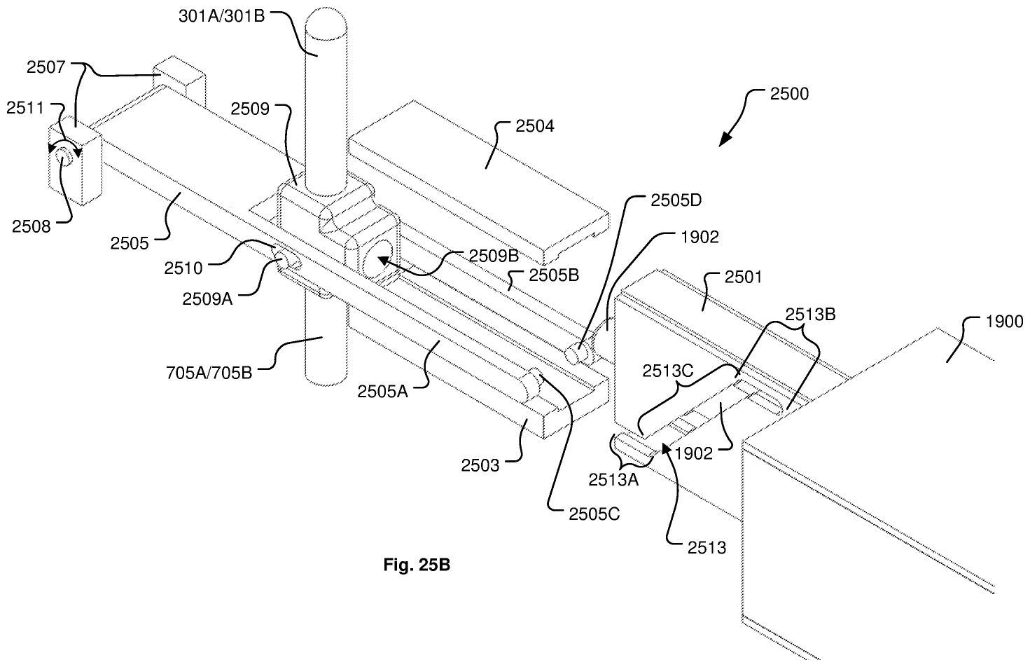

The method includes an operation 1801 for calibrating RF power output by the first/second direct-drive RF signal generator 101A/101B using a reference box 1900 that implements a reference circuit 1901 (see FIG. 19). The calibration of operation 1801 calibrates the RF power transfer into the reactive circuit 901/1001 by the first/second direct-drive RF signal generator 101A/101B to a respective master-standard (or “golden”) reference. This enables chamber-to-chamber matching of the RF power output by different direct-drive RF signal generators that are configured to operate at a same target frequency. Connection of the reference box 1900 to the plasma processing system 100 is described below with regard to the method of FIG. 22. The operation 1801 is described in more detail below with regard to the method of FIG. 24.

The method of FIG. 18 also includes an operation 1803 for fine-tuning of the reactive circuit 901/1001 to ensure that the operating frequency of the first/second direct-drive RF signal generator 101A/101B is within an acceptable range of the target operating frequency, e.g., 2 MHz or 13.56 MHz. The method also includes an operation 1805 for performing a no-plasma RF power delivery test to calibrate for resistive power losses in the first/second reactive circuit 901/1001, outer/inner coil 109O/109I, and anywhere that power dissipation currents, such as mirror currents and/or eddy currents, may occur within the plasma processing system 100 to cause dissipation of RF power.

The method of FIG. 18 is performed in-situ with the plasma processing system 100 installed at the semiconductor fabrication facility. In some embodiments, a pre-calibration process is performed on the first/second direct-drive RF signal generator 101A/101B by the manufacturer before shipping of the first/second direct-drive RF signal generator 101A/101B to the semiconductor fabrication facility, i.e., before the method of FIG. 18 is performed on the installed plasma processing system 100. In some embodiments, the pre-calibration process includes an output calibration to confirm the RF current and voltage readback precision and accuracy at the output O1 (see FIG. 14) of the first/second direct-drive RF signal generator 101A/101B. This output calibration is done to make sure the first/second direct-drive RF signal generator 101A/101B is outputting the correct amount of RF power before delivery to the semiconductor fabrication facility.

The pre-calibration process also includes a coarse-tuning of the reactive circuit 901/1001 by the manufacturer to ensure that the operating frequency of the first/second direct-drive RF signal generator 101A/101B is within the acceptable range of the target operating frequency, e.g., 2 MHz or 13.56 MHz. In this coarse-tuning process, the reactive circuit 901/1001 is adjusted to enable full forward RF power transfer to the plasma processing chamber 111 with essentially zero reactance. More specifically, in the case of the first direct-drive RF signal generator 101A, the coarse-tuning process includes running a no-plasma test procedure in which the first direct-drive RF signal generator 101A is operated to transmit RF power to through the outer coil 109O to the plasma processing chamber 111 (with no plasma generated), and in which the capacitance setting of the variable capacitor 801 in the first reactive circuit 901 is adjusted to ensure that the operating resonance frequency of the first direct-drive RF signal generator 101A is within the acceptable range of the target operating frequency, e.g., 2 MHz. Likewise, in the case of the second direct-drive RF signal generator 101B, the coarse-tuning process includes running a no-plasma test procedure in which the second direct-drive RF signal generator 101B is operated to transmit RF power to through the inner coil 109I to the plasma processing chamber 111 (with no plasma generated), and in which the variable capacitor 811 in the second reactive circuit 1001 is adjusted to ensure that the operating resonance frequency of the second direct-drive RF signal generator 101B is within the acceptable range of the target operating frequency, e.g., 13.56 MHz. The variable capacitor 801/811 in the first/second reactive circuit 901/1001 is locked at its adjusted capacitance setting, per the pre-calibration process, for delivery of the first/second direct-drive RF signal generator 101A/101B to the semiconductor fabrication facility.

An objective of the manufacturer's pre-calibration process and the in-situ calibration process performed on the first/second direct-drive RF signal generator 101A/101B is to ensure that the RF power delivered by different direct-drive RF signal generators operating at a same target frequency is substantially the same for different plasma processing chambers 111. The reference circuit 1901 in the reference box 1900 is used to achieve this RF power delivery matching from chamber-to-chamber. Another object of the manufacturer's pre-calibration process and the in-situ calibration process performed on the first/second direct-drive RF signal generator 101A/101B is to ensure that the operating frequency of the different direct-drive RF signal generators that have the same target frequency is substantially the same for different plasma processing chambers 111.

During operation, the operating frequency of the first/second direct-drive RF signal generator 101A/101B is controlled to tune the plasma load. Also, during operation, the variable capacitors 801/811 in the first/second reactive circuits 901/1001 are locked/fixed at their calibrated capacitance setting. Therefore, in the semiconductor fabrication facility, two different direct-drive RF signal generators that have the same target operating frequency can actually be operating at different frequencies because the operating frequency of each direct-drive RF signal generator is used to tune the plasma load. Therefore, for the frequency coarse-tuning process done by the manufacturer and for the frequency fine-tuning process (operation 1803) done in-situ, the first/second direct-drive RF signal generator 101A/101B is run in a no-plasma mode, while the variable capacitor 801/811 in the first/second reactive circuit 901/1001 is adjusted so that the operating frequency of the first/second direct-drive RF signal generator 101A/101B is within an acceptable range of the target operating frequency, thereby ensuring that the operating frequency of the first/second direct-drive RF signal generator 101A/101B is sufficiently the same between different plasma processing systems (chamber-to-chamber).

Operation of the plasma processing system 100 in the no-plasma mode includes operating the first/second direct-drive RF signal generator 101A/101B to drive RF power through the coil assembly 109, with process gas supplied to the plasma processing chamber 111 at a high enough pressure to prevent generation of the plasma 211 in the plasma processing chamber 111. Therefore, when the plasma processing system 100 is operating in the no-plasma mode, there is no RF power drawn from the coil assembly 109 into the plasma 211. Therefore, the no-plasma mode is used to characterize actual RF power losses in the first/second reactive circuit 901/1001 and the coil assembly 109, as well as RF power losses that may be caused by power dissipation currents that form in enclosures, connectors, etc., through/over which RF power is transmitted in route from the first/second direct-drive RF signal generator 101A/101B to the plasma processing chamber 111.

In some embodiments, RF power losses in the coil assembly 109 and RF power losses caused by power dissipation currents are on the order of 1% to 2% of the RF power output by the first/second direct-drive RF signal generator 101A/101B. Also, in some embodiments, it is desirable/specified for the RF power delivered to the plasma 211 in different plasma processing systems 100 to be within 1% of a target amount of delivered RF power. Therefore, in these embodiments, it is necessary to compensate for the unique RF power loss characteristics of the plasma processing system 100 that may occur in the coil assembly 109 and because of power dissipation currents. The characterization of the RF power losses in the plasma processing system 100 obtained from the no-plasma mode test is used to adjust the RF power output of the first/second direct-drive RF signal generator 101A/101B to compensate for the unique RF power loss characteristics of the plasma processing system 100.

In some embodiments, the frequency fine-tuning process of operation 1803 includes having the controller 1404 direct a sweeping (incremental adjustment) of the operating frequency of the first/second direct-drive RF signal generator 101A/101B to find the operating resonance frequency for the extant capacitance setting of the variable capacitor 801/811 in the first/second reactive circuit 901/1001. The operating resonance frequency obtained using the extant capacitance setting is compared to the target operating frequency to determine an adjustment recommendation for the capacitance setting of the variable capacitor 801/811 in the first/second reactive circuit 901/1001 that will move the operating resonance frequency toward the target operating frequency. The capacitance setting of the variable capacitor 801/811 in the first/second reactive circuit 901/1001 is then adjusted in accordance with the recommendation. Then, the controller 1404 is operated to repeat the sweeping of the operating frequency of the first/second direct-drive RF signal generator 101A/101B to find the operating resonance frequency for the newly adjusted capacitance setting of the variable capacitor 801/811 in the first/second reactive circuit 901/1001. The operating resonance frequency obtained using the extant capacitance setting is again compared to the target operating frequency to determine an adjustment recommendation for the capacitance setting of the variable capacitor 801/811 in the first/second reactive circuit 901/1001 that will move the operating resonance frequency toward the target operating frequency, and the recommended capacitance setting adjustment is made to the variable capacitor 801/811 in the first/second reactive circuit 901/1001. The above-described procedure is repeated until the operating resonance frequency of the first/second direct-drive RF signal generator 101A/101B is within the acceptable range of the target operating frequency, at which point the capacitance setting of the variable capacitor 801/811 in the first/second reactive circuit 901/1001 is locked at its tuned position.

In some embodiments, the adjustment of the capacitance setting of the variable capacitor 801/811 in the first/second reactive circuit 901/1001 is done manually by inserting a tool, e.g., screwdriver, through the access port 707A/707B in the front wall of the junction box 121A/121B to turn capacitance setting control 801A/811A on the variable capacitor 801/811. In some of these embodiments, the adjustment recommendation for the capacitance setting of the variable capacitor 801/811 is specified as a number of turns of the capacitance setting control 801A/811A either clockwise or counter-clockwise, where the number of turns is either a whole number and/or fractional number.

In some embodiments, the capacitance setting control 801A/811A on the variable capacitor 801/811 provides for automated adjustment of the capacitance setting of the variable capacitor 801/811, such as by way of stepper motor and corresponding mechanical linkage, by way of example. In these embodiments, the adjustment of the capacitance setting of the variable capacitor 801/811 in the first/second reactive circuit 901/1001 is done automatically by having the controller 1404 transmit control signals to the capacitance setting control 801A/811A, where the control signals direct the capacitance setting control 801A/811A to automatically implement the recommended adjustment for the capacitance setting of the variable capacitor 801/811. In some embodiments, the control signals are transmitted as electrical signals through wired connections between the controller 1404 and the capacitance setting control 801A/811A. In some embodiments, the control signals are transmitted as wireless signals from the controller 1404 to the capacitance setting control 801A/811A. Also, in some embodiments, information is transmitted from the capacitance setting control 801A/811A to the controller 1404, such as to indicate the extant capacitance setting, where the information is transmitted through either electrical signals or wireless signals.

Operation 1801 of the method of FIG. 18 requires the measurement of RF power output by the first/second direct-drive RF signal generator 101A/101B. Most industry standard RF power meters are designed to connect between a reference impedance, e.g., 50 ohm, output of an RF power source and a same reference impedance, e.g., 50 ohm, load to which RF power is transmitted by the RF power source. The first/second direct-drive RF signal generator 101A/101B does not have a reference impedance, e.g., 50 ohm, output to which an industry standard RF power meter can connect. Also, the first/second direct-drive RF signal generator 101A/101B does not have a standard RF power output connector to which an industry standard RF power meter can connect. Also, the plasma processing system 100 does not have an impedance matching network or a reference impedance, e.g., 50 ohm, cable over which RF power is transmitted to facilitate connection of an industry standard RF power meter to measure the RF power output by the first/second direct-drive RF signal generator 101A/101B. However, it is desirable to be able to use an industry standard RF power meter to measure the RF power output by the first/second direct-drive RF signal generator 101A/101B. To this end, a reference box 1900 that implements a reference circuit 1901 is disclosed herein to enable use of a reference impedance, e.g., 50 ohm, industry standard RF power meter to measure the RF power output by the first/second direct-drive RF signal generator 101A/101B. The reference box 1900 that implements the reference circuit 1901 is used to performed the operation 1801.

FIG. 19 shows a schematic of the reference circuit 1901 implemented within the reference box 1900, in accordance with some embodiments. An input connector 1902 of the reference box 1900 is electrically connected to receive RF power from the output of the first/second direct-drive RF signal generator 101A/101B, with the output of the first/second direct-drive RF signal generator 101A/101B disconnected form the corresponding reactive circuit 901/1001. In some embodiments, when the reference box 1900 is used to perform operation 1801, the first/second upper RF connection structure 301A/301B is electrically disconnected from the first/second lower RF connection structure 705A/705B, so that the first/second direct-drive RF signal generator 101A/101B is electrically disconnected from the first/second reactive circuit 901/1001. The input connector 1902 of the reference box 1900 is then electrically connected to the first/second upper RF connection structure 301A/301B, so that RF power output by the first/second direct-drive RF signal generator 101A/101B will be transmitted through the reference circuit 1901 within the reference box 1900. The reference circuit 1901 includes an inductor 1905, a series capacitor 1909, and shunt capacitor 1913. The input connector 1902 is electrically connected through a connector 1903 to an input terminal of the inductor 1905. An output terminal of the inductor 1905 is electrically connected through a connector 1907 to an input terminal of the series capacitor 1909. An output terminal of the series capacitor 1909 is electrically connected through a connector 1911 to both an input terminal of the shunt capacitor 1913 and an output 1917 of the reference box 1900. An output terminal of the shunt capacitor 1913 is electrically connected through a connector 1915 to the reference ground potential 903. In some embodiments, the connector 1915 is a wall of the reference box 1900 itself. The input connector 1902 and the connectors 1903, 1907, 1911, and 1915 are formed of electrically conductive material(s) over which RF power is readily transmitted.

The output 1917 of the reference box 1900 is electrically connected to an RF power input of an industry standard reference impedance, e.g., 50 ohm, RF power meter 1919. An RF power output of the RF power meter 1919 is electrically connected through a reference impedance, e.g., 50 ohm, cable 1923 to a reference impedance, e.g., 50 ohm, test load 1921. A data interface of the RF power meter 1919 is connected to a controller 1925, as indicated by a connection 1927. In some embodiments, the connection 1927 is a wired connection through which electrical signals are transmitted to convey information between the RF power meter 1919 and the controller 1925. In some embodiments, the connection 1927 is a wireless connection over which wireless signals are transmitted to convey information between the RF power meter 1919 and the controller 1925. In some embodiments, the controller 1925 is implemented as computer-executable program instructions. In some embodiments, the controller 1925 is implemented as a combination of software, hardware, and/or firmware. The controller 1925 is connected in data communication with a user interface 1929, as indicated by a connection 1931. In some embodiments, the connection 1931 is a wired connection through which electrical signals are transmitted to convey information between the controller 1925 and the user interface 1929. In some embodiments, the connection 1931 is a wireless connection over which wireless signals are transmitted to convey information between the controller 1925 and the user interface 1929. In some embodiments, the user interface 1929 includes a display device on which computer generated graphical information is displayable. In some embodiments, the user interface 1929 includes an input/output (I/O) device through which a user is able to provide information/instructions to the controller 1925. In some embodiments, the input device is a keyboard, keypad, touch-screen, and/or control panel, among other types of input devices.

In some embodiments, the controller 1925 is a stand-alone controller connected in data communication with the controller 1404 of the first/second direct-drive RF signal generator 101A/101B, as indicated by a connection 1933. In some embodiments, the connection 1933 is a wired connection through which electrical signals are transmitted to convey information between the controller 1925 and the controller 1404. In some embodiments, the connection 1933 is a wireless connection over which wireless signals are transmitted to convey information between the controller 1925 and the controller 1404. In some embodiments, the controller 1925 is implemented within the controller 1404 of the first/second direct-drive RF signal generator 101A/101B. In some of these embodiments, the connection 1933 is one or more electrical connections between the controller 1925 and the controller 1404. In some embodiments, the controller 1925 is integrated within the controller 1404 such that the connection 1933 is not necessary.

The reference circuit 1901 is configured to convert the non-reference output impedance, e.g., the non-50 ohm output impedance, of the first/second direct-drive RF signal generator 101A/101B to a reference output impedance, e.g., to a 50 ohm output impedance, at the output 1917 of the reference box 1900. In some embodiments, the output impedance of the first/second direct-drive RF signal generator 101A/101B is less than 1 ohm. In some embodiments, the output impedance of the first/second direct-drive RF signal generator 101A/101B is within a range extending from about 0.1 ohm to about 0.5 ohm. In some embodiments, the output impedance of the first/second direct-drive RF signal generator 101A/101B is about 0.5 ohm.

In the operation 1801, RF power output by the first/second direct-drive RF signal generator 101A/101B is driven through the reference circuit 1901, through the RF power meter 1919, and through the reference impedance, e.g., 50 ohm, cable 1923 to the reference impedance, e.g., 50 ohm, test load. The reference circuit 1901 converts the signal output by the first/second direct-drive RF signal generator 101A/101B to the reference impedance, e.g., to 50 ohms, for the purpose of measuring the transmitted RF power using the industry standard reference impedance, e.g., 50 ohm, RF power meter 1919. There is a different reference circuit 1901, and correspondingly a different reference box 1900, for each target operating frequency of the first/second direct-drive RF signal generator 101A/101B. However, the same reference circuit 1901 (reference box 1900) can be used in the operation 1801 to measure the RF power output by different instances of the first/second direct-drive RF signal generator 101A/101B that have the same target operating frequency. Therefore, a first reference circuit 1901 (first reference box 1900) configured for a first target operating frequency, e.g., 2 MHz, can be used to perform the operation 1801 on different instances of the first direct-drive RF signal generator 101A. Likewise, a second reference circuit 1901 (second reference box 1900) configured for a second target operating frequency, e.g., 13.56 MHz, can be used to perform the operation 1801 on different instances of the second direct-drive RF signal generator 101B. In some embodiments, the reference circuits 1901 (reference boxes 1900) for different target operating frequencies will have a different inductance value for the inductor 1905, and/or a different capacitance value for the series capacitor 1909, and/or have a different capacitance value for the shunt capacitor 1913.

FIG. 20A shows a perspective view of the reference box 1900 connected to the first/second upper coupling structure 503A/503B, in accordance with some embodiments. As previously discussed with regard to FIGS. 6 and 7A-7C, the first/second RF jumper 501A/501B is removed to enable connection of the reference circuit 901 (reference box 1900) to receive the RF power output by the first/second direct-drive RF signal generator 101A/101B instead of having the RF power transmitted to the first/second reactive circuit 901/1001. In some embodiments, with the first/second RF jumper 501A/501B removed, the reference box 1900 is positioned so that the input connector 1902 of the reference box 1900 is inserted into the first/second upper coupling structure 503A/503B. Also, the reference box 1900 includes a dielectric member 1904 disposed to electrically separate the input connector 1902 from the grounded wall/structure of the reference box 1900. The dielectric member 1904 is formed by an electrical insulator material over which RF power does not easily travel. FIG. 20B shows the perspective view of the reference box 1900 of FIG. 20A with the top and sides of the reference box 1900 removed to reveal the components of the reference circuit 1901 as previously discussed with regard to FIG. 19, in accordance with some embodiments.

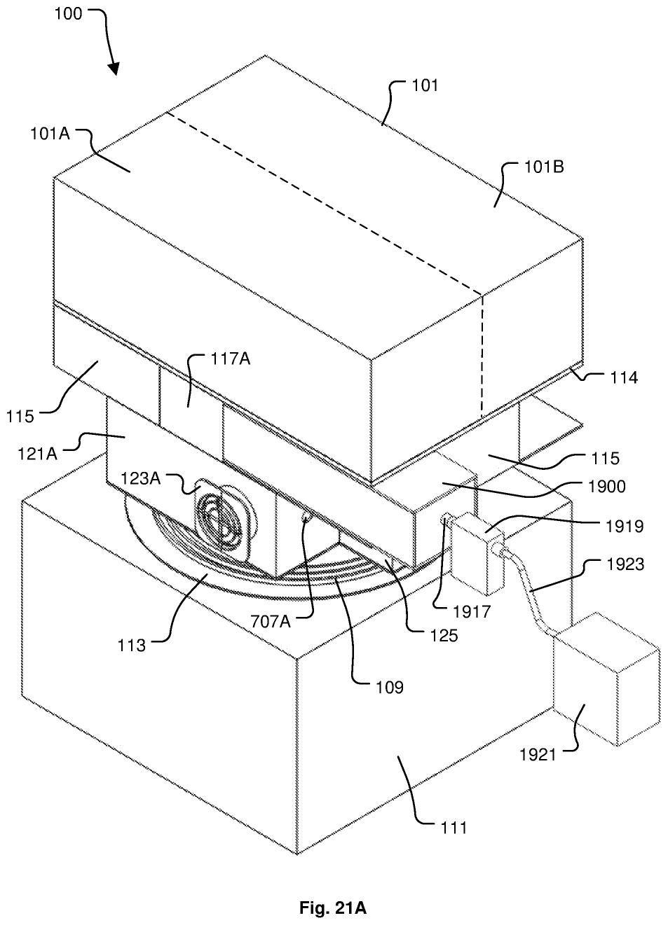

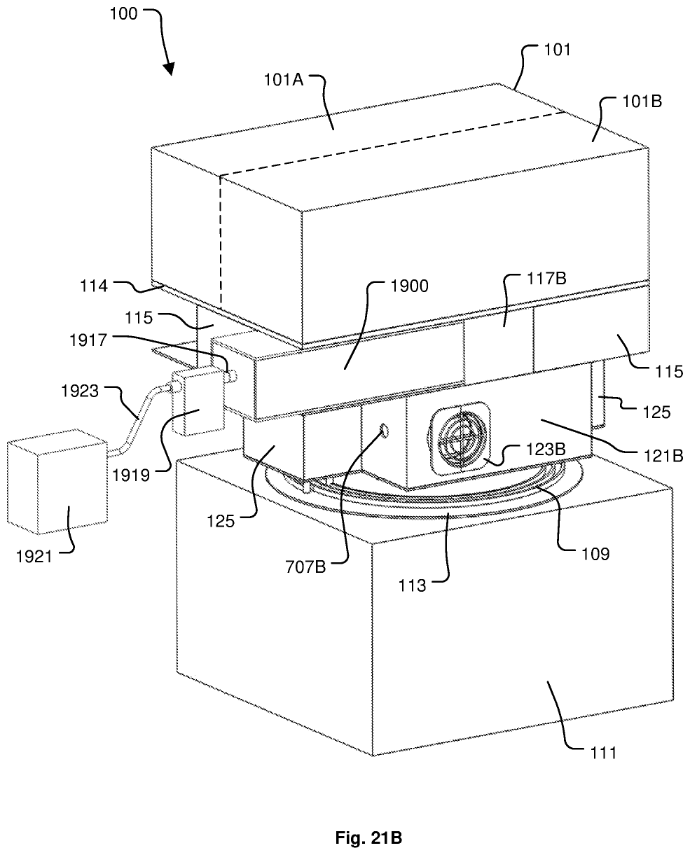

FIG. 21A shows an isometric view of the plasma processing system 100 with the reference box 1900 connected to the first upper coupling structure 503A to receive RF power from the first direct-drive RF signal generator 101A, in accordance with some embodiments. In this example embodiment, the removable door 119A (see FIG. 4) is removed from the first RF connection enclosure 117A to reveal the access opening 502A (see FIG. 5) through which the input connector 1902 is positioned to engage with the first upper coupling structure 503A. In this example embodiment, the reference box 1900 is inserted between the platform 114 and the junction box 121A, and the reference box 1900 is slid in a front-to-back direction to engage the input connector 1902 with the first upper coupling structure 503A. Conversely, the reference box 1900 is removed by sliding the reference box 1900 in a back-to-front direction to disengage the input connector 1902 from the first upper coupling structure 503A.

FIG. 21B shows an isometric view of the plasma processing system 100 with the reference box 1900 connected to the second upper coupling structure 503B to receive RF power from the second direct-drive RF signal generator 101B, in accordance with some embodiments. In this example embodiment, the removable door 119B (see FIG. 4) is removed from the second RF connection enclosure 117B to reveal the access opening 502B (see FIG. 5) through which the input connector 1902 is positioned to engage with the second upper coupling structure 503B. In this example embodiment, the reference box 1900 is inserted between the platform 114 and the junction box 121B, and the reference box 1900 is slid in a front-to-back direction to engage the input connector 1902 with the second upper coupling structure 503B. Conversely, the reference box 1900 is removed by sliding the reference box 1900 in a back-to-front direction to disengage the input connector 1902 from the second upper coupling structure 503B.

FIG. 22 shows a flowchart of a method for connecting the reference box 1900 to the plasma processing system 100, in accordance with some embodiments. An operation 2201 is performed to remove the first/second RF jumper 501A/501B to electrically disconnect the RF power output of the first/second direct-drive RF signal generator 101A/101B from the reactive circuit 901/1001. An operation 2203 is performed to electrically connect the input connector 1902 of the reference circuit 1901 (reference box 1900) to the RF power output of the first/second direct-drive RF signal generator 101A/101B. An operation 2205 is performed to electrically connect the RF power input of the industry standard reference impedance, e.g., 50 ohm, RF power meter 1919 to the output 1917 of the reference circuit 1901 (reference box 1900). In some embodiments, the electrical connection of the RF power meter 1919 to the output 1917 of the reference circuit 1901 (reference box 1900) is made by a direct, solid electrical connection in order to avoid having to determine RF power loss in a cable that would otherwise be used to connect the RF power meter 1919 to the output 1917 of the reference circuit 1901 (reference box 1900). An operation 2207 is performed to electrically connect the RF power output of the RF power meter 1919 to the reference impedance, e.g., 50 ohm, test load 1921. An operation 2209 is also performed to establish the connection 1927 for transfer of data between the RF power meter 1919 and the controller 1925.

The reference circuit 1901 (reference box 1900) has to be calibrated for RF power loss itself because the conversion that it does from the non-reference output impedance, e.g., non-50 ohm output impedance, of the first/second direct-drive RF signal generator 101A/101B to the reference output impedance, e.g., 50 ohm output impedance, of the reference circuit 1901 (reference box 1900) has associated RF power losses. If the amount of RF power loss within the reference circuit 1901 (reference box 1900) is known, the RF power measured by the RF power meter 1919 can be used to determine the amount of RF power that is actually being output by the first/second direct-drive RF signal generator 101A/101B. For example, if the RF power measured by the RF power meter 1919 is 3000 Watts (W) and it is known that the reference circuit 1901 (reference box 1900) dissipates 100 W, then it is known that the total RF power output by the first/second direct-drive RF signal generator 101A/101B is 3100 W. In some embodiments, the RF power loss in a field unit reference box 1900 (for use in the semiconductor fabrication facility) is calibrated against the RF power loss in a master-standard reference box 1900. In some embodiments, the master-standard reference box is maintained by the reference box 1900 manufacturer.

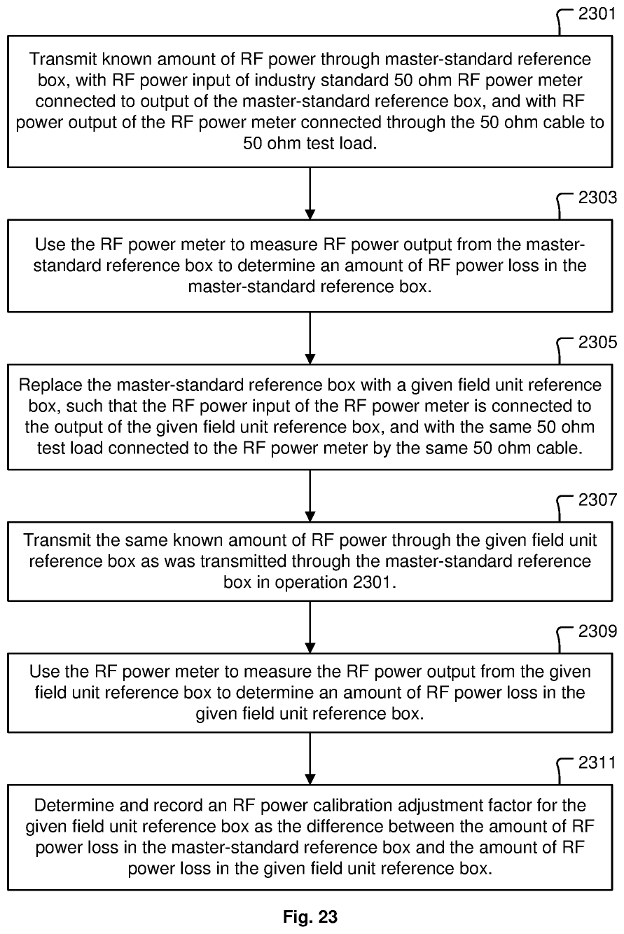

FIG. 23 shows a flowchart of a method for calibrating the field unit reference box 1900 against the master-standard reference box 1900, in accordance with some embodiments. The field unit reference box 1900 and the master-standard reference box 1900 are configured in a substantially identical manner. However, due to manufacturing tolerances/variances in the various components within the reference circuit 1901, each field unit reference box 1900 and the master-standard reference box 1900 will dissipate different amounts of RF power. The method includes an operation 2301 for transmitting a known amount of RF power through the master-standard reference box 1900, with the RF power input of the industry standard reference impedance, e.g., 50 ohm, RF power meter 1919 connected to the output 1917 of the master-standard reference box 1900, and with the RF power output of the RF power meter 1919 connected through the reference impedance, e.g., 50 ohm, cable to the reference impedance, e.g., 50 ohm, test load 1921. An operation 2303 is performed to use the RF power meter 1919 to measure the RF power output from the master-standard reference box 1900 to determine an amount of RF power loss in the master-standard reference box 1900. An operation 2305 is performed to replace the master-standard reference box 1900 with a given field unit reference box 1900, such that the RF power input of the RF power meter 1919 is connected to the output 1917 of the given field unit reference box 1900, and with the same reference impedance, e.g., 50 ohm, test load connected to the RF power meter 1919 by the same reference impedance, e.g., 50 ohm, cable. An operation 2307 is then performed to transmit the same known amount of RF power through the given field unit reference box 1900 as was transmitted through the master-standard reference box 1900 in operation 2301. An operation 2309 is performed to use the RF power meter 1919 to measure the RF power output from the given field unit reference box 1900 to determine an amount of RF power loss in the given field unit reference box 1900.

The method also includes an operation 2311 to determine and record an RF power calibration adjustment factor for the given field unit reference box 1900 as the difference between the amount of RF power loss in the master-standard reference box 1900 and the amount of RF power loss in the given field unit reference box 1900. The RF power calibration adjustment factor for the given field unit reference box 1900 can be either positive or negative, dependent on whether more or less RF power is dissipated in the given field unit reference box 1900 as compared to the master-standard reference box 1900. In some embodiments, a record is maintained of the RF power calibration adjustment factor for the given field unit reference box 1900, such as by recording the RF power calibration adjustment factor in connection with a serial number for the given field unit reference box 1900. In some embodiments, the RF power calibration adjustment factor is engraved on the side of the given field unit reference box 1900. In some embodiments, the RF power calibration adjustment factor for the given field unit reference box 1900 is stored on a computer readable medium, e.g., flash drive, etc., inside of the given field unit reference box 1900, such that the RF calibration adjustment factor can be automatically read and applied by the controller 1925 when performing the RF power calibration of operation 1801. Also, in some embodiments, the field unit reference box 1900 is equipped with an ethernet port, or similar data connection port, that provides for digital data connection between the computer readable medium inside the field unit reference box 1900 and the controller 1925.

FIG. 24 shows a flowchart of a method for using the field unit reference box 1900 to calibrate the RF power output of the first/second direct-drive RF signal generator 101A/101B, in accordance with some embodiments. The input connector 1902 of the field unit reference box 1900 is electrically connected to the RF power output of the first/second direct-drive RF signal generator 101A/101B in accordance with the method of FIG. 22 before performing the method of FIG. 24. The method includes an operation 2401 for providing the RF power calibration adjustment factor for the field unit reference box 1900, as determined by the method of FIG. 23, to the controller 1925. The method includes an operation 2403 for operating the first/second direct-drive RF signal generator 101A/101B at the target operating frequency to transmit a specified amount of RF power through the reference circuit 1901 of the field unit reference box 1900, the RF power meter 1919, and the reference impedance, e.g., 50 ohm, cable 1923 to the reference impedance, e.g., 50 ohm, test load 1921. The specified amount of RF power is prescribed in an RF power output calibration schedule for the first/second direct-drive RF signal generator 101A/101B to be processed by the controller 1925. In an operation 2405, the RF power meter 1919 is operated to measure an amount of RF power output from the field unit reference box 1900 for the specified amount of RF power transmitted in the operation 2403, and communicate the amount of RF power output from the field unit reference box 1900 to the controller 1925. In an operation 2407, the controller 1925 determines an adjusted amount of RF power output from the field unit reference box 1900 by applying the RF power calibration adjustment factor for the field unit reference box 1900 as received in the operation 2401 to the amount of RF power measured by the RF power meter 1919 in the operation 2405. It should be understood that the adjusted amount of RF power output from the field unit reference box 1900 represents the amount of RF power that would have been output from the master-standard reference box 1900 if it had been used instead of the field unit reference box 1900.

In an operation 2409, the adjusted amount of RF power output from the field unit reference box 1900 is stored in a lookup table for the specified amount of RF power transmitted in the operation 2403 as an RF power output calibration data point for the first/second direct-drive RF signal generator 101A/101B. The method proceeds with an operation 2411 to determine whether or not another RF power setpoint needs to be processed in the RF power output calibration schedule for the first/second direct-drive RF signal generator 101A/101B. If the determination in operation 2411 is yes, the method reverts back to the operation 2403 for operating the first/second direct-drive RF signal generator 101A/101B to transmit the next specified amount of RF power in the calibration schedule. If the determination in operation 2411 is no, the method proceeds with an operation 2413 to conclude the RF power calibration of the first/second direct-drive RF signal generator 101A/101B. In some embodiments, the operation 2413 includes using the RF power output calibration data points as stored in the lookup table in operation 2409 for the various RF power setpoints in the RF power output calibration schedule to determine a function/formula that specifies an RF power setting for the first/second direct-drive RF signal generator 101A/101B that is required to obtain a target RF power output from the first/second direct-drive RF signal generator 101A/101B. For example, if the RF power output calibration indicates that 3002 W is output by the first/second direct-drive RF signal generator 101A/101B when the RF power output setting is 3000 W, the RF power output calibration setting is −2 W, such that the RF power output setting of 3000 W is automatically adjusted to 2998 W by the controller 1925 during normal operation. Also, the operation 2413 includes disconnecting the field unit reference box 1900 from the RF power output of the first/second direct-drive RF signal generator 101A/101B. Also, the operation 2413 includes reconnecting the RF power output of the first/second direct-drive RF signal generator 101A/101B to the first/second reference circuit 901/1001, such as by re-inserting the first/second RF jumper structure 501A/501B into both the first/second upper coupling structures 503A/503B and the first/second lower coupling structures 505A/505B, and by securing the first/second bolt 753A/753B through the first/second RF jumper structure 501A/501B to the first/second dielectric bracket 751A/751B (see FIG. 7B).

In some embodiments, as the RF power is transmitted through the reference circuit 1901 of the field unit reference box 1900, the thermal load in the components in the reference circuit 1901 increases and causes a corresponding increase in the temperatures of the components in the reference circuit 1901, which in turn changes the RF power dissipation characteristics of the components in the reference circuit 1901 to the point where the RF power calibration adjustment factor for the field unit reference box 1900 may no longer be applicable. In some embodiments, to mitigate and/or prevent increase in temperatures of the components in the reference circuit 1901 that would cause the RF power calibration adjustment factor for the field unit reference box 1900 to no longer be applicable, the operation 2403 is performed in a pulsed manner. More specifically, in the operation 2403, the first/second direct-drive RF signal generator 101A/101B is operated at the target operating frequency to transmit the specified amount of RF power through the reference circuit 1901 of the field unit reference box 1900 in a pulsed manner, such that the “on” portion of each RF power transmission pulse cycle is long enough to establish stable RF power transmission for the purpose of RF power output calibration, and with the “off” portion of each RF power transmission pulse cycle set long enough to ensure that the components in the reference circuit 1901 of the field unit reference box 1900 do not increase in temperature to a point where the RF power calibration adjustment factor for the field unit reference box 1900 is no longer applicable. In these embodiments, the controller 1925 synchronizes the RF power measurement by the RF power meter 1919 in the operation 2405 with the “on” portion of each RF power transmission pulse cycle. In some embodiments, the “on” portion of each RF power transmission pulse cycle is less than about 10% of the total pulse cycle length (“on” portion plus “off” portion). In some embodiments, a thermal sensitivity evaluation of the field unit reference box 1900 is performed by testing the to determine how much the RF power dissipation within the field unit reference box 1900 changes with variations in temperatures of the components in the reference circuit 1901 of the field unit reference box 1900. Based on this thermal sensitivity evaluation, a maximum allowable thermal load for the field unit reference box 1900 is determined for a given RF power calibration adjustment factor for the field unit reference box 1900. In some embodiments, the thermal sensitivity evaluation is used to determine a duty cycle for the “on/off” pulsing of the first/second direct-drive RF signal generator 101A/101B for use in performing the operation 2403 in order to avoid adverse temperature-induced drift in RF power dissipation characteristics of the components in the reference circuit 1901 of the field unit reference box 1900.

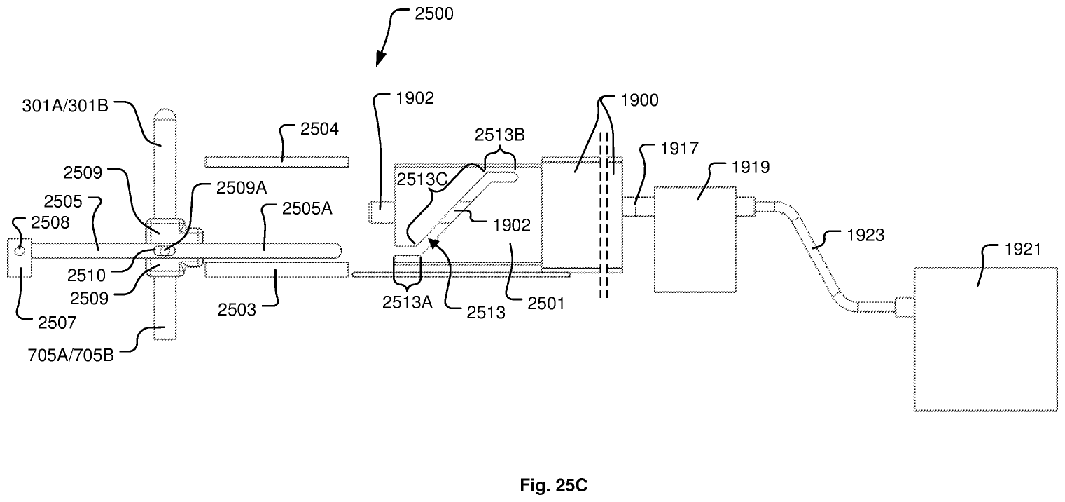

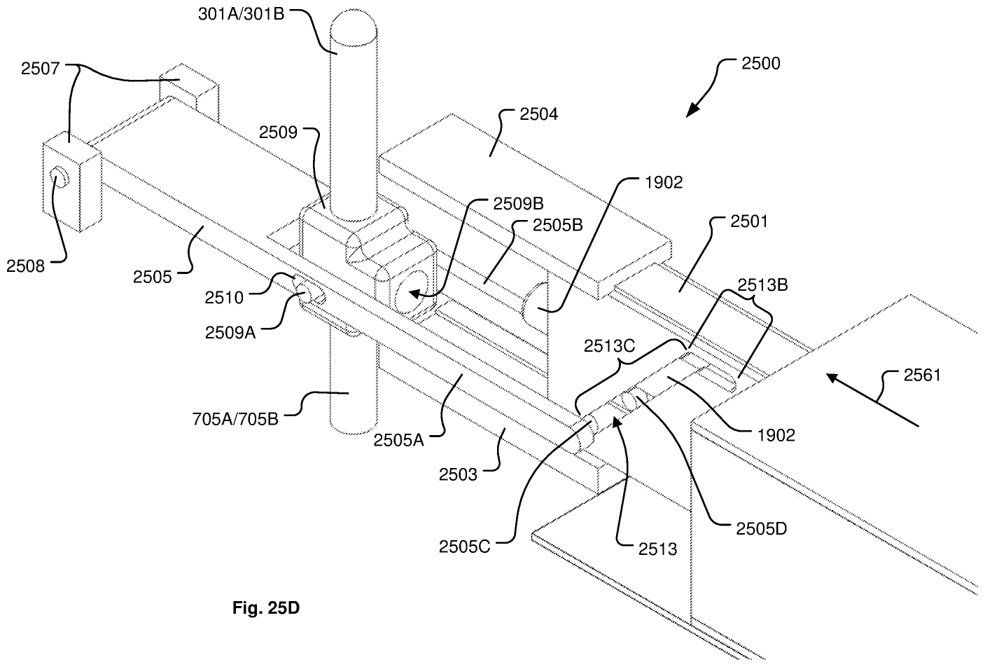

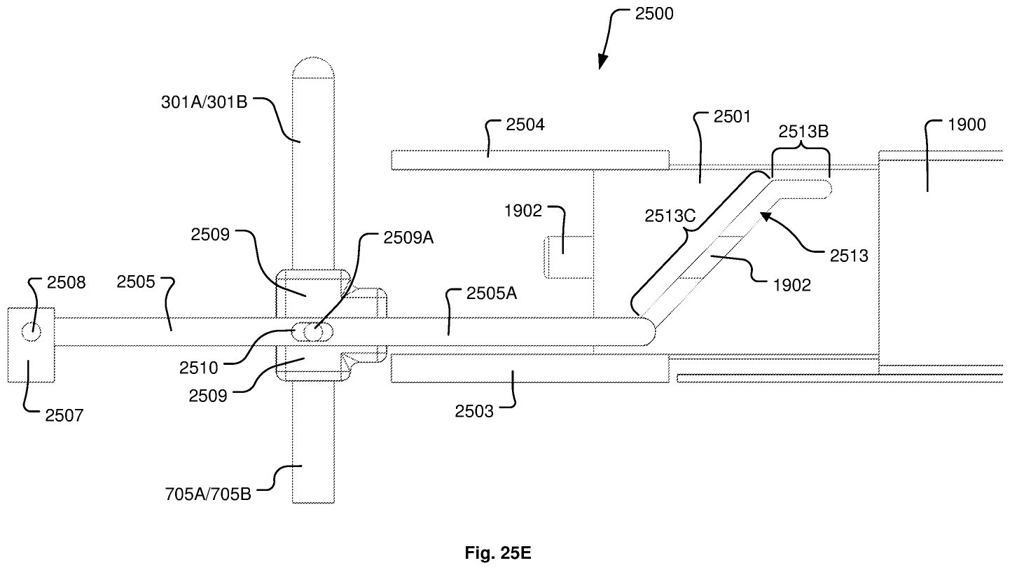

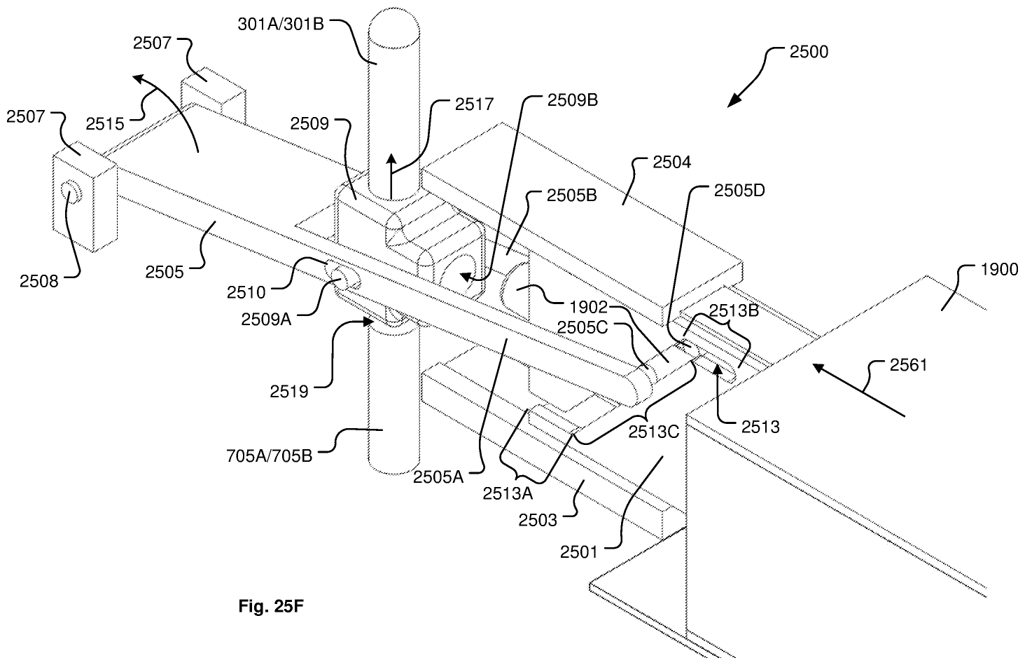

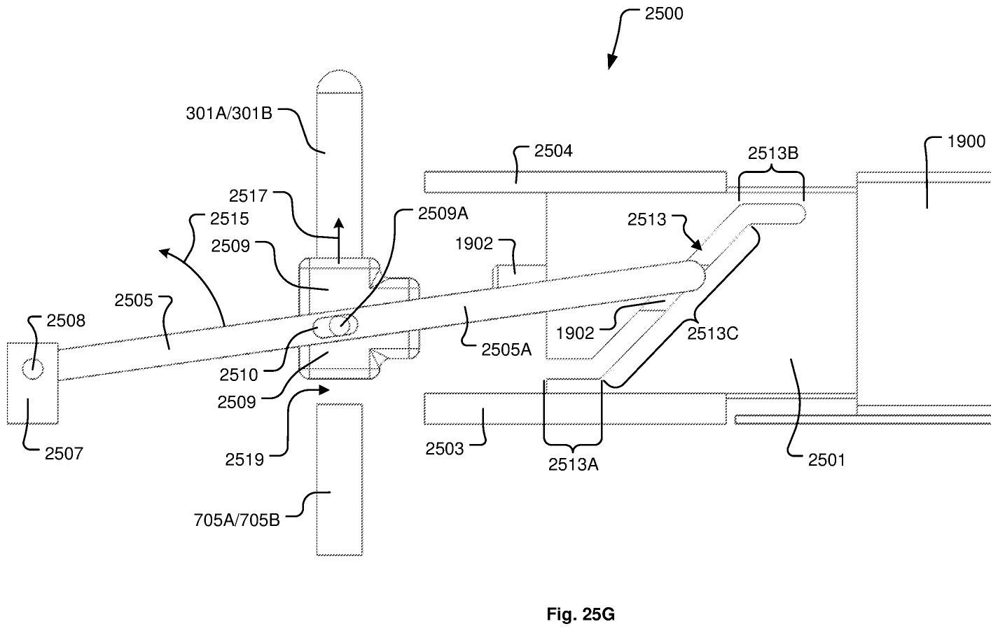

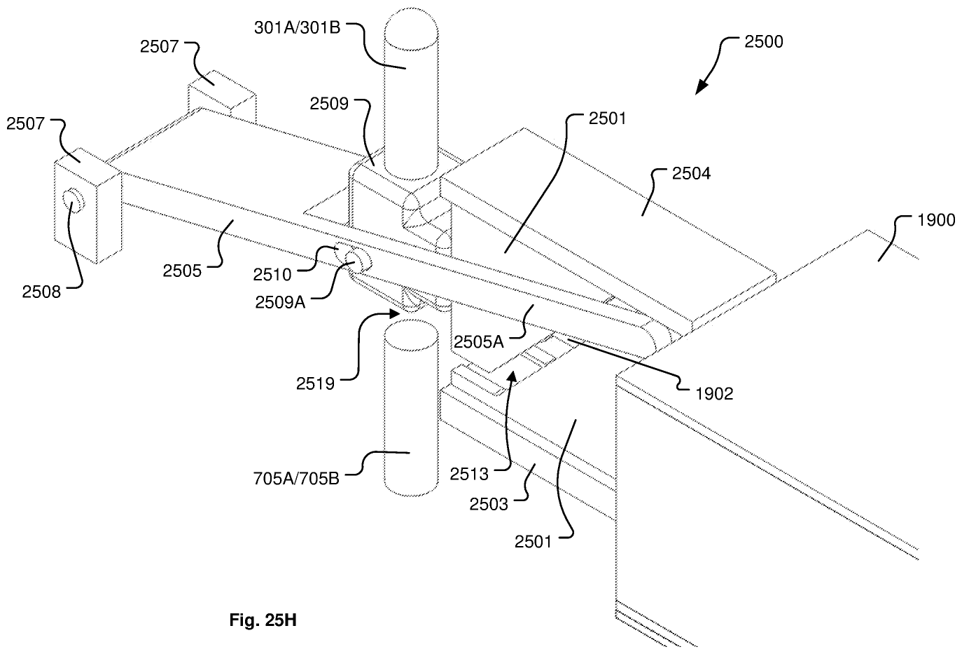

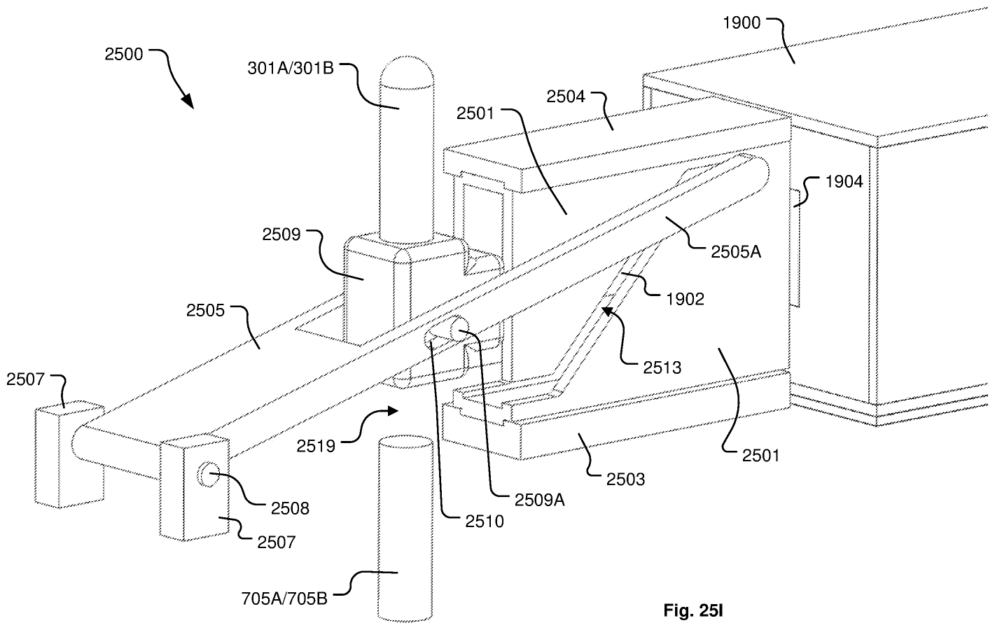

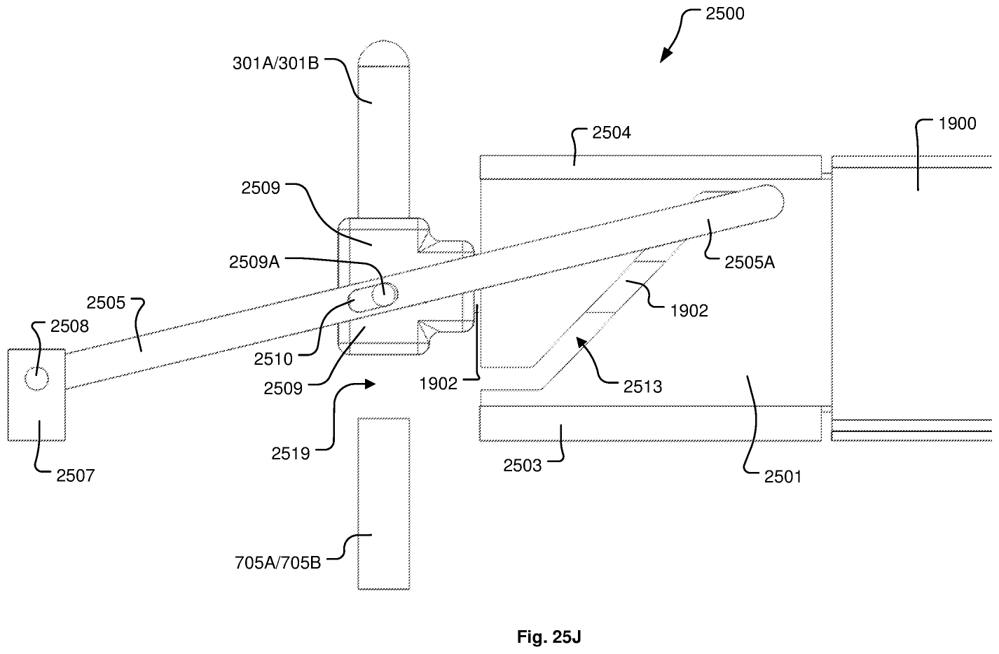

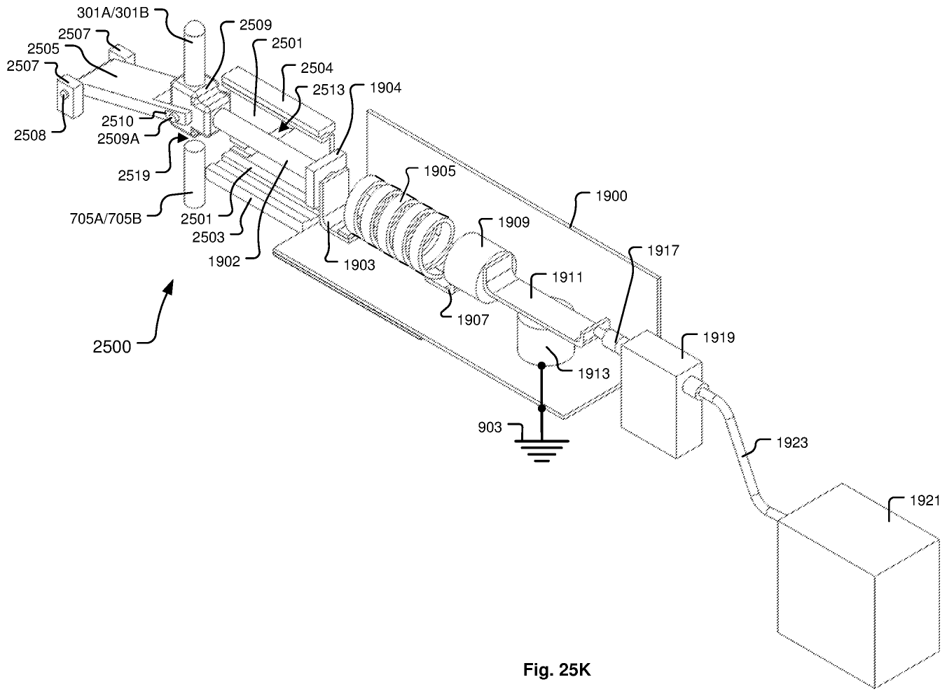

FIG. 25A shows an isometric view of a hands-free reference box connection system 2500, in accordance with some embodiments. The reference box connection system 2500 provides for hands-free disconnection of the RF power output of the first/second direct-drive RF signal generator 101A/101B from the downstream RF power transmission system that includes the first/second reference circuit 901/1001 and coil assembly 109. The reference box connection system 2500 also provides for hands-free connection of the input connector 1902 of the field unit reference box 1900 to the RF power output of the first/second direct-drive RF signal generator 101A/101B. In this manner, the reference box connection system 2500 is used in lieu of the first/second RF jumper structure 501A/501B that is simultaneously inserted into both the first/second upper coupling structure 503A/503B and the first/second lower coupling structure 505A/505B, as previously described with regard to FIGS. 7A-7C.

In the reference box connection system 2500, the field unit reference box 1900 is equipped with a guide plate 2501. Specifically, the guide plate 2501 is attached to an end of the field unit reference box 1900 through which the input connector 1902 extends. The input connector 1902 is configured to extend from the field unit reference box 1900 through an inner open region of the guide plate 2501 to a distal end of the guide plate 2501 relative to the field unit reference box 1900. The input connector 1902 extends a distance outward from the distal end of the guide plate 2501, so as to enable insertion of the input connector 1902 into an RF output coupling 2509 when the guide plate 2501 is inserted into the first/second RF connection enclosure 117A/117B. In some embodiments, the guide plate 2501 is formed of an electrical insulator material over which RF power is not readily transmitted. Also, in some embodiments, the inner open region of the guide plate 2501 is sized large enough that the input connector 1902 does not physically contact the guide plate 2501. The RF output coupling 2509 is formed of an electrically conductive material over which RF power is readily transmitted. It should be understood that the reference box connection system 2500 includes the first/second upper RF connection structure 301A/301B and the first/second lower RF connection structure 705A/705B, but does not include the first/second upper coupling structure 503A/503B and the first/second lower coupling structure 505A/505B as previously discussed.

In some embodiments, the reference box connection system 2500 includes a bottom guide rail 2503 and a top guide rail 2504. A bottom surface of the guide plate 2501 is contoured to have a linear-shaped convexity (ridge) that extends in a linear manner along a length of the guide plate 2501 in a direction substantially perpendicular to the end of the field unit reference box 1900 through which the input connector 1902 extends. A top surface of the bottom guide rail 2503 includes a linear-shaped channel configured to receive the linear-shaped convexity on the bottom surface of the guide plate 2501. In some embodiments, a top surface of the guide plate 2501 is contoured to have a linear-shaped convexity (ridge) that extends in a linear manner along a length of the guide plate 2501 in a direction substantially perpendicular to the end of the field unit reference box 1900 through which the input connector 1902 extends. A bottom surface of the top guide rail 2503 includes a linear-shaped channel configured to receive the linear-shaped convexity on the top surface of the guide plate 2501.

FIG. 25B shows an isometric view of the reference box connection system 2500 with the first/second RF connection enclosure 117A/117B removed to more clearly reveal components of the reference box connection system 2500, in accordance with some embodiments. FIG. 25B shows the guide plate 2501 of the field unit reference box 1900 ready to engage the bottom guide rail 2503 and the top guide rail 2504. The linear-shaped channel in the top surface of the bottom guide rail 2503 and the linear-shaped channel in the bottom surface of the top guide rail 2504 are positioned and oriented to direct the input connector 1902 to a location for engagement with the RF output coupling 2509 as the guide plate 2501 is inserted into the first/second RF connection enclosure 117A/117B by moving (sliding) the field unit reference box 1900 toward the first/second RF connection enclosure 117A/117B. FIG. 25C shows a side view of the configuration of FIG. 25B, in accordance with some embodiments.

The reference box connection system 2500 includes a lever member 2505 pivotally connected to a fulcrum 2508. In some embodiments, the fulcrum 2508 is a pin supported by stanchions 2507 positioned on each side of the level member 2505 at a distal end of the lever member 2505 relative to the field unit reference box 1900. In some embodiments, the lever member 2505 is formed of an electrical insulator material over which RF power is not readily transmitted. In some embodiments, the stanchions 2507 are rigidly connected to the structure of the plasma processing system 100, such as to the floor inside the metrology enclosure 115. The lever member 2505 is configured to pivot upward from its resting position, as depicted in FIG. 25B, and pivot back downward to its resting position by rotating about the fulcrum 2508, as indicated by the arrow 2511. In some embodiments, the first/second RF connection enclosure 117A/117B includes an opening 2506 through which the lever member 2505 is positioned, where the opening 2506 is vertically sized large enough to accommodate lifting of the lever member 2505 by rotation about the fulcrum 2508. Alternatively, in some embodiments, the first/second RF connection enclosure 117A/117B is sized large enough to encompass the stanchions 2507, so as avoid having the opening 2506 formed in the wall of the first/second RF connection enclosure 117A/117B.

In some embodiments, the lever member 2505 is fork-shaped to include a first fork 2505A and a second fork 2505B, with an inner open region between the first fork 2505A and the second fork 2505B. The first fork 2505A and the second fork 2505B are configured to extend along opposite sides of the RF output coupling 2509 to a location near the access opening 502A/502B of the first/second RF connection enclosure 117A/117B. The lever member 2505 includes a first lifting pin 2505C connected to an inner side of the first fork 2505A, and second lifting pin 2505D connected to an inner side of the second fork 2505B, such that the first lifting pin 2505C and the second lifting pin 2505D face toward each other across the inner region between the first fork 2505A and the second fork 2505B. In some embodiments, the first lifting pin 2505C and the second lifting pin 2505D are configured as respective cylinders that are horizontally oriented to have substantially co-aligned axes. The first lifting pin 2505C and the second lifting pin 2505D are positioned near the lifting end of the lever member 2505, where the lifting end of the lever member 2505 is opposite from the fulcrum 2508 end of the lifting member 2505.

The first lifting pin 2505C and the second lifting pin 2505D are configured to slide into a guide track 2513 formed within/through each sidewall of the guide plate 2501. The guide track 2513 is formed in a substantially same manner, e.g., size, position, and shape, in each sidewall of the guide plate 2501. The guide track 2513 is configured to receive each of the first lifting pin 2505C and the second lifting pin 2505D and provide for sliding of the first lifting pin 2505C and the second lifting pin 2505D along the guide track 2513. In some embodiments, the guide track 2513 is shaped to include a lower horizontal section 2513A, a upper horizontal section 2513B, and an angled section 2513C (angled with respect to horizontal) extending between the lower horizontal section 2513A and the upper horizontal section 2513B.

The lower horizontal section 2513A is vertically positioned such that the first lifting pin 2505C and the second lifting pin 2505D enter the lower horizontal section 2513A on respective sides of the guide plate 2501 when the lifting end of the lever member 2505 is at its fully lowered position, as the guide plate 2501 is moved toward the RF output coupling 2509 between and along the bottom guide rail 2503 and the top guide rail 2504. The first lifting pin 2505C and the second lifting pin 2505D continue to move along the guide track 2513 as the guide plate 2501 is moved toward the RF output coupling 2509 between and along the bottom guide rail 2503 and the top guide rail 2504. As the first lifting pin 2505C and the second lifting pin 2505D move along the angled section 2513C, the lifting end of the lever member 2505 is raised to cause upward rotation of the lever member 2505 about the fulcrum 2508. When the first lifting pin 2505C and the second lifting pin 2505D enter the upper horizontal section 2513B, the lifting end of the lever member 2505 is at its fully raised position.

Each of the first fork 2505A and the second fork 2505B includes a respective slot 2510 that is configured to receive a respective pin 2509A that extends horizontally outward from respective sides of the RF output coupling 2509. The slot 2510 is configured to allow rotational and sliding movement of the pin 2509A within the slot 2510. As the lifting end of the lever member 2505 is raised because of the first lifting pin 2505C and the second lifting pin 2505D moving along the angled section 2513C of the guide track 2513, the bottom inner surface of the slot 2510 engages the pin 2509A and applies an upward vertical force to the pin 2509A, which causes the RF output coupling 2509 to move vertically upward along the first/second upper RF connection structure 301A/301B. A length of the slot 2510 is sized larger than a diameter of the pin 2509A and the slot 2510 is positioned about the pin 2509A to enable sliding of the pin 2509A within the slot 2510 as the lifting end of the lever member 2505 is rotationally raised and lowered about the fulcrum 2508. Also, it should be understood that as the guide plate 2501 is moved away from the RF output coupling 2509, the lifting end of the lever member 2505 is lowered along the angled section 2513C of the guide track 2513, so as to cause the top inner surface of the slot 2510 to engage the pin 2509A and apply a downward vertical force to the pin 2509A, which causes the RF output coupling 2509 to move vertically downward along the first/second upper RF connection structure 301A/301B.

The RF output coupling 2509 includes an opening 2509B configured to receive the input connector 1902 of the field unit reference box 1900. When the first lifting pin 2505C and the second lifting pin 2505D are positioned in the upper horizontal section 2513B of the guide track 2513 (when the lifting end of the lever member 2505 is at its fully raised position), the RF output coupling 2509 is vertically positioned to receive the input connector 1902 as the input connector 1902 is moved horizontally toward the RF output coupling 2509 by moving of the guide plate 2501 between and along the bottom guide rail 2503 and the top guide rail 2504. When the first lifting pin 2505C and the second lifting pin 2505D are positioned in the upper horizontal section 2513B of the guide track 2513 (when the lifting end of the lever member 2505 is at its fully raised position), the RF output coupling 2509 is vertically positioned to be electrically disconnected from the first/second lower RF connection structure 705A/705B and in turn from the first/second reactive circuit 901/1001. When the first lifting pin 2505C and the second lifting pin 2505D are positioned in the lower horizontal section 2513A of the guide track 2513 (when the lifting end of the lever member 2505 is at its fully lowered position), the RF output coupling 2509 is vertically positioned to be electrically connected to both the first/second upper RF connection structure 301A/301B and the first/second lower RF connection structure 705A/705B, such that the RF power output of the first/second direct-drive RF signal generator 101A/101B is electrically connected to the first/second reactive circuit 901/1001.

FIG. 25D shows an isometric view of the reference box connection system 2500, with the guide plate 2501 of the field unit reference box 1900 inserted between the bottom guide rail 2503 and the top guide rail 2504, and with the guide plate 2501 and field unit reference box 1900 moved in a direction 2561 toward the RF output coupling 2509 up to a point where vertical lifting of the RF output coupling 2509 is to start, in accordance with some embodiments. FIG. 25E shows a side view of the configuration of FIG. 25D, in accordance with some embodiments. In FIGS. 25D and 25E, the first lifting pin 2505C and the second lifting pin 2505D are positioned in the lower horizontal section 2513A of the guide track 2513 and at the lower extent of the angled section 2513C of the guide track 2513. In FIGS. 25A through 25E, the RF power coupling 2509 is electrically connected to both the first/second upper RF connection structure 301A/301B and the first/second lower RF connection structure 705A/705B, such that the RF power coupling 2509 provides an electrical transmission path over which RF power is transmitted from the first/second upper RF connection structure 301A/301B to the first/second lower RF connection structure 705A/705B. In the embodiments that use the reference box connection system 2500, the RF power coupling 2509 provides the electrical transmission path over which RF power is transmitted from the first/second upper RF connection structure 301A/301B to the first/second lower RF connection structure 705A/705B during normal operation of the first/second direct-drive RF signal generator 101A/101B.

FIG. 25F shows an isometric view of the reference box connection system 2500, with the guide plate 2501 of the field unit reference box 1900 inserted between the bottom guide rail 2503 and the top guide rail 2504, and with the guide plate 2501 and field unit reference box 1900 moved further in the direction 2561 toward the RF output coupling 2509 up to a point where vertical lifting of the RF output coupling 2509 in the direction 2517 is at about half way through its vertical stroke length, in accordance with some embodiments. FIG. 25G shows a side view of the configuration of FIG. 25F, in accordance with some embodiments. As the first lifting pin 2505C and the second lifting pin 2505D move upward along the angled section 2513C of the guide track 2513, the lifting end of the lever member 2505 is raised such that the lever member 2505 rotates upward about the fulcrum 2508, as indicated by the arrow 2515. As the lifting end of the lever member 2505 is raised, the first fork 2505A and the second fork 2505B apply an upward force to the pin 2509A to vertically raise the RF output coupling 2509 in the direction 2517. As the RF output coupling 2509 is raised in the direction 2517, the RF output coupling physically and electrically disconnects from the first/second lower RF connection structure 705A/705B, as indicated by a gap 2519 that opens up between the RF output coupling 2509 and the first/second lower RF connection structure 705A/705B. In this manner, the first/second direct-drive RF signal generator 101A/101B is electrically disconnected from the first/second reactive circuit 901/1001. It should be understood, however, that as the RF output coupling is vertically raised in the direction 2517, the RF output coupling 2509 remains physically and electrically connected to the first/second upper RF connection structure 301A/301B.

FIG. 25H shows an isometric view of the reference box connection system 2500, with the guide plate 2501 of the field unit reference box 1900 inserted between the bottom guide rail 2503 and the top guide rail 2504, and with the guide plate 2501 and field unit reference box 1900 moved in the direction 2561 to a fully inserted position at which the input connector 1902 is physically engaged with and electrically connected to the RF output coupling 2509, in accordance with some embodiments. FIG. 25I shows another perspective view of the configuration of FIG. 25H from a point of view looking toward the front of the field unit reference box 1900, in accordance with some embodiments. FIG. 25J shows a side view of the configuration of FIG. 25H, in accordance with some embodiments. In the configuration of FIGS. 25H through 25J, the first lifting pin 2505C and the second lifting pin 2505D are positioned in the upper horizontal section 2513B of the guide track 2513, such that the RF output coupling 2509 has been raised in the direction 2517 over its complete vertical stroke length, with the opening 2509B of the RF output coupling 2509 vertically positioned to receive the input connector 1902 of the field unit reference box 1900 as the field unit reference box 1900 and the input connector 1902 are moved in the direction 2561 to the fully inserted position.

FIG. 25K shows an isometric view of the field unit reference box 1900 in the fully inserted position within the first/second RF connection enclosure 117A/117B, with cut-away views of the top guide rail 2504, guide plate 2501, and reference box 1900 to show the components of the reference circuit 1901, in accordance with some embodiments. FIG. 25K shows the input connector 1902 electrically connected to the RF output coupling 2509. FIG. 25K also shows the RF output coupling 2509 electrically disconnected from the first/second lower RF connection structure 705A/705B, such that the first/second direct-drive RF signal generator 101A/101B is electrically disconnected from the first/second reactive circuit 901/1001. In this manner, the first/second direct-drive RF signal generator 101A/101B operates to drive RF power through the reference circuit 1901 of the field unit reference box 1900, instead of through the first/second reactive circuit 901/1001 to the coil assembly 109. In some embodiments, the connected field unit reference box 1900, as shown in FIG. 25K, is used to perform the method of FIG. 24. It should be understood that when the reference box 1900 and guide plate 2501 is moved along the bottom guide rail 2503 and the top guide rail 2504 away from the RF output coupling 2509, the input connector 1902 disconnects from the RF output coupling, and the lifting end of the lever member 2505 is lowered as the first lifting pin 2505C and the second lifting pin 2505D move downward along the angled section 2513C of the guide track 2513, which in turn causes downward vertical movement of the RF output coupling 2509 to reconnect physically and electrically with the first/second lower RF connection structure 705A/705B, as shown in FIGS. 25B and 25C.

The various embodiments described herein may be practiced in conjunction with various computer system configurations including hand-held hardware units, microprocessor systems, microprocessor-based or programmable consumer electronics, minicomputers, mainframe computers and the like. The various embodiments described herein can also be practiced in conjunction with distributed computing environments where tasks are performed by remote processing hardware units that are linked through a computer network.

In some embodiments, a control system, e.g., host computer system, is provided for controlling the plasma processing system 100. In various embodiments, the plasma processing system 100 includes semiconductor processing equipment, such as processing tool(s), chamber(s), platform(s) for processing, and/or specific processing components such as a wafer pedestal, a gas flow system, among other components. In various embodiments, the plasma processing system 100 is integrated with electronics for controlling its operation before, during, and after processing of a semiconductor wafer or substrate, where the electronics are implemented within a controller that is configured and connected to control various components and/or sub-parts of the plasma processing system 100. Depending on substrate/wafer processing requirements and/or the particular configuration of the plasma processing system 100, the controller is programmed to control any process and/or component disclosed herein, including a delivery of process gas(es), temperature settings (e.g., heating and/or cooling), pressure settings, vacuum settings, power settings, first/second direct-drive RF signal generator 101A/101B settings, first/second reactive circuit 901/1001 settings, electrical signal frequency settings, gas flow rate settings, fluid delivery settings, positional and operation settings, substrate/wafer transfers into and out of the plasma generation chamber 111 and/or into and out of load locks connected to or interfaced with the plasma processing system 100.

Broadly speaking, in a variety of embodiments, the controller that is connected to control operations of the plasma processing system 100 is defined as electronics having various integrated circuits, logic, memory, and/or software that direct and control various tasks/operations, such as receiving instructions, issuing instructions, controlling device operations, enabling cleaning operations, enabling endpoint measurements, enabling metrology measurements (optical, thermal, electrical, etc.), among other tasks/operations. In some embodiments, the integrated circuits within the controller include one or more of firmware that stores program instructions, a digital signal processors (DSP), an Application Specific Integrated Circuit (ASIC) chip, a programmable logic device (PLD), one or more microprocessors, and/or one or more microcontrollers that execute program instructions (e.g., software), among other computing devices. In some embodiments, the program instructions are communicated to the controller in the form of various individual settings (or program files), defining operational parameters for carrying out a process on a substrate/wafer within the plasma processing system 100. In some embodiments, the operational parameters are included in a recipe defined by process engineers to accomplish one or more processing steps during the fabrication of one or more layers, materials, metals, oxides, silicon, silicon dioxide, surfaces, circuits, and/or dies on the substrate/wafer.

In some embodiments, the controller is a part of, or connected to, a computer that is integrated with, or connected to, the plasma processing system 100, or that is otherwise networked to the plasma processing system 100, or a combination thereof. For example, in some embodiments, the controller is implemented in a “cloud” or all or a part of a fab host computer system, which allows for remote access for control of substrate/wafer processing by the plasma processing system 100. The controller enables remote access to the plasma processing system 100 to provide for monitoring of current progress of fabrication operations, provided for examination of a history of past fabrication operations, provide for examination of trends or performance metrics from a plurality of fabrication operations, provide for changing of processing parameters, provide for setting of subsequent processing steps, and/or provide for initiation of a new substrate/wafer fabrication process.

In some embodiments, a remote computer, such as a server computer system, provides process recipes to the controller of the plasma processing system 100 over a computer network, which includes a local network and/or the Internet. The remote computer includes a user interface that enables entry or programming of parameters and/or settings, which are then communicated to the controller of the plasma processing system 100 from the remote computer. In some examples, the controller receives instructions in the form of settings for processing a substrate/wafer within the plasma processing system 100. It should be understood that the settings are specific to a type of process to be performed on a substrate/wafer and a type of tool/device/component that the controller interfaces with or controls. In some embodiments, the controller is distributed, such as by including one or more discrete controllers that are networked together and synchronized to work toward a common purpose, such as operating the plasma processing system 100 to perform a prescribed process on a substrate/wafer. An example of a distributed controller for such purposes includes one or more integrated circuits on a chamber in communication with one or more integrated circuits located remotely (such as at a platform level or as part of a remote computer) that combine to control a process in a chamber. Depending on a process operation to be performed by the plasma processing system 100, the controller communicates with one or more of other tool circuits or modules, other tool components, cluster tools, other tool interfaces, adjacent tools, neighboring tools, tools located throughout a factory, a main computer, another controller, or tools used in material transport that bring containers of substrates/wafers to and from tool locations and/or load ports in a semiconductor manufacturing factory.

It should be understood that, in some embodiments, operation of the plasma processing system 100 includes performance of various computer-implemented operations involving data stored in computer systems. These computer-implemented operations are those that manipulate physical quantities. In various embodiments, the computer-implemented operations are performed by either a general purpose computer or a special purpose computer. In some embodiments, the computer-implemented operations are performed by a selectively activated computer, and/or are directed by one or more computer programs stored in a computer memory or obtained over a computer network. When computer programs and/or digital data is obtained over the computer network, the digital data may be processed by other computers on the computer network, e.g., a cloud of computing resources. The computer programs and digital data are stored as computer-readable code on a non-transitory computer-readable medium. The non-transitory computer-readable medium is any data storage hardware unit, e.g., a memory device, etc., that stores data, which is thereafter readable by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), digital video/versatile disc (DVD), magnetic tapes, and other optical and non-optical data storage hardware units. In some embodiments, the computer programs and/or digital data are distributed among multiple computer-readable media located in different computer systems within a network of coupled computer systems, such that the computer programs and/or digital data is executed and/or stored in a distributed fashion.

Although the foregoing disclosure includes some detail for purposes of clarity of understanding, it will be apparent that certain changes and modifications can be practiced within the scope of the appended claims. For example, it should be understood that one or more features from any embodiment disclosed herein may be combined with one or more features of any other embodiment disclosed herein. Accordingly, the present embodiments are to be considered as illustrative and not restrictive, and what is claimed is not to be limited to the details given herein, but may be modified within the scope and equivalents of the described embodiments.

1. A reference box for a direct-drive radiofrequency power supply, comprising:
an input connector;
a reference circuit having an input terminal connected to the input connector, the reference circuit configured to convert a non-reference input impedance to a reference output impedance; and
an output connector connected to an output terminal of the reference circuit.

2. The reference box as recited in claim 1, wherein the input connector extends outward from an end of the reference box.

3. The reference box as recited in claim 2, wherein the reference box is movable to enable sliding of the input connector in a substantially linear manner to electrically connect with a radiofrequency output coupling of the direct-drive radiofrequency power supply and to electrically disconnect from the radiofrequency output coupling.

4. The reference box as recited in claim 3, further comprising:
a guide plate attached to an end of the reference box, the guide plate having an open interior region through which the input connector extends, the input connector extending outward from an end of the guide plate, the guide plate configured to guide movement of the reference box in the substantially linear manner to guide electrical connection of the input connector with the radiofrequency output coupling and to guide electrical disconnection of the input connector from the radiofrequency output coupling.

5. The reference box as recited in claim 4, wherein the guide plate is configured to engage with a first end of a lever member and cause a lifting of the first end of the lever member as the reference box is moved to guide electrical connection of the input connector with the radiofrequency output coupling, wherein the lever member is engaged with the radiofrequency output coupling such that lifting of the first end of the lever member causes a vertical lifting of the radiofrequency output coupling to a calibration position at which the radiofrequency output coupling is both disconnected from a downstream radiofrequency power transmission system and positioned to engage with the input connector.

6. The reference box as recited in claim 5, wherein the guide plate is configured to cause a lowering of the first end of the lever member as the reference box is moved to guide electrical disconnection of the input connector from the radiofrequency output coupling, wherein the lever member is engaged with the radiofrequency output coupling such that lowering of the first end of the lever member causes a vertical lowering of the radiofrequency output coupling to a normal operating position at which the radiofrequency output coupling is electrically connected to the downstream radiofrequency power transmission system.

7. The reference box as recited in claim 1, wherein the reference circuit includes an inductor, a first capacitor, and a second capacitor, the inductor having an input terminal electrically connected to the input terminal of the reference circuit, the inductor having an output terminal electrically connected to an input terminal of the first capacitor, the first capacitor having an output terminal electrically connected to both the output terminal of the reference circuit and an input terminal of the second capacitor, the second capacitor having an output terminal electrically connected to a reference ground potential.

8. The reference box as recited in claim 1, further comprising:
an outer housing structure, the reference circuit disposed within the outer housing structure, the input connector extending through a first wall of the outer housing structure, the output connector extending through a second wall of the outer housing structure.

9. A radiofrequency calibration system, comprising:
a reference box including a reference circuit configured to convert a non-reference input impedance to a reference output impedance, the reference box having an input connector and an output connector, the input connector configured to electrically connect with a radiofrequency output coupling of a direct-drive radiofrequency power supply;
a radiofrequency power meter having a radiofrequency power input electrically connected to the output connector of the reference box, the radiofrequency power meter having a radiofrequency power output and a data interface, the radiofrequency power meter having a reference input impedance and a reference output impedance substantially equal to the reference output impedance of the reference box;
a cable having an impedance substantially equal to the reference output impedance of the reference box, the cable having a first end electrically connected to the radiofrequency power output of the radiofrequency power meter, the cable having a second end;
a test load electrically connected to the second end of the cable, the test load having an impedance substantially equal to the reference output impedance of the reference box; and
a controller connected in data communication with the data interface of the radiofrequency power meter.

10. The radiofrequency calibration system as recited in claim 9, wherein the input connector and the radiofrequency output coupling are configured to enable sliding of the input connector in a substantially linear manner to electrically connect with the radiofrequency output coupling and to electrically disconnect from the radiofrequency output coupling.

11. The radiofrequency calibration system as recited in claim 9, wherein the reference circuit includes an inductor, a first capacitor, and a second capacitor, the inductor having an input terminal electrically connected to the input terminal of the reference circuit, the inductor having an output terminal electrically connected to an input terminal of the first capacitor, the first capacitor having an output terminal electrically connected to both the output terminal of the reference circuit and an input terminal of the second capacitor, the second capacitor having an output terminal electrically connected to a reference ground potential.

12. A method for calibrating a direct-drive radiofrequency power supply, comprising:
(a) electrically disconnecting a radiofrequency power output of the direct-drive radiofrequency power supply from a downstream radiofrequency power transmission system;
(b) electrically connecting an input connector of a reference box to the radiofrequency power output of the direct-drive radiofrequency power supply, the reference box including a reference circuit configured to convert a non-reference input impedance to a reference output impedance;
(c) electrically connecting an output of the reference box to an input of a radiofrequency power meter, the radiofrequency power meter having an output electrically connected through a cable to a test load;
(d) operating the direct-drive radiofrequency power supply to drive a setpoint amount of radiofrequency power through the reference box, power meter, and cable to the test load;
(e) operating the radiofrequency power meter to measure an output amount of radiofrequency power at the output of the reference box;
(f) adjusting the output amount of radiofrequency power measured by the radiofrequency power meter by a known amount of radiofrequency power dissipated by the reference box to determine an actual output amount of radiofrequency power; and
(g) storing the actual output amount of radiofrequency power in relation to the setpoint amount of radiofrequency power as a radiofrequency power calibration datapoint for the direct-drive radiofrequency power supply, a difference between the actual output amount of radiofrequency power and the setpoint amount of radiofrequency power providing a radiofrequency power calibration adjustment factor to ensure that the radiofrequency power output of the direct-drive radiofrequency power supply substantially matches the setpoint amount of radiofrequency power during operation of the direct-drive radiofrequency power supply.

13. The method as recited in claim 12, wherein the reference box includes a reference circuit connected between the input connector of the reference box and the output of the reference box, the reference circuit including an inductor, a first capacitor, and a second capacitor, the inductor having an input terminal electrically connected to the input terminal of the reference circuit, the inductor having an output terminal electrically connected to an input terminal of the first capacitor, the first capacitor having an output terminal electrically connected to both the output terminal of the reference circuit and an input terminal of the second capacitor, the second capacitor having an output terminal electrically connected to a reference ground potential.

14. The method as recited in claim 12, wherein the operation (a) includes removing an electrically conductive jumper that electrically connects a radiofrequency output coupling of the direct-drive radiofrequency power supply to the downstream radiofrequency power transmission system.

15. The method as recited in claim 12, wherein the operations (a) and (b) are performed by moving the reference box in a substantially linear manner so that a guide plate attached to an end of the reference box engages with a first end of a lever member and lifts the first end of the lever member as the reference box is moved, wherein lifting of the first end of the lever member causes a vertical lifting of an output coupling of the direct-drive radiofrequency power supply to a calibration position at which the output coupling is both disconnected from the downstream radiofrequency power transmission system and positioned to engage with the input connector of the reference box.

16. The method as recited in claim 12, further comprising:
repeating operations (d), (e), (f), and (g) for different setpoint amounts of radiofrequency power over an operational power range within which the direct-drive radiofrequency power supply will be operated to generate a set of radiofrequency power calibration datapoints for the direct-drive radiofrequency power supply as a function of the setpoint amount of radiofrequency power.

17. The method as recited in claim 12, wherein operations (d) and (e) are performed with the direct-drive radiofrequency power supply operating to generate radiofrequency signals having a target frequency, the reference circuit being specifically configured for use at the target frequency.

18. The method as recited in claim 12, wherein the known amount of radiofrequency power dissipated by the reference box is determined by calibrating the reference box against a master-standard reference box.

19. The method as recited in claim 12, wherein the downstream radiofrequency power transmission system includes a reactive circuit and a coil, the reactive circuit configured to cancel a combined reactance of both the coil and a load to which the direct-drive radiofrequency power supply drives radiofrequency power.

20. The method as recited in claim 19, further comprising:
sweeping a setpoint operating frequency of the direct-drive radiofrequency power supply over a range about a target operating frequency of the direct-drive radiofrequency power supply to determine an extant resonance frequency of the direct-drive radiofrequency power supply;
adjusting a capacitance setting of a variable capacitor within the reactive circuit to cause an adjustment of the extant resonance frequency of the direct-drive radiofrequency power supply toward the target operating frequency of the direct-drive radiofrequency power supply; and
repeating the sweeping of the setpoint operating frequency and the adjusting of the capacitance setting of the variable capacitor within the reactive circuit until the extant resonance frequency of the direct-drive radiofrequency power supply is within an acceptable range of the target operating frequency of the direct-drive radiofrequency power supply.
